(19) United States
(12) Patent Application Publication
(10) Pub. No.: US 2015/0177272 A1
(43) Pub. Date: Jun. 25, 2015

(54) MICROELECTROMECHANICAL SYSTEM AND METHODS OF USE

(71) Applicant: Purdue Research Foundation, West Lafayette, IN (US)

(72) Inventor: Jason V. Clark, West Lafayette, IN (US)

(21) Appl. No.: 14/407,898

(22) PCT Filed: May 31, 2013
(86) PCT No.: PCT/US2013/043595

§ 371 Date: Dec. 12, 2014

Related U.S. Application Data
(60) Provisional application No. 61/659,179, filed on Jun. 13, 2012.
(60) Provisional application No. 61/659,068, filed on Jun. 13, 2012.
(60) Provisional application No. 61/723,927, filed on Nov. 8, 2012.
(60) Provisional application No. 61/724,325, filed on Nov. 9, 2012.
(60) Provisional application No. 61/724,400, filed on Nov. 9, 2012.
(60) Provisional application No. 61/724,482, filed on Nov. 9, 2012.

(51) Int. Cl. G01P 15/125; B81B 3/00; B81C 99/00; G01Q 20/00; G01K 11/00

(52) U.S. Cl. CPC G01P 15/125; G01Q 20/00; G01K 11/00; B81C 99/0045; B81B 3/0051

(57) ABSTRACT

Methods of measuring displacement of a movable mass in a microelectromechanical system (MEMS) include driving the mass against two displacement-stopping surfaces and measuring corresponding differential capacitances of sensing capacitors such as combs. A MEMS device having displacement-stopping surfaces is described. Such a MEMS device can be used in a method of measuring properties of an atomic force microscope (AFM) having a cantilever and a deflection sensor, or in a temperature sensor having a displacement-sensing unit for sensing a movable mass permitted to vibrate along a displacement axis. A motion-measuring device can include pairs of accelerometers and gyroscopes driven 90° out of phase.

### CROSS-REFERENCE TO RELATED APPLICATIONS

This application is a nonprovisional application of, and claims priority to, U.S. Provisional Patent Applications Nos. 61/659,179, filed Jun. 13, 2012; 61/723,927, filed Nov. 8, 2012; 61/724,325, filed Nov. 9, 2012; 61/724,400, filed Nov. 9, 2012; 61/724,482, filed Nov. 9, 2012; and 61/659,068, filed Jun. 13, 2012, the entirety of each of which is incorporated herein by reference.

### FIELD OF THE INVENTION

The present application relates to microelectromechanical systems (MEMS) and nanoelectromechanical systems (NEMS).

### BACKGROUND

Microelectromechanical systems (MEMS) are commonly fabricated on silicon (Si) or silicon-on-insulator (SOI) wafers, much as standard integrated circuits are. However, MEMS devices include moving parts on the wafers as well as electrical components. Examples of MEMS devices include gyroscopes, accelerometers, and microphones. MEMS devices can also include actuators that move to apply force on an object. Examples include microrobotic manipulators. However, when a MEMS device is fabricated, the dimensions of the structures fabricated often do not match the dimensions specified in the layout. This can result from, e.g., under- or over-etching.

Reference is made to the following:
[A1] D. H. Titterton, J. L. Weston, “Strapdown Inertial Navigation Technology.” Peter Peregrinus Ltd. UK, 1997.
[A2] Y. Yazdi, F. Ayazi, K. Najafi, “Micromachined inertial sensors,” Proceedings of the IEEE, vol. 86, no. 8, pp. 1640-1659, 1998.
[A3] I. Skog, P. Handel. “Calibration of a MEMS inertial measurement unit,” XVII IMEKO WORLD CONGRESS Metrology for a Sustainable Development, Sep. 17-22, 2006.
[A4] I. Skog. P. Handel “A Versatile PC-Based Platform for Inertial Navigation”, in Proc. NORSIG 2006, Nordic Signal Processing Symposium, pp. 262-265, June. 2006.
[A5] A. Kim, M. F Golnaraghi, “Initial calibration of an inertial measurement unit using an optical position tracking system”, in Proc. PLANS 2004, IEEE Position Location and Navigation Symposium, pp. 96-101, April. 2004.
[A6] R M. Rogers, “Applied Mathematics In integrated Navigation Systems,” Second Edition. AIAA Education Series, 2003.
[A7] F. Li and J. Clark, “Practical measurements of stiffness, displacement, and comb drive force of MEMS,” IEEE UGIM, 2010.
[A8] A. Shkel, C. Acar. “MEMS Vibratory Gyroscopes Structural Approaches to Improve Robustness.” Springer Verlag, 2008.
[A9] Tang W C. “Electrostatic comb drive for resonant sensor and actuator applications.” PhD Dissertation, University of California, Berkeley, Calif. 1990.
[A11] AD7746 Capacitance-to-Digital Convertor, Analog Devices, MA, 2011.

Reference is also made to the following:
[B1] Udrea, F., Santra, S., and Gardner, J. W., 2008, “CMOS Temperature Sensors—Concepts, State-of-the-art and Prospects”, IEEE Semiconductor Conference, 1 pp. 31-40.
[B2] Webb, C., 1997, “Infrared: Faster, Smaller, Cheaper” Control Instrumentation 44.
[B3] Childs, P. R. N., Greenwood, J. R. and Long, C. A., 2000, “Review of Temperature Measurement”, Review of Scientific Instruments, 71(8) pp. 2959-2978.
[B4] Preston-Thomas, H., 1990, “The International Temperature Scale of 1990 (ITS-90)”, Metrologia 27, pp. 186-193.
[B5] Huffer, J. L., and Bechhoefer, J., 1993, “Calibration of atomic-force microscope tips” Review of Scientific Instruments 64(7), pp. 1868-1873.
[B6] Matei, G. A., Thoreson, E. J., Pratt, J. R., Newell, D. B. and Bumham, N. A., 2006, “Precision and accuracy of thermal calibration of atomic force microscopy cantilevers” Review of Scientific Instruments 77(8), pp. 1-6.
[B7] Press, W. H., Flannery, B. P., Teukolsky, S. A. and Vetterling, W. T., 1989, “Numerical Recipes in FORTRAN”, Cambridge University Press, Cambridge, Chap. 12.
[B8] Stark, R. W., Drobek, T., and Heckl, W. M., 2001, “Thermomechanical Noise of a Free V-Shaped Cantilever for Atomic Force Microscopy”, Ultramicroscopy, 86, pp. 201-215.
[B9] Butt, H. J., and Jaschke, M., 1995, “Calculation of Thermal Noise in Atomic Force Microscopy”, Nanotechnology, 6(1), pp. 1-7.
[B10] Levy, R., and Maaloum, M., 2002, “Measuring the Spring Constant of Atomic Force Microscope Cantilevers: Thermal Fluctuations and Other Methods”, Nanotechnology, 13 (1), pp. 34-37.
[B11] Jayich, A. C., and Shanks, W. E., 2008, “Noise Thermometry and Electron Thermometry of a Sample-On-Cantilever System Below 1 Kelvin”, Applied Physics Letters, 92(1), pp. 1-3.
[B12] Li, F., and Clark, J. V., 2010, “Practical Measurements of Stiffness, Displacement, and Comb Drive Force of MEMS”, EEE UGIM (University Government Industry Micro/nano) Symposium, pp. 1-6.
[B15] COMSOL, Inc. 744 Cowper Street, Palo Alto, Calif. 94301, USA, www.comsol.com

Reference is also made to the following:
[C1] Gabrielson, T. B., 1993, “Mechanical-Thermal Noise in Micromachined Acoustic and Vibration Sensors,” IEEE Trans. Electron Dev., 40(5), pp. 903-909.
[C2] Leland, R. P., 2005, “Mechanical-Thermal Noise in MEMS Gyroscopes,” IEEE Sensors J., 5(3), pp. 493-500.
[C3] Vig, J. R., and Kim, Y., 1999, “Noise in Microelectromechanical System Resonators,” IEEE Trans. Ultrasonics, Ferroelectrics, Freq. Control, 46(6), pp. 1558-1565.
[C4] Butt, H-J., and Jaschke, M., 1995, “Calculation of thermal noise in atomic force microscopy,” Nanotechnology, 6, pp. 1-7.
[C5] Shao, Z., Mou, J., Czajkowsky, D. M., Yang, J., Yuan, J-Y., 1996, “Biological atomic force microscopy: what is achieved and what is needed,” Adv. Phys., 45(1), pp. 1-86.
[C6] Gittes, F., and Schmidt, C. F., 1998, “Thermal noise limitations on micromechanical experiments,” Eur. Biophys. J., 27, pp. 75-81.
[C7] Rief, M., Gautel, M., Oesterhelt, F., Fernandez, J. M., Gaub, H. E., 1997, “Reversible unfolding of individual titin immunoglobulin domains by AFM,” Science, 276, pp. 1109-1112.
[C8] Boser, B. E., and Howe, R. T., 1996, “Surface Micromachined Accelerometers,” IEEE J. Solid-State Circuits, 31, pp. 366-375.
[C9] Dong, Y., Kraft, M., Gollasch, C., Redman-White, W., 2005, “A high-performance accelerometer with a fifth order sigma-delta modulator,” J. Micromech. Microeng., 15, pp. S22-S29.
[C10] Jiang, X., Seeger, J. I., Kraft, M., Boser, B. E., 2000, “A Monolithic Surface Micromachined Z-Axis Gyroscope with Digital Output,” 2000 Symposium on VLSI Circuits Digest of Technical Papers, Honolulu, Hi., pp. 16-19.
[C11] Handtmann, M., Aigner, R., Meckes, A., Wachutka, G. K. M., 2002, “Sensitivity enhancement of MEMS inertial sensors using negative springs and active control,” Sensor Actuat A-Phys, 97-98, pp. 153-160.
[C12] Huber, D., Corredoura, P., Lester, S., Robbins, V., Kamas, L., 2004, “Reducing Brownian Motion in an Electrostatically Tunable MEMS Laser,” J. Microelectromech. Syst., 13(5), pp. 732-736.
[C13] Friswell, F. I., Inman, D. J., Rietz, R. W., 1997, “Active Damping of Thermally Induced Vibrations,” J. Intel. Mat. Syst. Struct., 8, pp. 678-685.
[C14] Wlodkowski, P. A., Deng, K., Kahn, M., 2001, “The development of high-sensitivity, low-noise accelerometers utilizing single crystal piezoelectric materials,” Sensor Actuat A-Phys., 90, pp. 125-131.
[C15] Levinzon, F. A., 2005, “Noise of Piezoelectric Accelerometer With Integral FET Amplifier,” IEEE Sensors J., 5(6), pp. 1235-1242.
[C16] Riewruja, V. and Rerkratn, A., 2010, “Analog Multipliers Using Operational Amplifiers”, Indian J. of Pure & Applied Physics, 48, pp. 67-70.

Reference is also made to the following:
[D1] J. C. Marshall, D. L. Herman, P. T. Vernier, D. L. DeVoe, and M. Gaitan, “Young's Modulus Measurements in Standard IC CMOS Processes Using MEMS Test Structures”, IEEE Electron Device Letters, (2007).
[D2] J. Yan, A. A. Seshia, P. Steeneken, J. V. Beek, “A Test Structure for Young Modulus Extraction through Capacitance-Voltage Measurements”, Sensors (2005).
[D3] L. M. Fok, C. K. M. Fung, Y. H. Liu, and W. J. Liz, “Nano-scale Mechanical Test of MEMS Structures by Atomic Force Microscope” Proceedings of the 5th World Congress on Intelligent Control and Automation, (2004).
[D4] W. N. Sharpe, B. Yuan, and R. Vaidyanathan, “New Test Structures and Techniques for Measurement of Mechanical Properties of MEMS Materials”, Proc. SPIE, (1996).
[D5] L. M. Zhang, D. Uttamchandani, and B. Culshaw, “Measurement of the Mechanical Properties of Silicon Resonators”, Sensors and Actuators, (1991).
[D6] COMSOL, Inc. 744 Cowper Street, Palo Alto, Calif. 94301, USA, www.comsol.com
[D7] M. Paz, “Structural Dynamics: Theory and Computation”, Chapman & Hall, (2004).
[D8] R. C. Hibbeler, “Structural Analysis”, Prentice Hall, Eighth edition, (2012).
[D9] L. L. Yaw, “Stiffness Matrix of 2D Tapered Beam”, online at Web site people.wallawalla.edu/˜louie.yaw/structuralanalysis/
[D10] J. R. Barber, “Solid Mechanics and Its Applications, Volume 107, (2004).
[D11] F. Li, J. V. Clark, “Practical Measurements of Stiffness, Displacement, and Comb Drive Force of MEMS”, EEE UGIM (University Government Industry Micro/nano) Symposium, (2010).

The discussion above is merely provided for general background information and is not intended to be used as an aid in determining the scope of the claimed subject matter.

### BRIEF DESCRIPTION

According to an aspect, there is provided a method of measuring displacement of a movable mass in a microelectromechanical system (MEMS), the method comprising:
moving the movable mass into a first position in which the movable mass is substantially in stationary contact with a first displacement-stopping surface;
using a controller, automatically measuring a first difference between the respective capacitances of two spaced-apart sensing capacitors while the movable mass is in the first position, wherein each of the two sensing capacitors includes a respective first plate attached to and movable with the movable mass and a respective second plate substantially fixed in position;
moving the movable mass into a second position in which the movable mass is substantially in stationary contact with a second displacement-stopping surface spaced apart from the first displacement-stopping surface;
using the controller, automatically measuring a second difference between the respective capacitances while the movable mass is in the second position;
moving the movable mass into a reference position in which the movable mass is substantially spaced apart from the first and the second displacement-stopping surfaces, wherein a first distance between the first position and the reference position is different from a second distance between the second position and the reference position;
using the controller, automatically measuring a third difference between the respective capacitances while the movable mass is in the reference position;
using the controller, automatically computing a drive constant using the measured first difference, the measured second difference, the measured third difference, and first and second selected layout distances corresponding to the first and second positions, respectively;
using the controller, automatically applying a drive signal to an actuator to move the movable mass into a test position;
using the controller, automatically measuring a fourth difference between the respective capacitances while the movable mass is in the test position; and using the controller, automatically determining the displacement of the movable mass in the test position using the computed drive constant and the measured fourth difference.

According to another aspect, there is provided a method of measuring properties of an atomic force microscope (AFM) having a cantilever and a deflection sensor, the method comprising:
using a controller, automatically measuring respective differential capacitances, at a reference position of a movable mass and at first and second characterization positions of the movable mass spaced apart from the reference position along a displacement axis by respective, different first and second distances, of two capacitors having respective first plates attached to and movable with the movable mass;
using the controller, automatically computing a drive constant using the measured differential capacitances and first and second selected layout distances corresponding to the first and second characterization positions, respectively;
using an AFM cantilever, applying force on the movable mass along the displacement axis in a first direction so that the movable mass moves to a first test position;
while the movable mass is in the first test position, measuring a first test deflection of the AFM cantilever using the deflection sensor and measuring a first test differential capacitance of the two capacitors;
applying a drive signal to an actuator to move the movable mass along the displacement axis opposite the first direction to a second test position;
while the movable mass is in the second test position, measuring a second test deflection of the AFM cantilever using the deflection sensor and measuring a second test differential capacitance of the two capacitors; and
automatically computing an optical-level sensitivity using the drive constant, the first and second test deflections, and the first and second test differential capacitances.

According to another aspect, there is provided a microelectromechanical-systems (MEMS) device, comprising:
a) a movable mass;
b) an actuation system adapted to selectively translate the movable mass along a displacement axis with reference to a reference position;
c) two spaced-apart sensing capacitors, each including a respective first plate attached to and movable with the movable mass and a respective second plate substantially fixed in position, wherein respective capacitances of the sensing capacitors vary as the movable mass moves along the displacement axis; and
d) one or more displacement stopper(s) arranged to form a first displacement-stopping surface and a second displacement-stopping surface, wherein the first and second displacement-stopping surfaces limit travel of the movable mass in respective, opposite directions along the displacement axis to respective first and second distances away from the reference position, wherein the first distance is different from the second distance.

According to another aspect, there is provided a motion-measuring device, comprising:
a) a first and a second accelerometer located within a plane, each accelerometer including a respective actuator and a respective sensor;
b) a first and a second gyroscope located within the plane, each gyroscope including a respective actuator and a respective sensor;
c) an actuation source adapted to drive the first accelerometer and the second accelerometer 90 degrees out of phase with each other, and adapted to drive the first gyroscope and the second gyroscope 90 degrees out of phase with each other; and
d) a controller adapted to receive data from the respective sensors of the accelerometers and the gyroscopes and determine a translational, centrifugal, Coriolis, or transverse force acting on the motion-measuring device.

According to another aspect, there is provided a temperature sensor, comprising:
a) a movable mass;
b) an actuation system adapted to selectively translate the movable mass along a displacement axis with reference to a reference position;
c) two spaced-apart sensing capacitors, each including a respective first plate attached to and movable with the movable mass and a respective second plate substantially fixed in position, wherein respective capacitances of the sensing capacitors vary as the movable mass moves along the displacement axis;
d) one or more displacement stopper(s) arranged to form a first displacement-stopping surface and a second displacement-stopping surface, wherein the first and second displacement-stopping surfaces limit travel of the movable mass in respective, opposite directions along the displacement axis to respective first and second distances away from the reference position, wherein the first distance is different from the second distance, and wherein the actuation system is further adapted to selectively permit the movable mass to vibrate along the displacement axis within bounds defined by the first and second displacement-stopping surfaces;
e) a differential-capacitance sensor electrically connected to the respective second plates; and
f) a displacement-sensing unit electrically connected to the movable mass and to the second plate of at least one of the sensing capacitors and adapted to provide a displacement signal correlated with a displacement of the movable mass along the displacement axis;
g) a controller adapted to automatically:
   operate the actuation system to position the movable mass in a first position substantially at the reference position, in a second position substantially in stationary contact with the first displacement-stopping surface, and in a third position substantially in stationary contact with the second displacement-stopping surface;
   using the differential-capacitance sensor, measure first, second, and third differential capacitances of the of the sensing capacitors corresponding to the first, second, and third positions, respectively;
   receive first and second layout distances corresponding to the first and second positions, respectively;
   compute a drive constant using the measured first, second, and third differential capacitances and the first and second layout distances;
   apply a drive signal to the actuation system to move the movable mass into a test position;
   measure a test differential capacitance corresponding to the test position using the differential-capacitance sensor;
   compute a stiffness using the computed drive constant, the applied drive signal, and the test differential capacitance;
   cause the actuation system to permit the movable mass to vibrate;
   while the movable mass is permitted to vibrate, measure a plurality of successive displacement signals using the displacement-sensing unit and compute respective displacements of the movable mass using the computed drive constant; and
   determine a temperature using the measured displacements and the computed stiffness.

This brief description is intended only to provide a brief overview of subject matter disclosed herein according to one or more illustrative embodiments, and does not serve as a guide to interpreting the claims or to define or limit the scope of the invention, which is defined only by the appended claims. This brief description is provided to introduce an illustrative selection of concepts in a simplified form that are further described below in the detailed description. This brief description is not intended to identify key features or essential features of the claimed subject matter, nor is it intended to be used as an aid in determining the scope of the claimed subject matter. The claimed subject matter is not limited to implementations that solve any or all disadvantages noted in the background.

### BRIEF DESCRIPTION OF THE DRAWINGS

The above and other objects, features, and advantages of the present invention will become more apparent when taken in conjunction with the following description and drawings wherein identical reference numerals have been used, where possible, to designate identical features that are common to the figures, and wherein:

FIG. 1 is a plan view of an exemplary self-calibratable MEMS device;

FIG. 2 is a perspective of an exemplary application of a calibratable MEMS to calibrate the displacement and stiffness of an atomic force microscope;

FIG. 3 shows representations of photographs of various conventional gravimeters;

FIG. 4 shows a perspective of a conventional sub-micro-G accelerometer;

FIG. 5 shows a layout schematic of a self-calibratable MEMS gravimeter according to various aspects;

FIG. 6 shows simulation results of uncertainty in capacitance as a function of flexure length;

FIGS. 7A-B show simulated uncertainty in frequency as a function of flexure length;

FIG. 8 shows an exemplary self-calibratable gyroscope;

FIG. 9 shows an exemplary self-calibratable accelerometer;

FIG. 10 is a plot showing a simulation of the velocities of exemplary proof masses;

FIG. 11 is a partially-schematic representation of images of a self-calibratable accelerometer and capacitance meter;

FIG. 12 is a plot of sensitivity of sensor noise to gap-measurement uncertainty;

FIG. 13 is a plot of sensitivity of mismatch to gap-measurement uncertainty;

FIG. 14 shows variation of displacement amplitude with stiffness;

FIG. 15 is a plot showing the dependence of amplitude on temperature;

FIG. 16 shows sensitivity of amplitude with stiffness;

FIG. 17 shows sensitivity of amplitude with temperature;

FIGS. 18A and 18B show an exemplary MEMS structure;

FIG. 19 is a flowchart of exemplary methods of determining a comb drive constant;

FIG. 20 is a flowchart of exemplary further processing after determining the comb drive constant;

FIG. 21 shows an exemplary system for instantaneous displacement sensing;

FIG. 22 shows a model for simulating to determine the comb drive constant;

FIG. 23 shows results of a simulation of the model in FIG. 22 at an initial state;

FIG. 24 shows results of a simulation of the model in FIG. 22 at an intermediate state;

FIG. 25 shows results of a simulation of static deflection for stiffness;

FIG. 26 is a schematic of a MEMS structure and a force feedback system according to various aspects;

FIG. 27 is a circuit diagram of an exemplary trans-impedance amplifier (TIA);

FIG. 28 is a circuit diagram of an exemplary differentiator and an exemplary demodulator;

FIG. 29 is a circuit diagram of an exemplary low-pass frequency filter;

FIG. 30 is a circuit diagram of an exemplary differentiator;

FIG. 31 is a circuit diagram of an exemplary filter;

FIG. 32 is a circuit diagram of exemplary zero-crossing detectors;

FIG. 33 is a circuit diagram of an exemplary conditional circuit;

FIG. 34 shows a simulated comparison between the output voltage Vₒᵤₜ and the input voltage Vᵢₙ of an exemplary transimpedance amplifier;

FIG. 35 shows a simulated demodulated signal;

FIG. 36 shows a simulated filtered signal;

FIG. 37 shows a simulated output signal from an exemplary differentiator;

FIG. 38 shows a simulated output signal from an exemplary filter;

FIGS. 39 and 40 show simulated output signals of two zero-crossing detectors;

FIG. 41 shows a simulated feedback signal from a conditional circuit;

FIG. 42 shows results of a simulation of an effect of electrostatic feedback force;

FIG. 43 shows data of the Young's modulus of polysilicon versus year published;

FIG. 44 shows representations of micrographs of fabricated MEMS devices according to various aspects;

FIG. 45 shows simulation meshes and results comparing the static displacement and resonant frequency of exemplary beams with and without fillets;

FIG. 46 shows simulation meshes and results comparing the static displacement and resonant frequency of exemplary tapered beams with and without fillets;

FIG. 47 shows an exemplary tapered beam component and various of its degrees of freedom;

FIGS. 48A and 48B show a MEMS structure and measurement of stiffness;

FIG. 49 shows an exemplary method of determining stiffness;

FIG. 50 shows the configuration of the portion of an exemplary comb drive;

FIG. 51 shows results of a simulation of the configuration shown in FIG. 50 at an initial state;

FIG. 52 shows results of a simulation of the configuration shown in FIG. 50 at an intermediate state;

FIG. 53 shows results of a simulation of static deflection for determining stiffness;

FIG. 54 is a high-level diagram showing components of a data-processing system;

FIG. 55 shows an exemplary method of measuring displacement of a movable mass in a microelectromechanical system;

FIG. 56 shows an exemplary method of measuring properties of an atomic force microscope; and

FIG. 57 is an axonometric view of a motion-measuring device according to various aspects.

The attached drawings are for purposes of illustration and are not necessarily to scale.

### DETAILED DESCRIPTION

Reference is also made to the following, the disclosure of each of which is incorporated herein by reference:
[A10] F. Li, J. V. Clark, “Self-Calibration for MEMS with Comb Drives: Measurement of Gap,” Journal of Microelectromechanical Systems, accepted May, 2012.
[B13] Clark, J. V., 2012, “Post-Packaged Measurement of MEMS Displacement, Force, Stiffness, Mass, and Damping”, International Microelectronics and Packaging Society.
[B14] Li. F, Clark, J. V., 2012, “Self-Calibration of MEMS with Comb Drives: Measurement of Gap”, Journal of Microelectromechanical Systems, December 2012.
[D12] J. V. Clark, “Post-Packaged Measurement of MEMS Displacement, Force, Stiffness, Mass, and Damping”, International Microelectronics and Packaging Society, March (2012).

Symbols for various quantities (e.g., Agap) are used herein. Throughout this disclosure, italic and non-italic variants of each of these symbols (e.g., “Δgap” and “Δgap”) are equivalent.

Various aspects relate to calibrating an atomic force microscope (AFM) with self-calibratable micro-electro-mechanical system (MEMS). Various arrangements for calibration of an atomic force microscope (AFM) using Micro-Electro-Mechanical Systems (MEMS) are disclosed herein. Some methods herein use a self-calibratable MEMS technology to traceably measure AFM cantilever stiffness and displacement. The calibration of displacement includes measuring the change in optical sensor voltage per change in displacement, or optical level sensitivity (OLS), and the calibration of stiffness along with displacement yields an accurate measurement of force. Calibrating the AFM is useful because the AFM has been a useful tool for nanotechnologists for over two decades, yet the accuracy of the AFM has been largely unknown. Previous efforts to calibrate the AFM, such as a thermal vibration method, an added weight method, and a layout geometry method, are about 10% uncertain. As a consequence, such AFM measurements yield about 1 significant digit of accuracy. Various aspects herein advantageously use a MEMS device, with traceably-calibrated force, stiffness, and displacement, as a sensor to calibrate the displacement reading and cantilever stiffness of the AFM. Various methods and devices described herein are practical, easy to use, and suitable for fabrication in a standard silicon on insulator (SOI) process. In the present disclosure, use of a general MEMS design is described and associated accuracy, sensitivity, and uncertainty analyses are presented.

Due to the specific capabilities of the AFM, the field of nanotechnology has seen extraordinary growth. The AFM is used to apply and sense forces or displacements to better understand phenomena at the nanoscale, which is a key building block scale of matter.

The AFM includes a cantilevered stylus for probing matter. Displacement is sensed by reflecting a beam of light off the cantilever onto a photodiode that detects the position of the light beam. Measurement of force is found by multiplying this deflection by the cantilever stiffness. The problem is that finding an accurate and practical way of calibrating the AFM cantilever stiffness and its displacement has been difficult. Several common methods used to calibrate AFM are described below.

In an AFM calibration method that requires the accurate knowledge of cantilever geometry and material properties, due to process variations, such properties should be measured; however, there has not been an accurate and practical means for such measurements.

In a calibration method that exploits thermally-induced vibration of the AFM cantilever, the accurate measurement of cantilever temperature and displacement are required; however, there has not been an accurate and practical means for such measurements.

A mixed method depends on geometry and dynamics.

A traceable method uses a series of uniform cantilevers calibrated by an electrostatic force balance method as calibration references for AFM cantilever stiffness. However, the method is impractical and therefore difficult for widespread use.

The optical level sensitivity (OLS) of the AFM is the ratio of the change in photodiode voltage to the change in displacement. This calibration is in some embodiments done by pressing the cantilever tip onto a non-deformable surface. It is assumed that a particular displacement can be prescribed by a piezoelectric positioning stage; however, calibrating the accuracy and precision of this positioning stage is difficult and impractical.

To address the above problems of inaccuracy, imprecision, and impracticality, the AFM's stiffness and displacement are calibrated by using the self-calibratable MEMS according to various aspects herein. This self-calibration is referred to herein as electro micro metrology (EMM), and is advantageously capable of extracting accurate and precise mechanical properties in terms of electronic measurands. Microfabrication of the MEMS micro-device can be done using a standard foundry process such as SOIMUMPs. Once the force, displacement, and stiffness of the MEMS are accurately calibrated, the micro-device can be used to calibrate the AFM by measuring its stiffness and deflection.

Various terms used herein are given in Table 1, below.

TABLE 1
NOMENCLATURE

| | |
|---|---|
| h | Thickness of the device layer |
| | (unknown) |
| g | Gap between comb fingers |
| | (unknown) |
| ε | Permittivity of the |
| | medium (unknown) |
| β | Capacitance correction factor |
| | (unknown) |
| L | Initial finger overlap (unknown) |
| C, C^{p} | Capacitance (measured) |
| Δ, δ | Difference and |
| | uncertainty (measured) |
| x | Comb drive displacement (measured) |
| F | Comb drive force (measured) |
| k | System stiffness (measured) |
| gap | Gap stop size (measured) |
| Ψ | Comb drive constant (measured) |
| Δgap | Layout-to-fabrication (measured) |
| V | Applied voltage (known) |
| N | Number of comb fingers (known) |
| n | n = gap_{2,layout}/gap_{1,layout} ≠ 1 (known) |

Electro micro metrology (EMM) is an accurate, precise, and practical method for extracting effective mechanical measurements of MEMS. Various methods of EMM use two unequal gaps to determine the difference in gap geometry between layout and fabrication (since MEMS devices change from layout to fabrication). These gap stops establish a means of equating a well-defined distance in terms of change in capacitance.

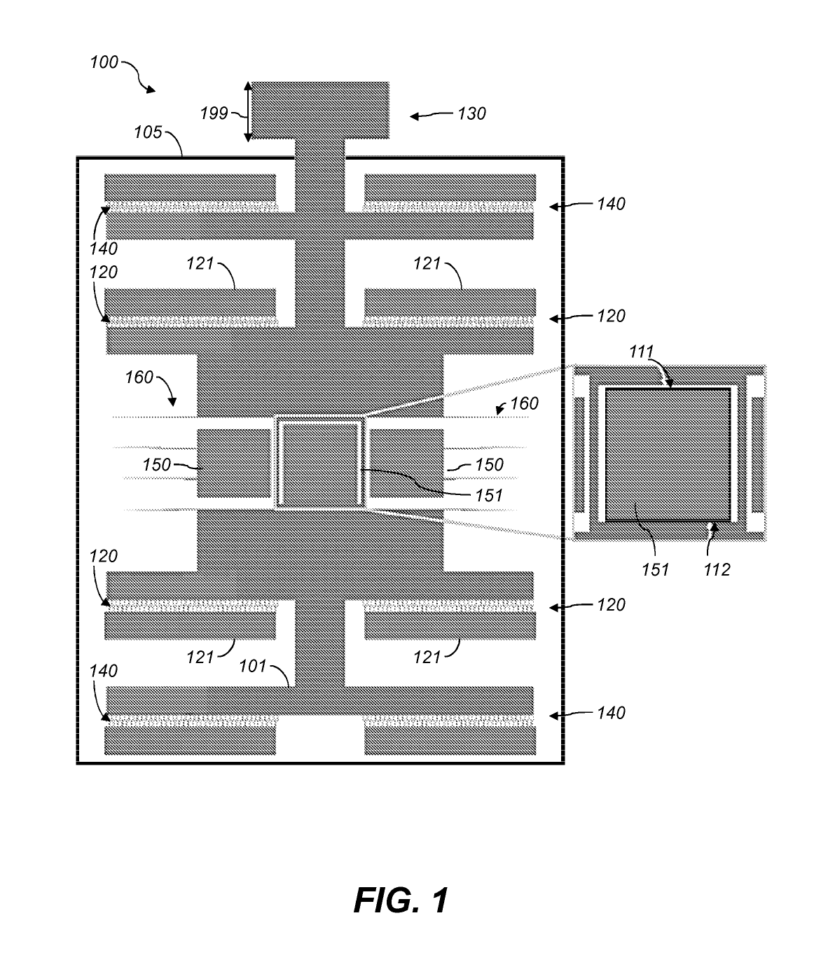

FIG. 1 is a plan view of a self-calibratable MEMS 100 according to various aspects of the present disclosure, including an inset around anchor 151. MEMS 100 is built over substrate 105. Two unequal gaps 111, 112 are defined in the layout. These two gaps are related by gap_{2,layout}=n gap_{1,layout}. They are used to provide two useful measurements to determine the unknown properties listed in Table 1.

FIG. 1 can be, e.g., a self-calibratable force-displacement sensor. The actuator 101 is supported by anchors 150, 151 via flexures 160 (only part shown). Actuation comb drives 120 have moved the actuator up to close gap 112. The substrate underneath the T-shape applicator 130 is backside etched for sidewall interaction with the AFM cantilever. Various aspects proceed as follows:

Using differential capacitive sensing, e.g., of sensing combs 140, measurements at zero-state and upon closing gap 111 and gap 112 by applying enough actuation voltage may be expressed as:

$$\begin{matrix}Δ {C}_{1} = ( {( \frac{2 N β ɛ hL}{g} + {C}_{+}^{P} )}_{\begin{matrix}left \\ comb\end{matrix}} - {( \frac{2 N β ɛ hL}{g} + {C}_{-}^{P} )}_{\begin{matrix}right \\ comb\end{matrix}} ) - \\ ( \begin{matrix}{( \frac{2 N β ɛ h ( L - {gap}_{1} )}{g} + {C}_{-}^{P} )}_{\begin{matrix}left \\ comb\end{matrix}} - \\ {( \frac{2 N β ɛ h ( L + {gap}_{1} )}{g} + {C}_{-}^{P} )}_{\begin{matrix}right \\ comb\end{matrix}}\end{matrix} ) \\ = \frac{- 4 N β ɛ h ( {gap}_{1 , layout} - Δ gap )}{g} ,\end{matrix} \qquad ( 1 )$$

where define Δgap=gap₁−gap_{1,layout}, and parasitics cancel. Similarly, closing the second gap yields

$$Δ {C}_{2} = \frac{4 N β ɛ h ( n {gap}_{1 , layout} - Δ gap )}{g} . \qquad ( 2 )$$

The unknowns are eliminated by taking the ratio

$$\frac{Δ {C}_{1}}{Δ {C}_{2}} = - \frac{{gap}_{1 , layout} - Δ gap}{n {gap}_{1 , layout} - Δ gap} , \qquad ( 3 )$$

which allows accurately measured change in gap stop from layout to fabrication as:

$$Δ gap = \frac{n Δ {C}_{1} + Δ {C}_{2}}{Δ {C}_{1} + Δ {C}_{2}} {gap}_{1 , layout} . \qquad ( 4 )$$

Once ΔC₁ and Δgap are measured, the comb drive displacement is calibrated. The comb drive constant Ψ can be determined as:

$$Ψ ≡ \frac{Δ {C}_{1}}{{gap}_{1 , layout} - Δ gap} = \frac{Δ {C}_{1}}{{gap}_{1}} , \qquad ( 5 )$$

where Ψ is the quantity 4 Nβεh/g expressed in the previous section. That is, Ψ is the ratio of the change in capacitance to traverse a gap-stop distance to that distance. This ratio is applies to any intermediate displacement x≦gap₁ and corresponding change in capacitance ΔC. The displacement may be computed as:

$$Ψ ≡ \frac{Δ {C}_{1}}{{gap}_{1}} = \frac{Δ C}{Δ x} ⇒ Δ x = {Ψ}^{- 1} Δ C . \qquad ( 6 )$$

Comb drive force can next be calibrated. Electrostatic force is defined as

$$F ≡ \frac{1}{2} \frac{\partial C}{\partial x} {V}^{2} . \qquad ( 7 )$$

When applied to comb drives within their large linear operating range, the partial derivatives in (7) can be replaced by differences,

$$F = \frac{1}{2} \frac{ Δ C}{Δ x} {V}^{2} = \frac{1}{2} Ψ {V}^{2} \qquad ( 8 )$$

where the measured comb drive constant from (5) has been substituted. It is useful to note that the force in (8) accounts for fringing fields and accommodates some non-ideal asymmetric geometries in the comb drive due to process variations.

System stiffness can then be calibrated. From measurements of comb drive displacement and force, system stiffness is defined as their ratio as

$$k ≡ \frac{F}{Δ x} = \frac{1}{2} {Ψ}^{2} \frac{{V}^{2}}{Δ C} \qquad ( 9 )$$

which is able to account for large linear deflections. That is, the quantity V²/AC in (9) is nearly constant for small deflections, but is expected to increase for large deflections.

Uncertainties accompany all measurements, yet reporting uncertainties with measurements are noticeably lacking in micro and nanoscale peer reviewed literature. Their absence is usually due to difficult or impractical metrological methods.

One method for measuring uncertainties is done by taking a multitude of measurements and computing the standard deviation in measurement from the computed average. As the number of measurements increase, the smaller the standard deviation becomes. If taking a large number of measurements is impractical, a more efficient method of measuring uncertainties due to a single measurement can be used as follows.

With respect to the above analyses, electrical uncertainties in the measured capacitance δC and voltage δV produce corresponding mechanical uncertainties in displacement δx, force δF, and stiffness δk. To determine such uncertainties, all quantities of capacitance and voltage can be rewritten in the above analyses as ΔC→ΔC+δC and ΔV→ΔV+δV. The first order terms of their multivariate Taylor expansions can then be identified as the mechanical uncertainties. For instance, the uncertainty in displacement δx of a single measurement is the first order term of the Taylor expansion of (6) about δC. As a result,

$$δ x = ( {gap}_{1 , layout} ( 1 - n ) \frac{Δ {C}_{1} + Δ {C}_{2} - 2 Δ C}{{( Δ {C}_{1} + Δ {C}_{2} )}^{2}} ) δ C \qquad ( 10 )$$

where the parenthetical coefficient of δC is the sensitivity ∂Δx/∂δC. Similarly, the uncertainties can be found in force δF and stiffness δk as

$$\begin{matrix} δ F = ( \frac{{V}^{2}}{{gap}_{1 , layout} ( 1 - n )} ) δ C + ( \frac{( Δ {C}_{1} + Δ {C}_{2} ) V}{{gap}_{1 , layout} ( 1 - n )} ) δ V & ( 11 ) \\ and & \\ δ k = ( \frac{( Δ {C}_{1} + Δ {C}_{2} ) ( Δ {C}_{1} + Δ {C}_{2} - 4 Δ C ) {V}^{2}}{2 {( n - 1 )}^{2} Δ {C}^{2} {gap}_{1 , layout}^{2}} ) δ C + ( \frac{{( Δ {C}_{1} + Δ {C}_{2} )}^{2} V}{{( n - 1 )}^{2} Δ C {gap}_{1 , layout}^{2}} ) δ V & ( 12 )\end{matrix}$$

where the parenthetical coefficients of δC and δV are the respective sensitivities.

AFM calibration can be performed with a MEMS device such as that shown in FIG. 1. For example, AFM displacement can be calibrated.

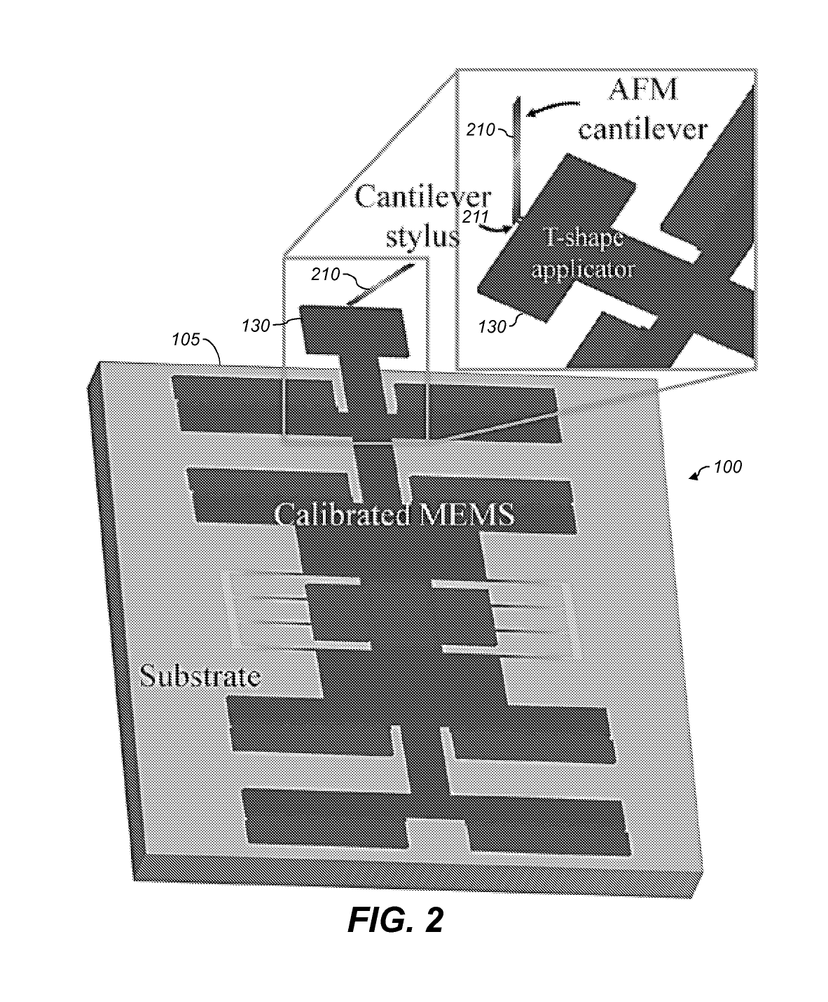

FIG. 2 is a perspective of an exemplary application of the calibratable MEMS 100 (with substrate 105) to calibrate the displacement and stiffness of an atomic force microscope. Since the MEMS 100 is calibrated in plane (as discussed above), the sensor 100 is positioned vertically underneath the AFM cantilever 210. In a vertical orientation, a thick sidewall of the SOI device layer is used as the surface with which the AFM cantilever stylus 211 will physically interact. A backside etch can be performed to expose the MEMS T-shaped applicator 130.

In various aspects of AFM calibration, the calibrated MEMS 100 can be used as an accurate and practical way to calibrate an AFM. Since the device is calibrated for in-plane operation, the sidewall of the device is used as the line of action. By placing the MEMS chip carrying sensor 100 vertically underneath the AFM cantilever stylus 211, the chip can be probed with the AFM. The AFM displacement and stiffness can be calibrated by relating the interaction displacement and force measurements of the MEMS sensor 100 against corresponding AFM output readings.

The AFM cantilever displacement can be calibrated as follows in various aspects. AFM cantilever 210 is configured to press vertically downward upon the calibrated MEMS. This action will result in an initial deflection in the flexures and comb drive of the MEMS, and a corresponding deflection of the cantilever and its beam of light of the AFM.

From this initial state, the reading of the photodiode voltage Uᵢₙᵢₜᵢₐₗ is noted, and a voltage V is applied to the MEMS comb drive 120 (FIG. 1) so that it will deflect upwards against the AFM cantilever 210. Upon static equilibrium, a final reading of the photodiode is notated U_{final}, and the deflection Δx of the comb drive is capacitively measured using (6) (i.e., after calibration of sensor 100 using the two gaps). The optical level sensitivity (OLS) is measured as

$$Θ = \frac{Δ U}{Δ x} {\vert}_{calibration} . \qquad ( 13 )$$

where Δx=Δx_{AFM} in (13) because the AFM base and MEMS substrate are fixed with respect to each other. It should be noted that AFM base or MEMS substrate is not fixed during the initial engagement as the two devices are brought into contact by a piezoelectric stage or other mechanism. For arbitrary AU, calibrated measurements of AFM cantilever displacements may be determined by

Δx_{AFM}=Θ⁻¹ΔU. (14)

The uncertainty in AFM displacement or stiffness may be determined by either of the two methods mentioned in Section 2.5.

The AFM cantilever stiffness can be calibrated, e.g., as follows. Given a measurement of AFM cantilever displacement (14) from an initial photodiode reading of initial U to a final reading of final U, the AFM cantilever stiffness can be measured as

$${k}_{AFM} = \frac{k Δ x}{Δ {x}_{AFM}} \qquad ( 15 )$$

where Δx and k of the MEMS are measured by (6) and (9). Here Δx≠Δx_{AFM}, unlike in (13), because the AFM base and MEMS substrate are moving with respect to each other during this interaction. In (15), the AFM and MEMS interaction forces are static equilibrium, and are equal and opposite, kΔx=k_{AFM}ΔX_{AFM}.

Various aspects of self-calibratable MEMS described herein advantageously permit calibration of an AFM cantilever displacement and stiffness. A MEMS sensor design and a method of application are described. Measurement uncertainties using the method are identifiable and are easily determined. Measurement accuracy is achieved by eliminating unknowns and implementing accurate measurements of force, displacement, and stiffness.

Various aspects relate to a gravimeter on a chip. In the present disclosure an arrangement of a novel gravimeter on a chip is disclosed. A gravimeter is a device used to measure gravity or changes in gravity. There are several kinds of conventional gravimeters: pendulum, free falling body, and spring gravimeters. They are all large, expensive, delicate, and require an external reference for calibration. One novel aspect of the gravimeter of the present disclosure was its micro-scaled size which increases portability, robustness, and lowers it costs; and its ability to self-calibrate on chip, which increases its autonomy. Gravimeters are often used in geophysical applications such as measuring gravitational fields for navigation, oil exploration, gravity gradiometry, earthquake detection, and possible earthquake prediction. Precisions of such gravimetry can require measurement uncertainties on the order of 20 μGal (1 Gal=0.01 m/s²). Various aspects described in the present disclosure provide self-calibration methods of micro electromechanical systems (MEMS) gravimeters capable of achieving accuracy and precision needed for use as a gravimeter or sub-micro-G accelerometer. For practical reasons, various aspects of MEMS designs described herein adhere to design constraints of a standard silicon on insulator (SOI) foundry process.

A gravimeter is a device used to measure gravity or changes in gravity. They are often referred to absolute and relative gravimeters respectively. Gravimeters have found application in geophysical and metrological areas such in navigation, oil exploration, gravity gradiometry, earthquake detection, and possible earthquake prediction. Measurement resolution that is often required in the above geophysical applications to resolve spatial gravity variations is ˜20 μGal=20×10⁻⁸ m/s². However, the time rate of gravitational change for many crustal deformation processes is on the order of 1 μGal per year. Gravimetry is also used in a number of metrological measurements such as the calibrations of load cell for mechanical force standards. Desirable attributes for gravimeters are smaller size, lower cost, increased robustness, and increased resolution. Decreasing their size increases their portability. Lowering their costs allows a larger number of them to be deployed simultaneously for finer spatial resolution. Improving their robustness to changes in temperature, age, and handling improves their reliability or repeatability. And improved accuracy and resolution increase confidence in measurement.

Various gravimeters are disclosed here that can be about a 100 times smaller (meter-size to centimeter-size) than prior gravimeters, 1000 times lower in cost ($500 k-$100 k to ˜$50), just as accurate and precise, and advantageously adapted to self-calibrate at any desired moment. Micro-fabrication reduces the size and costs of such a device by being able to batch fabricate a multitude of microscale devices simultaneously. The self-calibration feature allows the devices to recalibrate after experiencing harsh environmental changes or long-term dormancy.

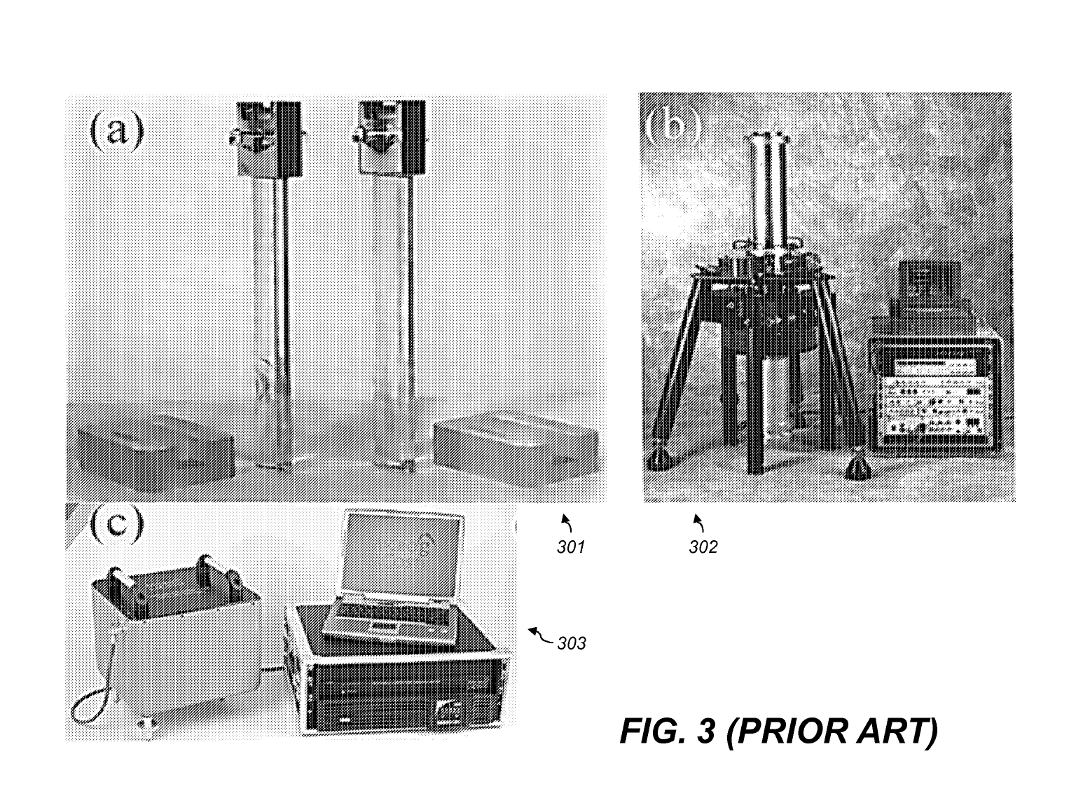

FIG. 3 shows representations of photographs of various conventional gravimeters. A pendulum gravimeter (representation 301) is used to measure absolute gravity by measuring its length, maximum angle, and period of oscillation. Its accuracy depends on the external calibration of such quantities. A free falling body (or “free fall”) gravimeter (representation 302) is used to measure absolute gravity by measuring the acceleration of a free falling mirror in a vacuum by measuring the time for laser pulses to return from the falling mirror. It requires external calibration of the laser pulse timing system. A spring gravimeter (representation 303) is used to measure relative gravity by using a spring supported mass to measure a change in static deflection between a reference gravitational position and a test gravitational position. It requires external calibration of spring stiffness, proof mass, and displacement.

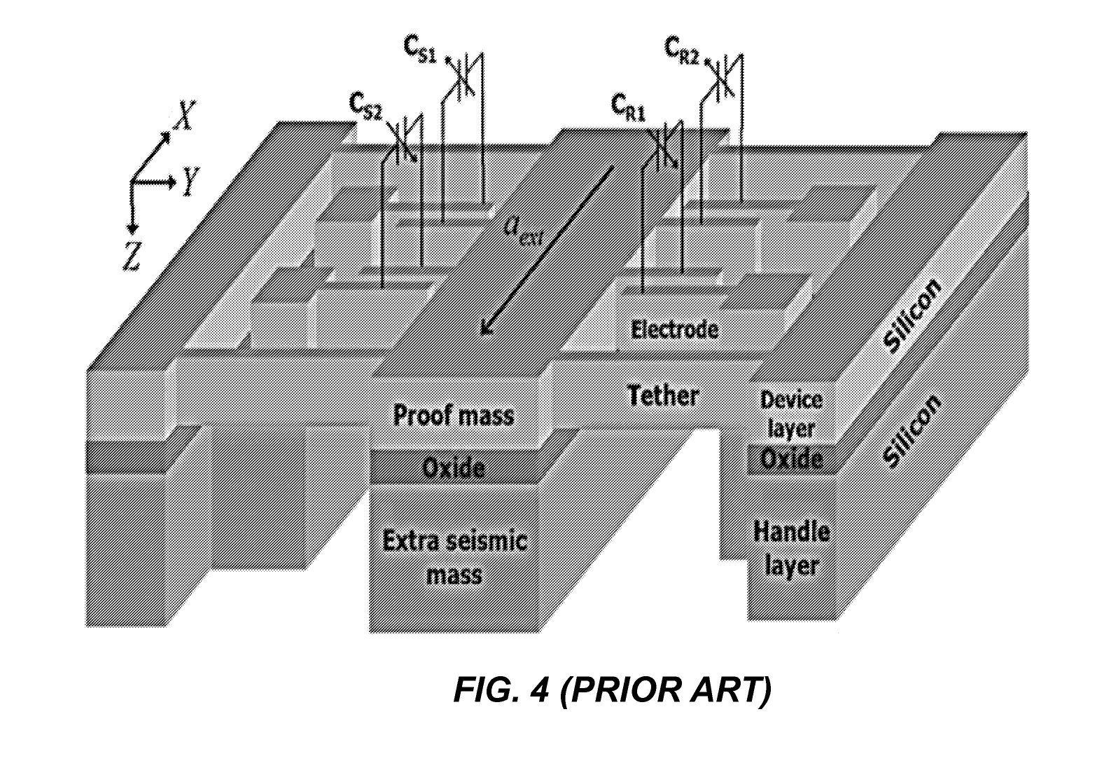

FIG. 4 shows a perspective of a conventional sub-micro-G accelerometer, a microscale device for measuring sub-micro-G accelerations (<μG=μ9.80665 m/s²). It requires the external calibration due to a known acceleration. In contrast, with respect to calibration, a MEMS device that is able to measure its own stiffness, displacement, and mass is described herein and is useful for absolute or relative gravimetry, or sub-micro-G accelerometry. Various nomenclature is given in table 2.

TABLE 2
NOMENCLATURE

| | |
|---|---|
| h | Thickness of the device layer |
| | (unknown) |
| g | Gap between comb fingers |
| | (unknown) |
| e | Permittivity of the medium |
| | (unknown) |
| b | Capacitance correction factor |
| | (unknown) |
| L | Initial finger overlap (unknown) |
| C, C^{P} | Capacitance (measured) |
| Δ, δ | Difference and uncertainty |
| | (measured) |
| x | Comb drive displacement |
| | (measured) |
| F | Comb drive force (measured) |
| k | System stiffness (measured) |
| gap | Gap stop size (measured) |
| Ψ | Comb drive constant (measured) |
| Δgap | Layout-to-fabrication (measured) |
| V | Applied voltage (known) |
| N | Number of comb fingers (known) |
| n | n = gap_{2,layout}/gap_{1,layout} ≠ 1 |
| | (known) |
| gap_{layout} | Layout gap (known) |

Various aspects of self-calibration described herein related to change from layout to fabrication. Electro micro metrology (EMM) is an accurate, precise, and practical method for extracting effective mechanical measurements of MEMS. A method of EMM begins by using two unequal gaps to determine the difference in gap geometry between layout and fabrication. These gap stops establish a means of equating a well-defined distance in terms of change in capacitance.

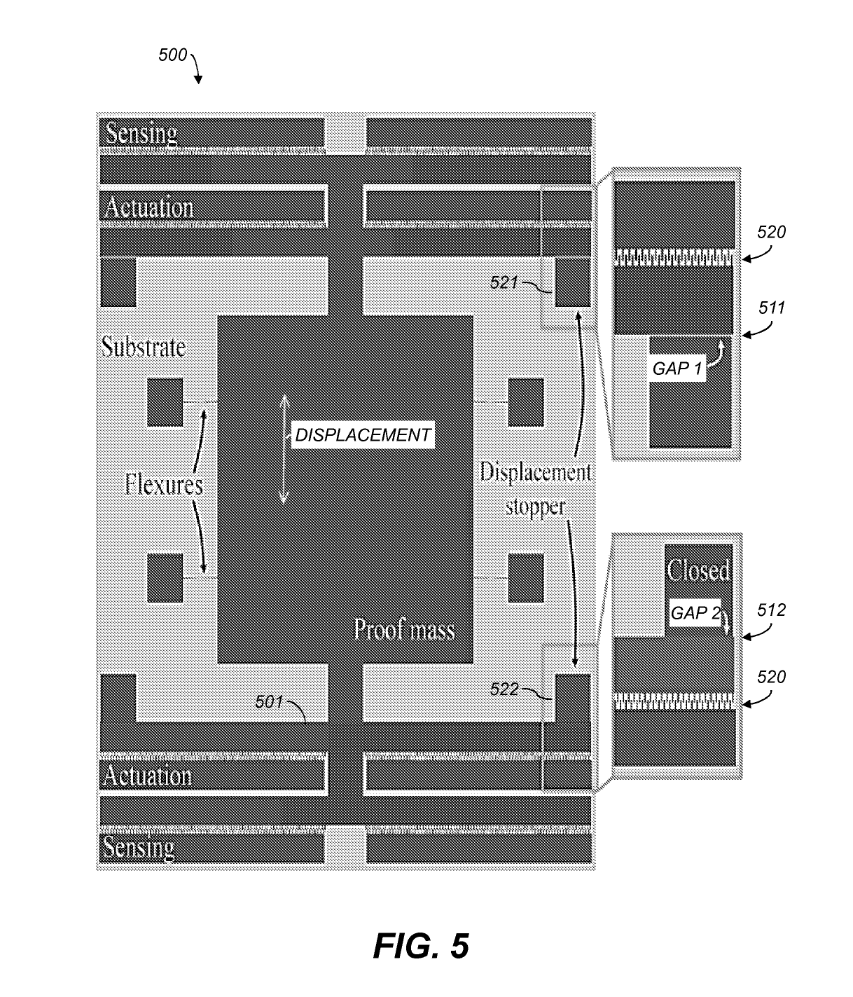

FIG. 5 shows a layout schematic of a self-calibratable MEMS gravimeter 500 according to various aspects, with respective insets for gaps 511, 512. The two unequal gaps 511, 512 are related by gap_{2,layout}=n gap_{1,layout}. They are used to provide two useful measurements to determine the unknown properties listed in Table 2 as follows. Displacement stoppers 521, 522 are arranged to form gaps 511 (gap1), 512 (gap2) respectively in relationship to actuator 501. In the example shown, actuation comb drives 520 have closed gap2 (gap 512). The substrate underneath the proof mass can be backside-etched to release the proof mass. The design can adhere to, e.g., design rules for the SOIMUMPs process.

Using differential capacitive sensing, measurements at zero-state and upon closing gap 511 and gap 512 by applying enough actuation, voltage may be expressed as:

ΔC₁=−4Nβεh(gap_{1,layout}+Δgap)/g, (16)

defining Δgap≡gap₁−gap_{1,layout}; parasitics cancel in the difference. Similarly, closing the second gap yields

ΔC₂=4Nβεh(ngap_{1,layout}+Δgap)/g. (17)

The unknowns are eliminated by taking the ratio of (16) to (17) and solve for the measurement of the change in gap-stop from layout-to-fabrication as

Δgap=−gap_{1,layout}(nΔC₁+ΔC₂)/(ΔC₁+ΔC₂). (18)

Displacement, stiffness, and mass can then be calibrated.

Once ΔC₁ and Δgap are measured, the comb drive is calibrated. The comb drive constant is measured as

Ψ≡ΔC₁/(gap_{1,layout}+Δgap)=ΔC₁/gap₁, (19)

where Ψ is the quantity 4Nβεh/g expressed above.

Regarding displacement, Ψ is the ratio of the change in capacitance to traverse a gap-stop distance to that distance. This ratio can be applied to any intermediate displacement x≦gap₁ and a corresponding change in capacitance ΔC. The displacement can be measured based on

Ψ≡ΔC₁/gap₁=ΔC/Δx [symbol] Δx=Ψ⁻¹ΔC. (20)

Regarding electrostatic force, when applied to comb drives within their large linear operating range, partial derivatives in the electrostatic-force equation can be replaced by differences. The electrostatic force is measured as

F≡½V²∂C/∂x=½V²ΔC/Δx=½V²Ψ. (21)

where the measured comb drive constant from (19) has been substituted. The force in (21) accounts for fringing fields and accommodates some non-ideal asymmetric geometries in the comb drive due to process variations.

Regarding stiffness, from measurements of displacement and force, system stiffness is defined as their ratio as

k≡F/Δx=0.5Ψ²V²/ΔC (21B)

which is able to account for large nonlinear deflections. The quantity V²/AC in (21B) is nearly constant for small deflections, but is expected to increase for large deflections.

Mass. From measurements of stiffness from (21B) and resonance ω₀, system mass can be measured as

m=k/ω₀², (22)

where ω₀ is not the displacement resonance that is affected by damping, but the velocity resonance that is independent of damping and equal to the undamped displacement frequency.

One method for measuring uncertainties is done by taking a multitude of measurements and computing the standard deviation in measurement from the computed average. As the number of measurements increase, the smaller the standard deviation becomes. If taking a large number of measurements is impractical, a more efficient method of measuring uncertainties due to a single measurement can be used which is described below.

With respect to the above analyses, electrical uncertainties in the measured capacitance δC and voltage δV produce corresponding mechanical uncertainties in displacement δx, force δF, mass δm, and stiffness δk. To determine such uncertainties, all quantities of capacitance can be rewritten and voltage in the above analyses as ΔC→ΔC+δC and ΔV→ΔV+δV. The first order terms of their multivariate Taylor expansions as the mechanical uncertainties can then be identified. The uncertainties in displacement, force, stiffness, and mass are:

$$\begin{matrix} δ x = ( {gap}_{1 , layout} ( 1 - n ) \frac{Δ {C}_{1} + Δ {C}_{2} - 2 Δ C}{{( Δ {C}_{1} + Δ {C}_{2} )}^{2}} ) δ C & ( 23 ) \\ δ F = ( \frac{{V}^{2}}{{gap}_{1 , layout} ( 1 - n )} ) δ C + ( \frac{( Δ {C}_{1} + Δ {C}_{2} ) V}{{gap}_{1 , layout} ( 1 - n )} ) δ V & ( 24 ) \\ δ k = ( \frac{- ( Δ {C}_{1} + Δ {C}_{2} ) ( Δ {C}_{1} + Δ {C}_{2} - 4 Δ C ) {V}^{2}}{2 {( n - 1 )}^{2} Δ {C}^{2} {gap}_{1 , layout}^{2}} ) δ C + ( \frac{{( Δ {C}_{1} + Δ {C}_{2} )}^{2} V}{{( n - 1 )}^{2} Δ C {gap}_{1 , layout}^{2}} ) δ V & ( 25 ) \\ and & \\ δ m = \frac{1}{{ω}_{0}^{2}} δ k + \frac{2 k}{{ω}_{0}^{3}} δ ω . & ( 26 )\end{matrix}$$

Performance predictions of a gravimeter on a chip are now discussed. The EMM results above can be used as a design factor in predicting the desired resolution of a MEMS gravimeter. That is, the necessary uncertainties in capacitance, voltage, and frequency can be identified to know the precision in the device's measurement of gravitational acceleration. Flexure length can then be parameterized. Other parameters such as mass, number of comb fingers, finger overlap, flexure width, layer thickness, etc., can also affect precision. In an example, the following parameters can be chosen: 1000 comb fingers total, 2 μm gap between each finger, 2 μm flexure width, 3500 μm-squared proof mass, and single crystal silicon material.

Regarding design issues, besides the abovementioned parameters, other issues that can be considered are the sizes of the gap-stops, the range of gravitational forces, and the comb drive levitation effect.

Gravitational acceleration acting on one of the MEMS gravimeter designs, according to the present disclosure, is identified in FIG. 5 (“DISPLACEMENT”). The constraints on the geometry and material properties of the MEMS can follow the 25 μm-thick SOIMUMPs design rules. The anchors near the comb drives (e.g., displacement stoppers 521, 522) provide the required gap-stops for self-calibration as discussed above. The size of these gaps is larger than the normal operating displacements due to the expected range of gravitational forces. The gaps can be sized so large that an unusually large voltage is not required to close and calibrate the device.

For the type of EMM analysis presented above, the translation of the comb drive remains in-plane. Comb drive levitation can cause a slight out-of-plane deflection. Such levitation is produced when there is an asymmetric distribution of surface charge about the comb fingers. This is usually due to the close proximity of the underlying substrate. In various aspects, a backside etch is implement underneath comb drives to reduce this levitation effect.

Results. To determine the uncertainty in measurement of the MEMS gravimeter, measurements are expressed as follows. Nominal measurement of gravitational acceleration is g=kx/m. Uncertainty in measurement yields

g+δg=(k+δk)(x+δx)/(m+δm). (26B)

Substituting uncertainties (23), (25), (26), a multivariate Taylor yields

$$δ g = ( \frac{G g}{2 {gap}_{1} h ( n - 1 ) N ɛ} - \frac{g E {w}^{3}}{N ɛ m {L}^{3}} ) δ C + ( \frac{G}{{L}^{3 / 2}} \sqrt{\frac{m}{E {w}^{3} h}} ) δ ω \qquad ( 27 )$$

which shows that the resolution of the gravitational acceleration depends on the uncertainties of δC and δω.

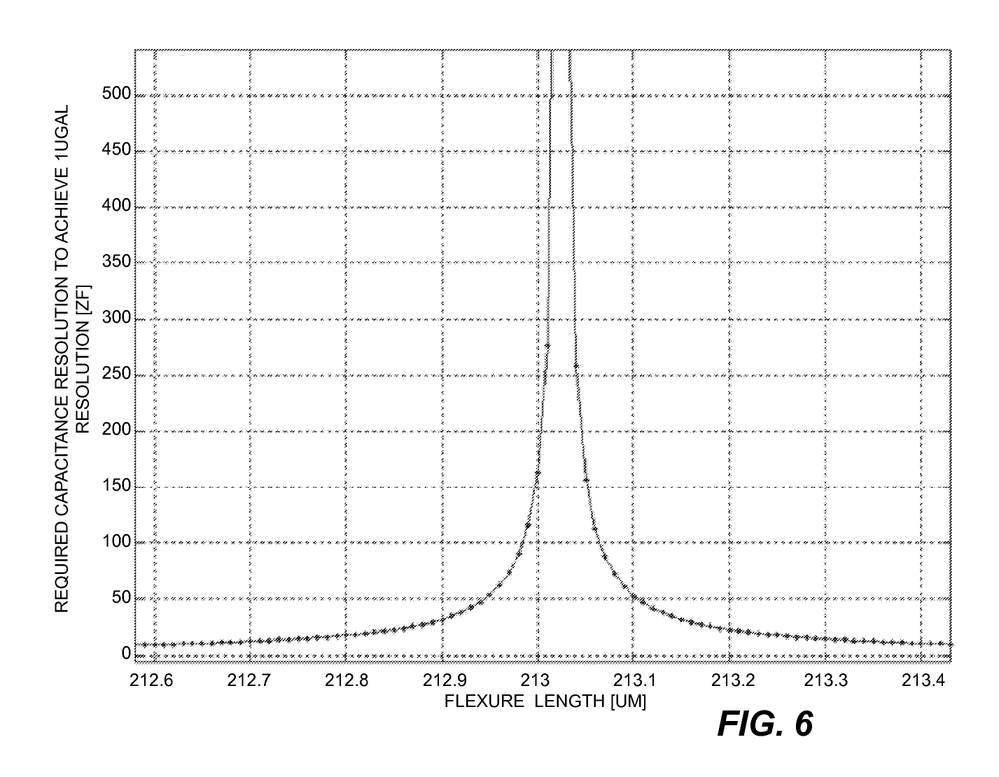

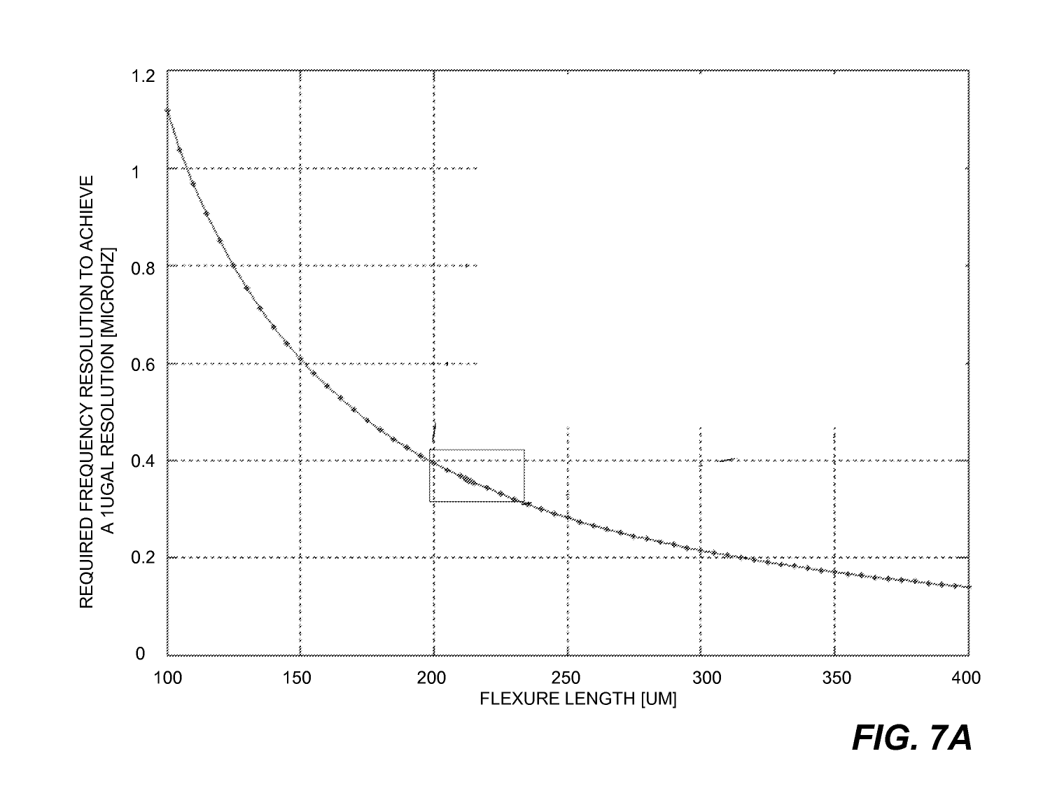

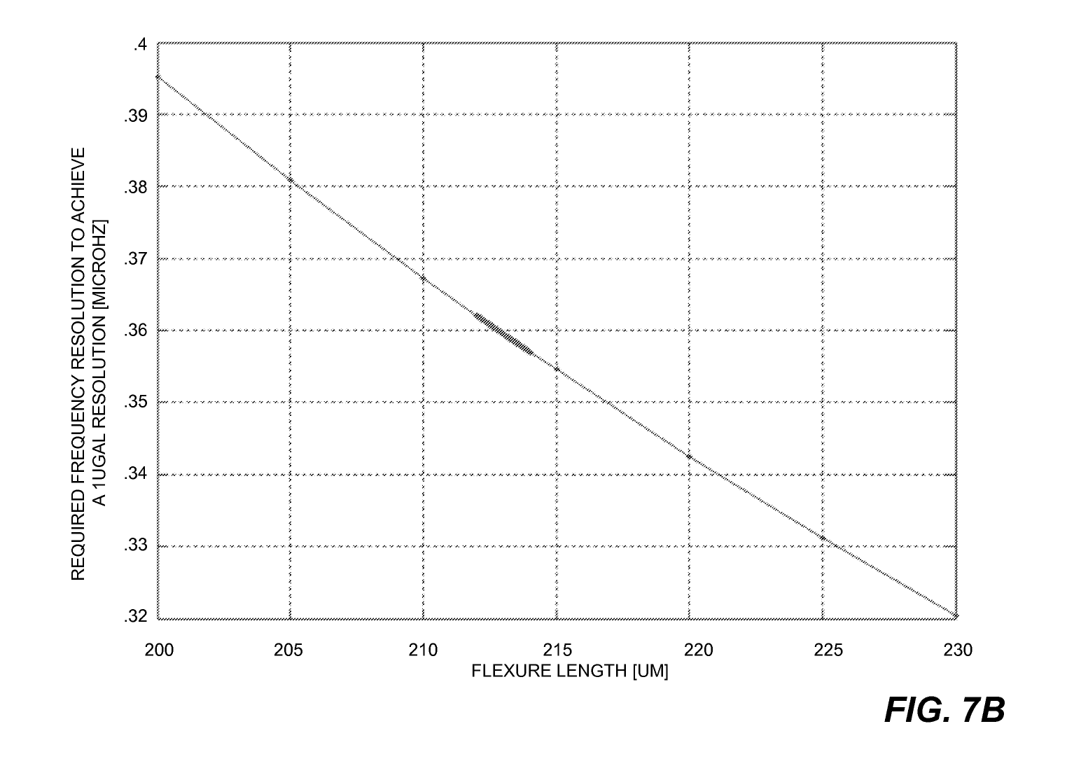

In an example of (27), typical measurement values are used for the following quantities: stiffness k=4Ehw³/L³ based on flexure length L that is used to sweep below, mass m=density×volume, x=mg/k, ΔC based on x, and ω₀ from (22). As previously mentioned a 1-20 μGal resolution is desirable. By constraining (27) such that δg=1 μGal, a simulation can be performed. In FIGS. 6 and 7, δC and δω, respectively, are plotted as functions of flexure length L (L changes stiffness).

FIG. 6 shows simulated uncertainty in capacitance δC as a function of flexure length L. The y-axis (δC) ranges from 0 to 575 zeptofarads, and the x-axis (L) ranges from 212.6 to 213.4 microns. Specifically, the Y-axis shows the required capacitance resolution to achieve 1 μGal resolution. As shown, the effect of uncertainty in capacitance is greatly reduced at the peak at approximately L=213.023 μm. However, the peak occurs over a small range <0.1 microns, which does not allow for much process variation in geometry. Widening this width of this curve and or creating designs that are more insensitive to process variation can be advantageous. It may be possible through design to eliminate the sensitivity to uncertainty in capacitance. This is seen as the peak in the plot, were the uncertainty can be large; and can be seen in (27) within the parenthetical expression which can possibly cancel depending on the choice of design parameters.

FIGS. 7A-B show simulated uncertainty in frequency δω as a function of flexure length L. In FIG. 7A, the y-axis (δω) ranges from 0 to 1.2 micro-Hertz (μHz), and the x-axis (L) ranges from 100 to 400 microns. FIG. 7B is an inset of the boxed area in FIG. 7A. FIG. 7B has an x-axis from 200 μm to 230 μm, and shows a highlighted range (thick trace) from 212.6 to 213.4 microns. The Y-axis of FIG. 7B extends from 0.3241 z to 0.441 z. The Y-axes of both the plot (FIG. 7A) and the inset (FIG. 7B) show the required frequency resolution to achieve 1 μGal resolution. As shown in FIG. 7, the uncertainty in frequency plays an important role. Since the sensitivity with respect to frequency is large, the uncertainty in frequency should be small such that a δg=1 μGal resolution is achieved. In the particular simulated test case of FIG. 7, a resolution of about 1 to 10 μHz can be used.

Various aspects of a gravimeter arrangement on a chip are described above. A test case is described above according to which uncertainties in electrical measurands are used to achieve the desired uncertainty in gravitational acceleration. The uncertainty due to voltage and capacitance can be eliminated. This leaves the uncertainty in frequency, which can be on the order of micro-Hertz.

Various aspects described herein relate to a self-calibratable inertial measurement unit. Various methods described herein permit an inertial measurement unit (IMU) to self-calibrate. Self-calibration of IMU can be useful for: sensing accuracy, reducing manufacturing costs, recalibration upon harsh environmental changes, recalibration after long-term dormancy, and reduced dependence on global positioning systems. Various aspects described herein, unlike prior schemes, offer post-packaged calibration of displacement, force, system stiffness, and system mass. An IMU according to various aspects includes three pairs of accelerometer-gyroscope systems located within the xy-, xz-, and yz-planes of the system. Each pair of sensors oscillates 90 degrees out of phase for continuous sensing during turning points of the oscillation where velocity goes to zero. An example of self-calibration of a prototype system is discussed below, as are results of modeling IMU accuracy and uncertainty through sensitivity analysis. Various aspects relate to a self-calibratable gyroscope, a self-calibratable accelerometer, or an IMU system configuration.

IMUs (inertial measurement units) are portable devices that are able to measure their translational and rotational displacements and velocities in space. Translational motion is usually measured with accelerometers, and rotational motion is usually measured with gyroscopes. IMUs are used in military and civil applications, where position and orientation information is needed [A1]. Advancements in micro electro mechanical system (MEMS) technology have made it possible to fabricate inexpensive accelerometers and gyroscopes, which have been adopted into many applications where traditionally inertial sensors have been too costly or too large [A2].

IMU accuracy, cost, and size are often critical factors in determining their use. Due to various sources of initial errors and accumulation of errors, an IMU is often recalibrated with the aid of global position systems. Calibration of IMU is important for overall system performance, but such calibration can be 30% to 40% of manufacturing costs [A3-A5].

Conventionally, the calibration of an IMU has been done using a mechanical platform, where the platform subjects the IMU to controlled translations and rotations [A6]. At various states, the output signals from the accelerometers and gyroscopes are observed and correlated with the prescribed inputs. However, this methodology is only as accurate at the mechanical platform, and this method treats the IMU as a black box, where the IMU's system masses, comb drive forces, displacements, stiffnesses, and other quantities that are useful for a mathematical description of its motion remain unknown.

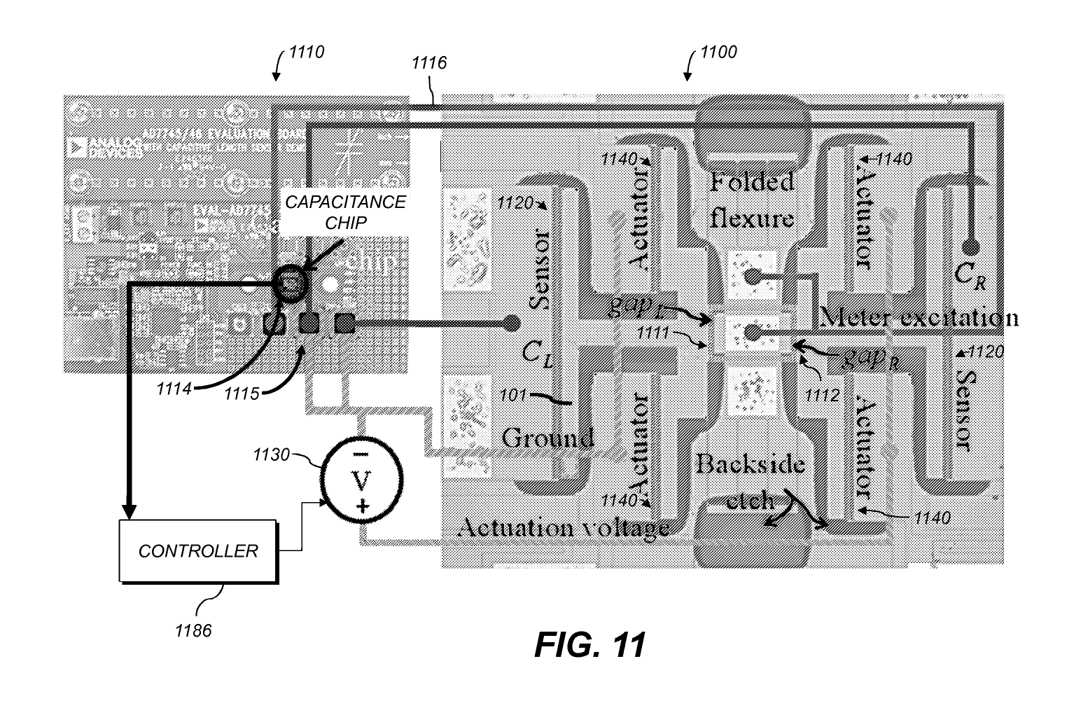

One problem for the traditional calibration scheme is that the signal outputs are often scalar, yet are determined by several unknown factors that can produce results that are not unique. That is, two more different conditions may yield the same output signal. Without knowing the physical quantities within the IMU's equation of motion, then reliable predictions, clearly identifiable improvements, and a more complete understanding of what is precisely being sensed remain uncertain. Moreover, a more complete understanding of such physical quantities can facilitate recalibration after long-term dormancy or after harsh environmental changes, such as with temperature. For example, variations in temperature can affect the geometry or stress of the sensor or its packaging. Various aspects herein include electronically-probed self-calibration technology which can be an integral part of a packaged IMU (see, e.g., controller 1186, FIG. 11). Various aspects can measure the quantities that represent the equation of motion of accelerometers and gyroscopes, and determine an experimentally-accurate compact model of the IMU. Below are described a self-calibration scheme; a system configuration that can help to eliminate the loss of sensor information due to the turning points of proof-mass oscillation where velocity is goes to zero; and analysis of an IMU test case. Various nomenclature is described in Table 3.

TABLE 3
Nomenclature

| | |
|---|---|
| β | Capacitance correction factor |
| | (unknown) |
| ε | Permittivity of the medium (unknown) |
| L | Initial finger overlap (unknown) |
| h | Layer thickness (unknown) |
| g | Gap between comb fingers (unknown) |
| fl | Layout parameter (known) |
| V | Applied voltage (known) |
| N | Number of comb fingers (known) |
| gap_{i,layout} | Layout gap for EMM (known) |
| Ψ | Comb drive constant (measured) |
| ΔCᵢ | Differential capacitance by closing the gap i (measured) |
| F | Comb drive force (measured) |
| k | System stiffness (measured) |
| Δgap | Uncertainty from layout to fabrication |
| | for EMM (measured) |

Regarding Self-Calibration of a MEMS IMU, Electro micro metrology (EMM) is an accurate, precise, and practical method for extracting effective mechanical measurements of MEMS [A7]. It works by leveraging the strong and sensitive coupling between microscale mechanics and electronics through fundamental electromechanical relationships. What results are expressions that relate fabricated mechanical properties in terms of electrical measurands.

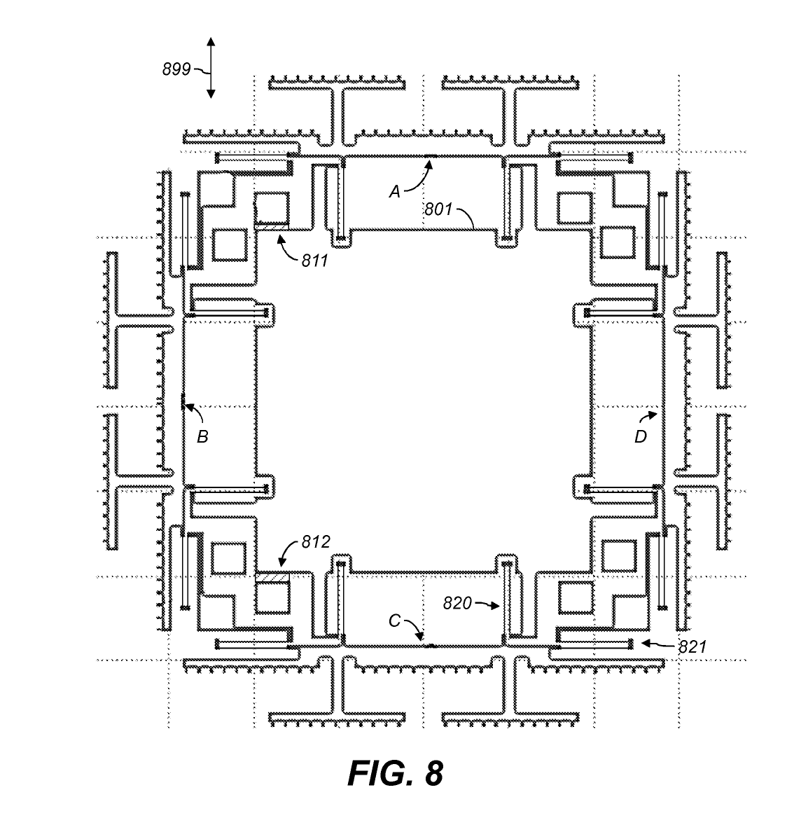

FIG. 8 shows an exemplary self-calibratable gyroscope. This MEMS gyroscope includes 2,000 comb fingers and orthogonal movable-guided flexures. These flexures allow the proof mass to translate with two degrees of freedom, and resist rotation. The set of fixed-guided flexures allows each comb drive only one degree of freedom. The magnitude and phase of the x coordinate of node C is swept from 10 k . . . 1M rad/sec. This design is modified from a design by Shkel and Trusov [A8] to include gap-stops for self-calibration of, e.g., stiffness, mass, or displacement.

FIG. 9 shows an exemplary self-calibratable accelerometer. This device is modified from a resonator by Tang [A9]. The device shown in FIG. 9 includes two asymmetrical gaps, and two sets of opposing comb drives. Each set of comb drives is a dedicated sensor or actuator.

In addition to the set of self-calibratable MEMS gyroscope and accelerometer shown in FIGS. 8 and 9, various aspects described herein can be used with many types of MEMS accelerometers and gyroscopes. Various aspects include a pre-existing design modified to integrate or include a pair of asymmetric gaps, which are used to uniquely calibrate the device. This is because no two MEMS are identical due to the culmination of fabrication process variations. Two unequal gaps are identified in FIGS. 8 and 9; these gaps enable this type of calibration. FIG. 8 shows gaps 811 and 812 and FIG. 9 shows gaps 911 and 912; the gaps are shown hatched for clarity. These two gaps are related by gap_{2,layout}=n ga_{1,layout}, where n≠1 is a layout parameter. Using differential capacitive sensing, measurements at zero state and actuated closure of gaps gap₁ and gap₂ are:

$$\begin{matrix}\begin{matrix}Δ {C}_{1} = ( \begin{matrix}{( \frac{2 N βɛ h ( L - {gap}_{1} )}{g} + {C}_{+}^{P} )}_{left comb} - \\ {( \frac{2 N βɛ h ( L + {gap}_{1} )}{g} + {C}_{-}^{P} )}_{right comb}\end{matrix} ) - \\ ( \begin{matrix}{( \frac{2 N βɛ h L}{g} + {C}_{+}^{P} )}_{left comb} - \\ {( \frac{2 N βɛ h L}{g} + {C}_{-}^{P} )}_{right comb}\end{matrix} ) \\ = - \frac{4 N β ɛ h ( {gap}_{1 , layout} + Δ gap )}{g}\end{matrix} & ( 28 ) \\ and & \\ Δ {C}_{2} = \frac{4 N βɛ h ( n \cdot {gap}_{1 , layout} + Δ gap ( 1 + σ ) )}{g} & ( 29 )\end{matrix}$$

where N is the number of comb fingers, L is the initial finger overlap, h is the layer thickness, g is the gap between comb fingers, β is the capacitance correction factor, ε is the permittivity of the medium, Δgap=gap₁−gap_{1,layout} is the uncertainty from layout to fabrication, a is the relative error (or mismatch) that accounts for non-identical process variations between the two gaps, C₊^{P} and C₋^{P} are the unknown parasitic capacitances. By taking the ratio of (1) and (2), all unknowns except Δgap are removed. Δgap can be written as:

$$Δ gap = - {gap}_{1 , layout} \frac{n \cdot Δ {C}_{1} + Δ {C}_{2}}{Δ {C}_{2} + Δ {C}_{1} ( 1 + σ )} \qquad ( 30 )$$

where the fabricated gap is now measurable as gap₁=gap_{1,layout}+Δgap; a may be ignored if mismatch is insignificant.

A comb drive constant of the given device is defined as the ratio between the gap and the change in capacitance required to traverse the gap. That is:

$$Ψ = \frac{Δ {C}_{1}}{{gap}_{1}} \qquad ( 31 )$$

where the comb drive can also be associated with the relation Ψ=4Nβεh/g in (28).

Regarding displacement, the ratio of capacitance to gap distance in (31) applies to any intermediate change in capacitance ΔC and displacement Δx<gap, since comb drives are linear between capacitance and displacement. Displacement can thus be determined using:

$$Ψ = \frac{Δ {C}_{1}}{{gap}_{1}} = \frac{Δ C}{Δ x} ⇒ Δ x = {Ψ}^{- 1} Δ C . \qquad ( 32 )$$

Electrostatic force often expressed as

$$F = \frac{1}{2} \frac{\partial C}{\partial x} {V}^{2} . \qquad ( 33 )$$

For comb drives that traverse laterally within their linear operating range, the partial derivative can be replaced by a difference, which is the comb drive constant from (31). Thus:

$$F = \frac{1}{2} \frac{\partial C}{\partial x} {V}^{2} = \frac{1}{2} Ψ {V}^{2} \qquad ( 34 )$$

It is important to note that the force in (34) accounts for fringing fields and accommodates some non ideal asymmetric geometry in the comb drive due to process variations.

From measurements of displacement and force, system stiffness can be expressed as:

$$k = \frac{F}{Δ x} = \frac{{Ψ}^{2} {V}^{2}}{2 Δ C} \qquad ( 35 )$$

which becomes nonlinear for large deflections.

From measurements of stiffness and resonance frequency ω₀, system mass can be measured as

$$m = \frac{k}{{ω}_{0}^{2}} \qquad ( 36 )$$

where ω₀ is either the velocity resonance if damping is present, or displacement resonance if the system is in vacuum.

From (31)-(36), it can be seen that comb drive constant plays an important role in the process of self calibration. From (31) it can be seen that the accuracy of comb drive constant depends on Δgap and ΔC₁. At the same time, (30) indicates that Δgap and ΔC₁ are correlated. To see the relationship clearly, an expression is derived for sensitivity and uncertainty in measurement of gap in (30) by a Taylor expansion.

The uncertainty of measuring capacitance is included into (30) by replacing instances of ΔC with ΔC±\sqrt{2}|δC|. That is, ±\sqrt{2}δC is the perturbation that results from adding independent random uncertainties in quadrature:

$$Δ C ⇒ ( {C}_{final} \pm δ {C}_{final} ) - ( {C}_{initial} \pm δ {C}_{initial} ) = ( {C}_{final} - {C}_{initial} ) \pm \sqrt{{( δ {C}_{final} )}^{2} + {( δ {C}_{initial} )}^{2}} = Δ C \pm \sqrt{2} \vert δ C \vert , \qquad ( 37 )$$

where O(δCᵢₙᵢₜᵢₐₗ)=O(δC_{final}). Substituting (37) into (38), its first order multivariate Taylor expansion about δC and σ is

$$Δ gap \pm δ gap = - {gap}_{1 , layout} \frac{n \cdot Δ {C}_{1} + Δ {C}_{2}}{Δ {C}_{1} + Δ {C}_{2}} \pm \{ \frac{\sqrt{2} {gap}_{1 , layout} ( n - 1 ) ( Δ {C}_{1} - Δ {C}_{2} )}{{( Δ {C}_{1} - Δ {C}_{2} )}^{2}} \} δ C \pm \{ \frac{{gap}_{1 , layout} ( n Δ {C}_{1} + Δ {C}_{2} )}{{( Δ {C}_{1} + Δ {C}_{2} )}^{2}} \} σ \qquad ( 38 )$$

where the first term on the right-hand side of (38) is Δgap, and the other terms represent δgap. The multiplicands in curly brackets are respectively the sensitivity in gap uncertainty to capacitance uncertainty, and the sensitivity in gap uncertainty to mismatch. discussed further below.

The self-calibratable IMU in various aspects includes three pairs of accelerometer-gyroscope systems, respectively located within the xy-, xz-, and yz-planes of the IMU. Each oscillatory system includes a neighboring copy that operates 90 degrees out of phase to counter lost information due to the turning points of proof-mass oscillation where velocity is goes to zero.

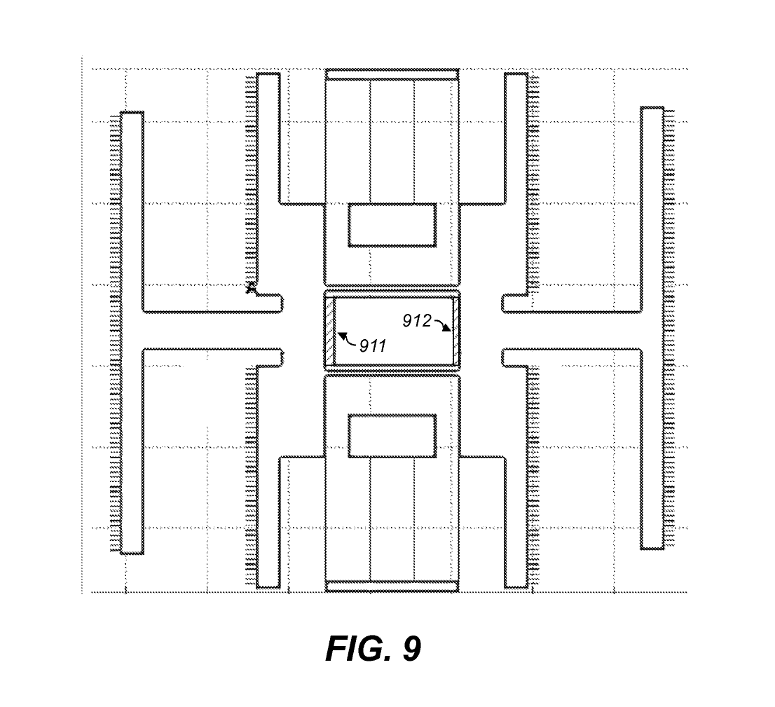

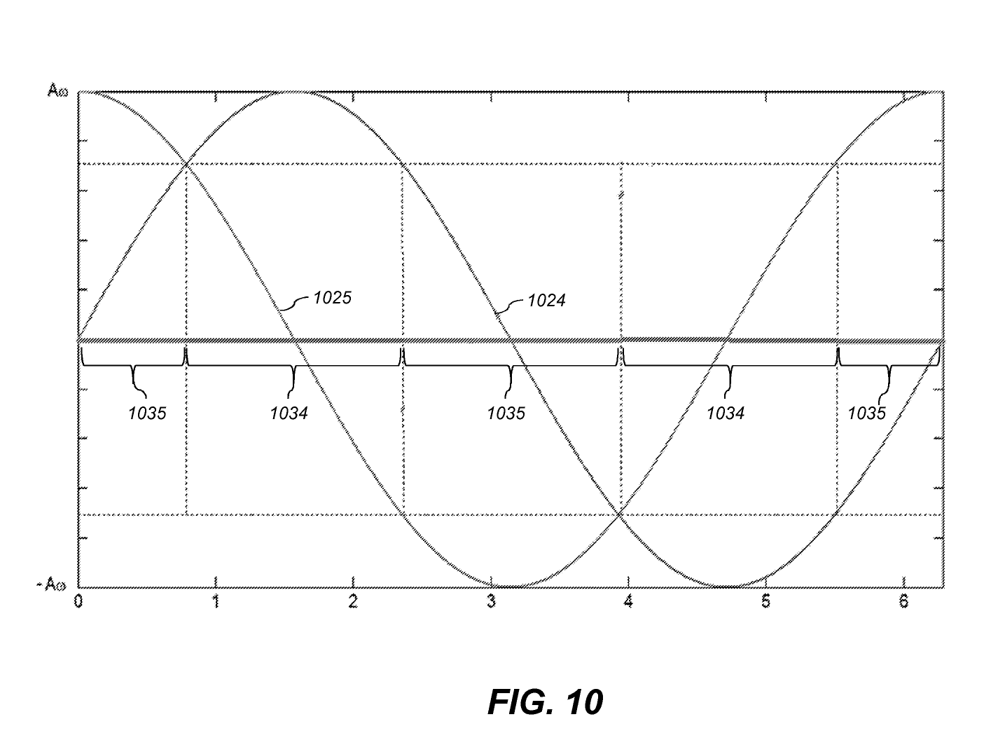

FIG. 10 is a plot showing a simulation of the velocities of exemplary proof masses. The abscissa shows ωt from 0-2π rad and the ordinate shows amplitude of velocity (m/s) from −Δω to Δω. Curve 1024 corresponds to gyroscope 1 and curve 1025 corresponds to gyroscope 2.

FIG. 10 relates to an excitation signal in a drive axis. Shown is a velocity vs. time plot representing twin gyroscopes operating 90 degrees out-of-phase. Sinusoidal curves 1024, 1025 represent the velocities of their proof masses. Ranges 1034, 1035 identify the states in time in which their respective velocities (curves 1024, 1025) are large enough to permit sensing the Coriolis force with a desired accuracy. The peak velocities are Δω. This simulation assumes that the structures are driven at or near resonance.

Considering the proportional relationship between Coriolis force and velocity, small velocities may result in an inability to resolvable Coriolis forces near the turning points of oscillation. While one proof-mass is slowing down, the other is speeding up, to that sensing the Coriolis force is maximal at all times. This configuration permits not only characterizing the mechanical quantities of the system, but also various noninertial forces, e.g., translational, centrifugal, Coriolis, or transverse forces.

An aspect of a method described herein was applied to an accelerometer with asymmetric gaps. Various aspects of methods described herein are applicable to vibratory gyroscopes.

FIG. 11 is a partially-schematic representation of images of a self-calibratable accelerometer and capacitance meter. An accelerometer was used as an example to test the process of self calibration. The accelerometer 1100 comprises 25 μm-thick SOI with 2 μm comb gaps. The accelerometer 1100 is electrically connected to an external capacitance meter [A11]. Differential sensing mode of the capacitance meter is used to reduce opposing electrostatic forces generated by the meter's sensing signal.

FIG. 11 shows capacitance meter 1110 and MEMS accelerometer 1100. Applied voltages from voltage source 1130 close gap_{R} and gap_{L} by moving movable mass 101. A capacitance chip 1114, e.g., an ANALOG DEVICES (ADI) AD7746, measures the change in capacitance in traversing the gaps 1111, 1112. Two inputs 1115 to capacitance chip 1114 are shown. As shown, the inputs are protected by ground rings. MEMS device 1100 has two sensor combs 1120 connected to respective inputs 1115, and four drive combs 1140 (“actuators”) driven by voltage source 1130. The movable mass in MEMS device 1120 is supported by two folded flexures. Capacitance chip 1114 provides an excitation signal via trace 1116 (shown schematically) for measuring differential capacitance. A backside etch is used to reduce comb drive levitation [A10].

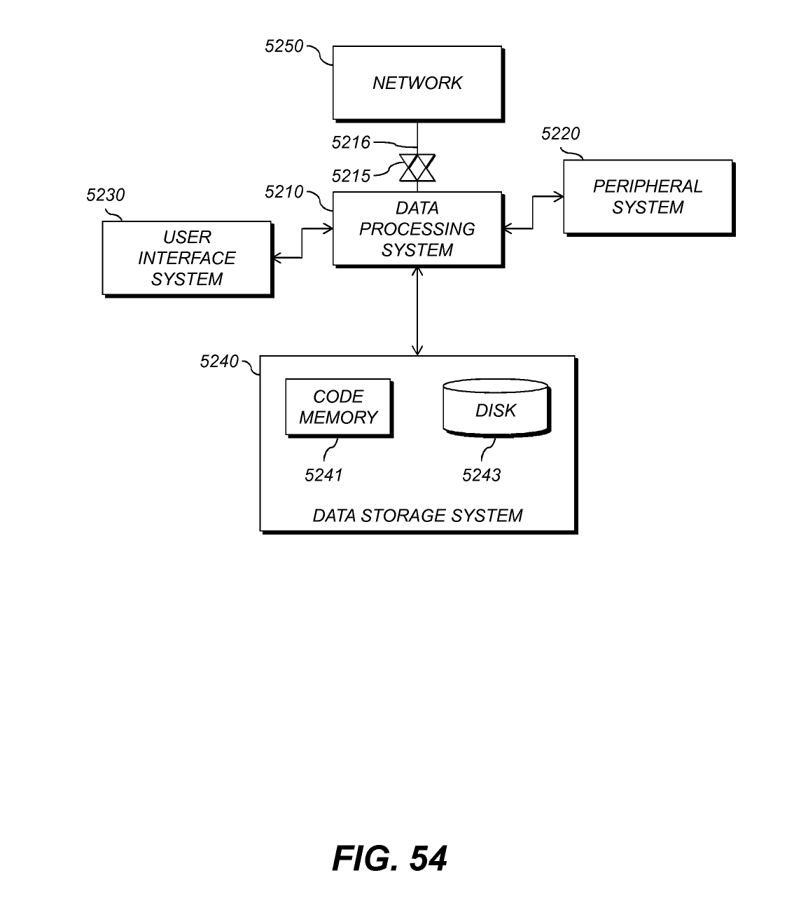

Controller 1186 can provide control signals to voltage source 1130 to operate actuators 1140. Controller 1186 can also receive capacitance measurements from capacitance chip 1114 or another capacitance meter. Controller 1186 can use the capacitance measurements to perform various computations described herein, e.g., to compute Ψ, displacement, comb-drive force, stiffness, and mass. Controller 1186, and other data processing devices described herein (e.g., data processing system 5210, FIG. 54) can include one or more microprocessors, microcontrollers, field-programmable gate arrays (FPGAs), programmable logic devices (PLDs), programmable logic arrays (PLAs), programmable array logic devices (PALs), or digital signal processors (DSPs).

In the tested self-calibratable accelerometer, parameters included left and right gaps of 2 μm and 4 μm, finger overlap of 11 μm, number of sense fingers is 90, finger width is 3 μm, and finger gap is 3 μm. At zero and gap-closed states, 300 capacitive measurements are taken with the AD7746 (5 msec each) that yields nominal capacitances, and a standard deviation of 21 aF. ADI specifies a resolution of 4 aF [A11].

Using (38), assuming σ=0, measurements of ΔC₁ and ΔC₂ were taken and it was determined that Δgap=0.150±0.001 μm. Optical and electron microscopy measurements on design 1100 were performed by refining measurement bars using monitor pixilation software. By using an experimenter's best guess at locating sidewall edges, gaps were estimated to be Δgap_{optical}=0.1±0.2 μm and Δgap_{electron}=0.19±0.07 μm. Results using EMM as described herein were within the range of results of optical and scanning electron microscopy (SEM) [A10].

Then from (31), the comb drive constant can be obtained. Then the self calibration scheme can be implemented as follows:

1) Displacement: Δx=ΔC/Ψ

2) Comb drive force: F=ΨV²/2

3) Stiffness: k=(Ψ²V²)/(2ΔC)

4) Mass: m=k/ω₀²

The uncertainties for measurements of displacement, comb drive force, system stiffness, and system mass can be obtained by performing a first order multivariate Taylor expansion as done in (38). That is, in (38) the sensitivity to capacitance error δC is on the order of 10⁸ m/F, and the sensitivity to mismatch a is on the order of 10⁻⁷ m for the tested design. Per (38), the sensitivity to capacitance also depends on design parameters.

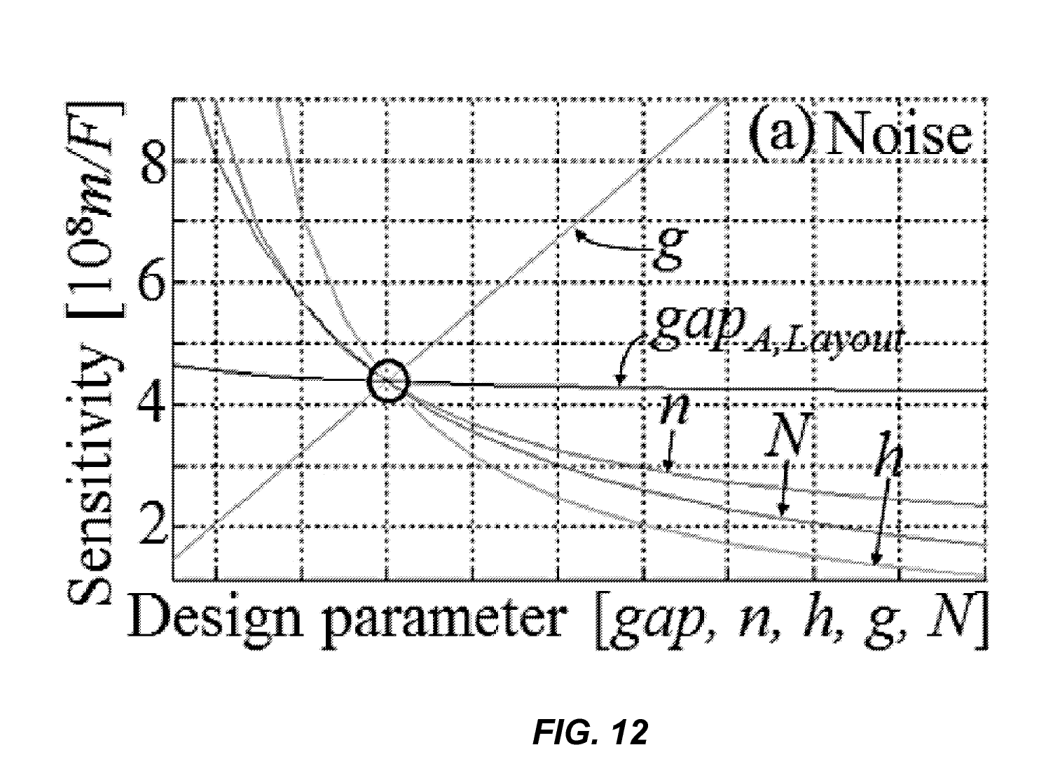

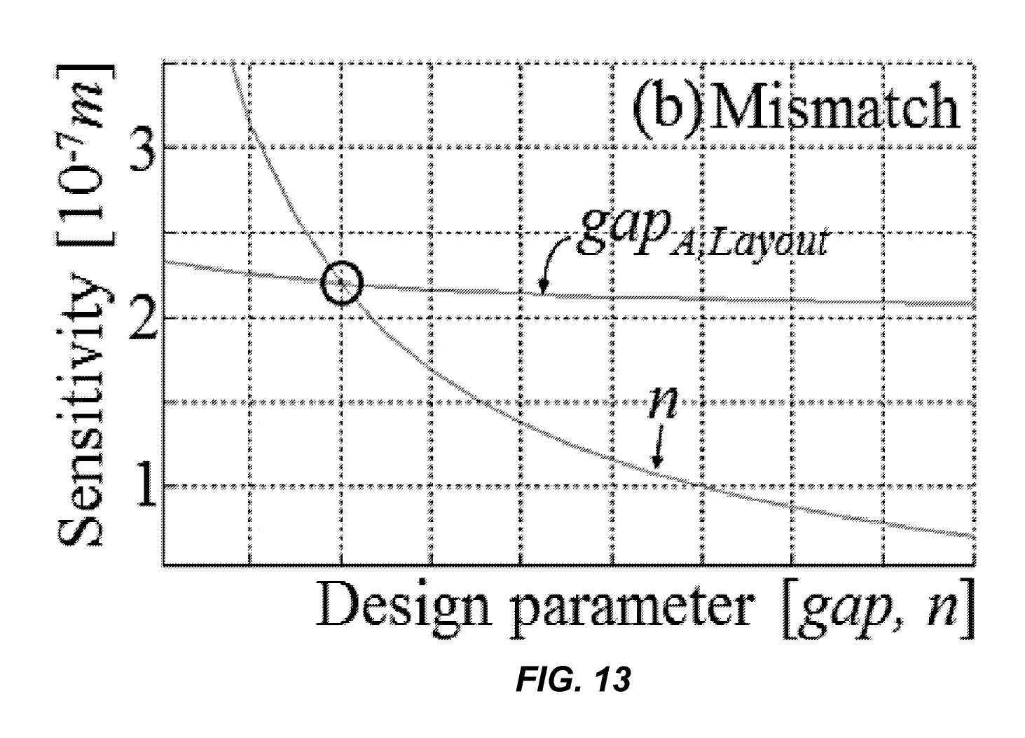

FIGS. 12 and 13 are plots of sensitivities as functions of some design parameters. E.g., by changing the design parameter n from 2 to 5, the sensitivity of the design to mismatch can reduce by an order of magnitude.

FIG. 12 shows sensitivity of sensor noise to δgap. FIG. 13 shows sensitivity of mismatch to δgap. Using (36), the sensitivities of an exemplary design are identified as circles. Holding other parameters constant, each parameter is swept as
n=[1.25 . . . 4.15]
h=[1 . . . 97]×10⁻⁶ m
N=[30 . . . 190]
g=[1 . . . 9]×10⁻⁶ m
gap_{A,layout}=[1 . . . 5]×10⁻⁶ m along the horizontal axis.

Described herein are various methods to permit IMUs to self-calibrate. Various aspects include applying enough voltage to close two unequal gaps and measuring the resulting changes in capacitances. Through this measurement, geometrical difference between layout and fabrication can be obtained. Upon the determination of fabricated gap, displacement, comb drive force, and stiffness can be determined. By measuring velocity resonance, mass can also be determined.

An IMU configuration according to various aspects includes three pairs of accelerometer-gyroscope systems located within the xy-, xz-, and yz-planes, respectively. The sensors in each pair of sensors oscillate 90 degrees out of phase with each other. This advantageously helps to counter lost information due to the turning points of proof-mass oscillation where velocity goes to zero.

Various aspects described herein relate to a self-calibratable microelectromechanical systems absolute temperature sensor. A self-calibratable MEMS absolute temperature sensor according to various aspects can provide accurate and precise measurements over a large range of temperatures.

Due to the high accuracy and precision required for some experiments and devices, such as studies involving fundamental laws or sensor drift due to thermal expansion, accurate temperature sensing is necessary. Conventional temperature sensors require factory calibration, which significantly increases the cost of manufacture. Using the equipartition theorem, nanotechnologists have long determined the stiffness of their atomic force microscope (AFM) cantilevers by measuring temperature and the cantilever's displacement. Various aspects described herein measure MEMS stiffness and displacement and determine temperature using those measurements. Various methods for accurately and precisely measuring nonlinear stiffness and expected displacement are described herein, as is an expression for quantifying the uncertainty in measuring temperature. Various nomenclature is described in Table 4.

TABLE 4
Nomenclature

| | |
|---|---|
| A | Amplitude |
| C₀ | Zero state capacitance |
| ΔC | Change in capacitance |
| ΔC_{R} | Change in capacitance to close gap_{R} |
| ΔC_{L} | Change in capacitance to close gap_{L} |
| δC | Uncertainty in capacitance |
| F | Comb drive force |
| gap_{L} | Left side gap for the test structure |
| gap_{R} | Right side gap for the test structure |
| k_{B} | Boltzmann's constant |
| k | Stiffness |
| N | Number of measurements |
| P | Area of the power spectrum |
| SD | Standard deviation |
| T | Absolute temperature |
| Tₙ | Sampling of absolute temperature |
| δT | Uncertainty in temperature |
| V | Applied voltage |
| δV | Uncertainty in voltage |
| y | Displacement |
| Ψ | Comb drive constant |
| <Y²> | Expected or mean square |
| | displacement |

Due to the temperature sensor's abundance of applications in personal computers, automobiles, and medical equipment [B1], for monitoring and controlling temperature they account for 75-80% of the worldwide sensor market [B2]. The types of techniques for measuring temperature include thermoelectricity, temperature dependent variation of the resistance of electrical conductors, fluorescence, and spectral characteristics [B3]. The most important performance metric of a temperature sensor is reproducibility in measurement. This metric is hard to achieve due to the limitations in calibrating procedures. Typically, a standard called International Temperature Scale (ITS) [B4] is followed to calibrate temperature sensors. This scale defines standards for calibrating temperature measurements ranging from 0K to 1300K, which is subdivided into multiple overlapping ranges. For applications within the temperature range of 13.8033K to 1234.93K, the standard is to calibrate against defined fixed points. Depending on the type of measurement these points can be triple-point, melting point, or freezing point of different materials that are accurately known. The limitation with these calibration standards is that the procedures are difficult, making their recalibration or batch calibration impractical.

The thermal method, based on the equipartition theorem, is commonly used to measure the stiffness of atomic force microscope (AFM) cantilevers [B5]. In the thermal method, the expected potential energy due to thermal disturbances is equated to the thermal energy in a particular degree of freedom by

½k [symbol] y² [symbol] =½k_{B}T. (39)

where k is the stiffness of the AFM cantilever, <y²> is the expected or mean square displacement, k_{B} is Boltzmann's constant (1.38×10⁻²³ NmK⁻¹), and T is absolute temperature in Kelvin. By measuring cantilever displacement and temperature, the stiffness can be determined. Due to the uncertainty in measuring displacement and temperature of the AFM cantilever, the uncertainty in measuring cantilever stiffness is about 5-10% [B6]. The problem with measuring displacement in the AFM is due to the difficulty in finding an accurate relationship between the voltage readout of the AFM's photodiode and the true vertical displacement of the cantilever. And the problem with measuring the temperature of the AFM cantilever is that it is not known if the thermometer that is nearby the cantilever is the same temperature as the AFM cantilever that is being measured. There are also decoupled mechanical vibrations between the mechanical support of the cantilever and the mechanical support of the photodiode that add to the uncertainty.

Herein is described a MEMS temperature sensor that is self-calibratable and provides accurate and precise temperature measurements over a large temperature range. Various methods herein include measuring the change in capacitance to close two asymmetric gaps to accurately determine displacement, comb drive force, and system stiffness. By substituting the MEMS stiffness and mean square displacement into the equipartition theorem, the temperature and its uncertainty is measured.

If a system can be described by classical statistical mechanics in equilibrium at absolute temperature T, then every independent quadratic term in its energy has a mean value equal to k_{B}T/2 [B5, B9-B11]. The equipartition theorem applied to cantilever potential energy [B11] gives (39). The equipartition theorem has been extensively used in the area of nanoscale metrology.

Hutter, in [B5], showed the use of this theorem for measuring the stiffness of individual cantilevers and tips used in AFM. In [B5] he states that for a spring constant of 0.05 N/m, thermal fluctuations will be of the order of 0.3 nm at room temperature which are relatively small deflections, so an AFM cantilever can be approximated to a simple harmonic oscillator. Hutter measured the root mean square fluctuations of a freely moving cantilever with a sampling frequency higher than its resonant frequency in order to estimate the spring constant. He computes the integral of power spectrum which is equal to the mean square of fluctuations in the time series data [B7]. The spring constant then is k=k_{B}T/P, where P is the area of the power spectrum of the thermal fluctuations alone.

Stark in [B8] calculated the thermal noise of an AFM V-shaped cantilever by means of finite element analysis. He showed that the stiffness can be calculated from equipartition theorem.

Butt in [B9] showed the use of equipartition theorem for calculating thermal noise of a rectangular cantilever. Levy in [B10] applied Butt's method to a V-shaped cantilever. Jayich in [B11] showed that thermomechanical noise temperature could be determined by measuring the mean square displacement of the cantilever's free end.

Herein are described the dependence of displacement amplitude on temperature and stiffness; some applications of the equipartition theorem; methods for accurately and precisely measuring MEMS displacement and stiffness; and details of measuring MEMS temperature.

Regarding dependence of displacement amplitude on stiffness and temperature, the dependence of amplitude on stiffness and temperature can be characterized. For a device vibrating sinusoidally, the expected or mean square displacement is

[symbol]

y² [symbol] =yᵣₘₛ²=½A². (40)

where yᵣₘₛ is the root mean square of its displacement and A is its amplitude of motion. Substituting (40) into (39) gives an amplitude of

A=\sqrt{2k_{B}T/k}. (41)

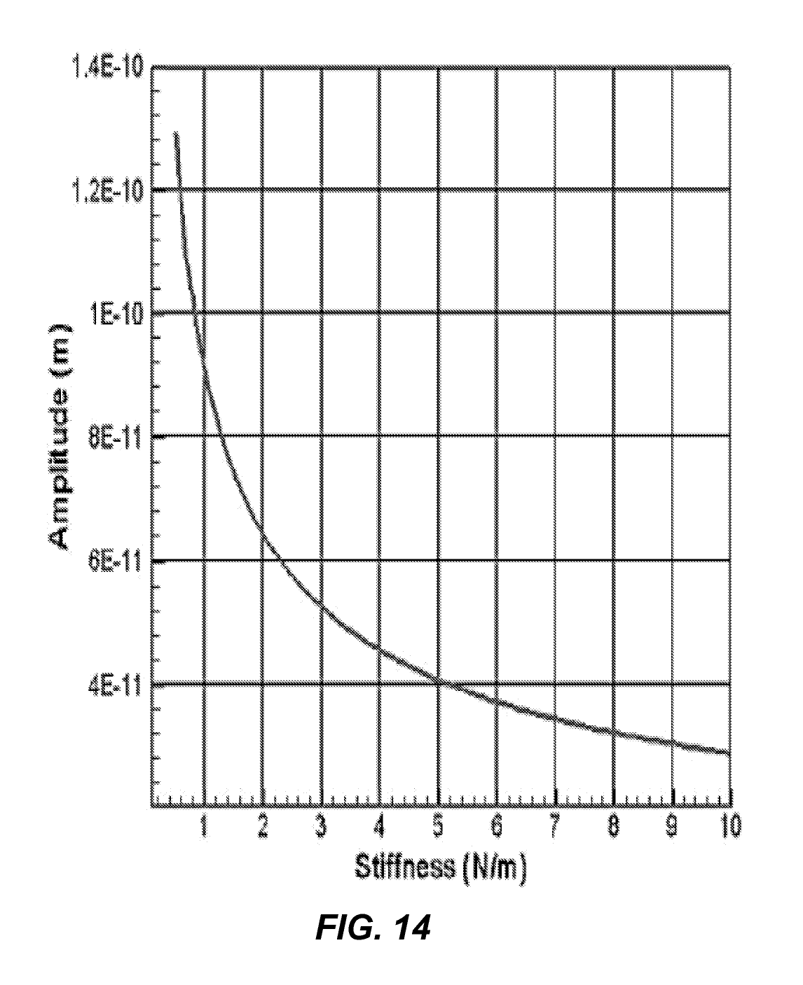

FIG. 14 shows variation of displacement amplitude with stiffness. Stiffness on the x-axis varies from 0.5 to 10 N/m, which is a typical rage for MEMS stiffness. Amplitude is determined by setting T to be 300K in (41). FIG. 14 is a plot showing an exemplary dependence of amplitude on stiffness, where temperature is set at 300K and stiffness is varied from 0.5 to 10 N/m, which is a typical range for micro-structures.

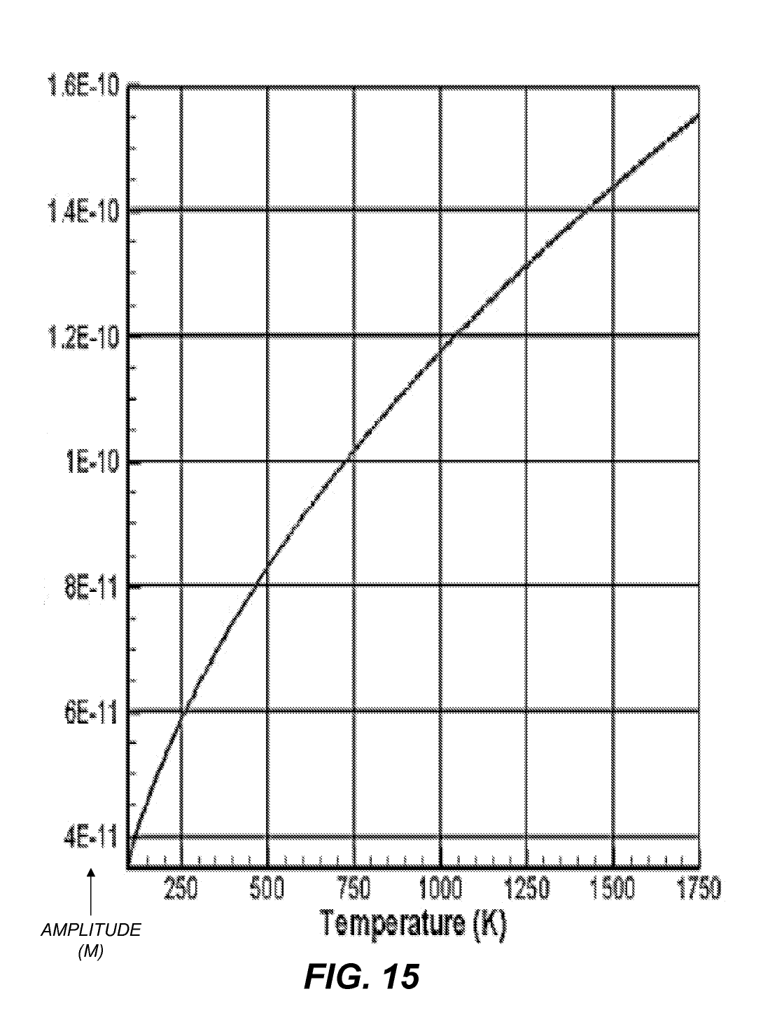

FIG. 15 is a plot showing the dependence of amplitude on temperature. The plot shows that the amplitude is proportional to square root of temperature. For this plot, stiffness was assumed to be 2 N/m and temperature was varied from 94 to 1687K. FIG. 15 shows variation of amplitude with temperature. Temperature on the x-axis varies from 94 to 1687 K (a range of temperatures including the melting point of silicon). Amplitude is determined by setting k as 2 N/m in (41). The plot shows that the amplitude is proportional to the square root of temperature.

By differentiating (40) with respect to stiffness and temperature, the sensitivities of amplitude with stiffness and temperature are determined to be:

dA/dk=(−½k)\sqrt{2k_{B}T/k}, and (42)

dA/dT=(½)\sqrt{2k_{B}/kT}. (43)

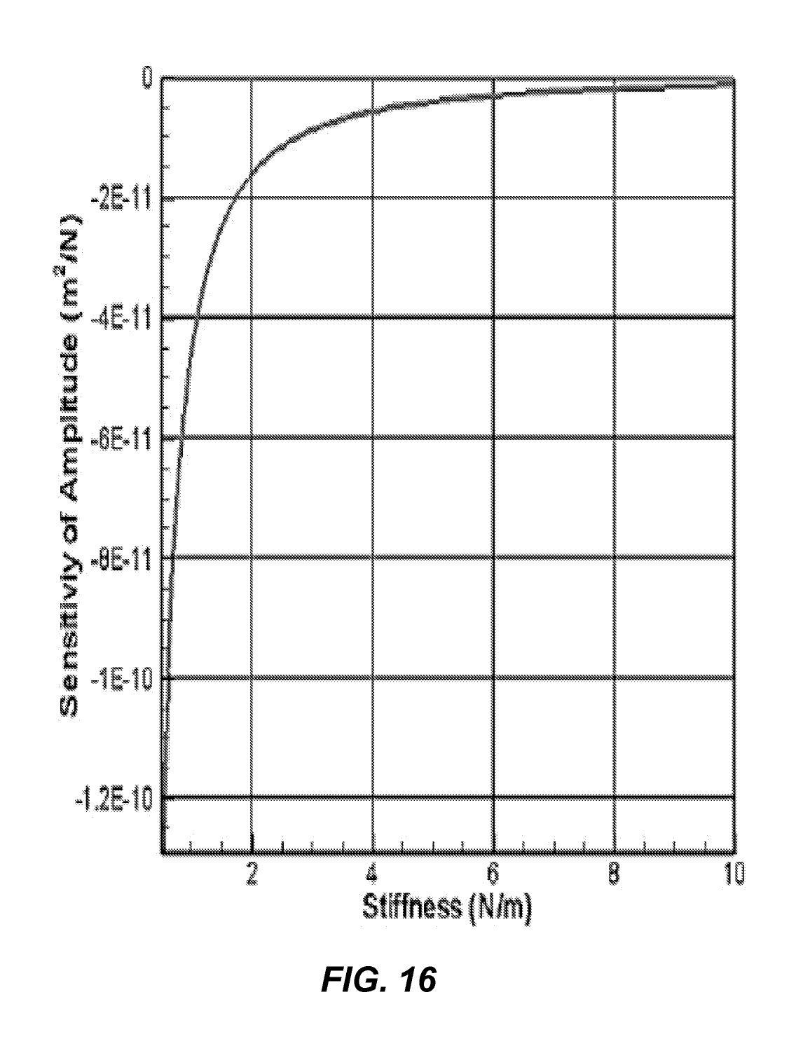

FIG. 16 shows sensitivity of amplitude with stiffness. Stiffness on the x-axis varies from 0.5 to 10 N/m, which is a typical range for MEMS stiffness. Sensitivity of amplitude is determined by setting T to be 300K in (42). As seen in the plot, the sensitivity of amplitude to stiffness increases as stiffness decreases. From FIG. 16, it can be seen that the amplitude is most sensitive for smaller values of stiffness, and least sensitive for larger values of stiffness, with a knee of about 2 N/m.

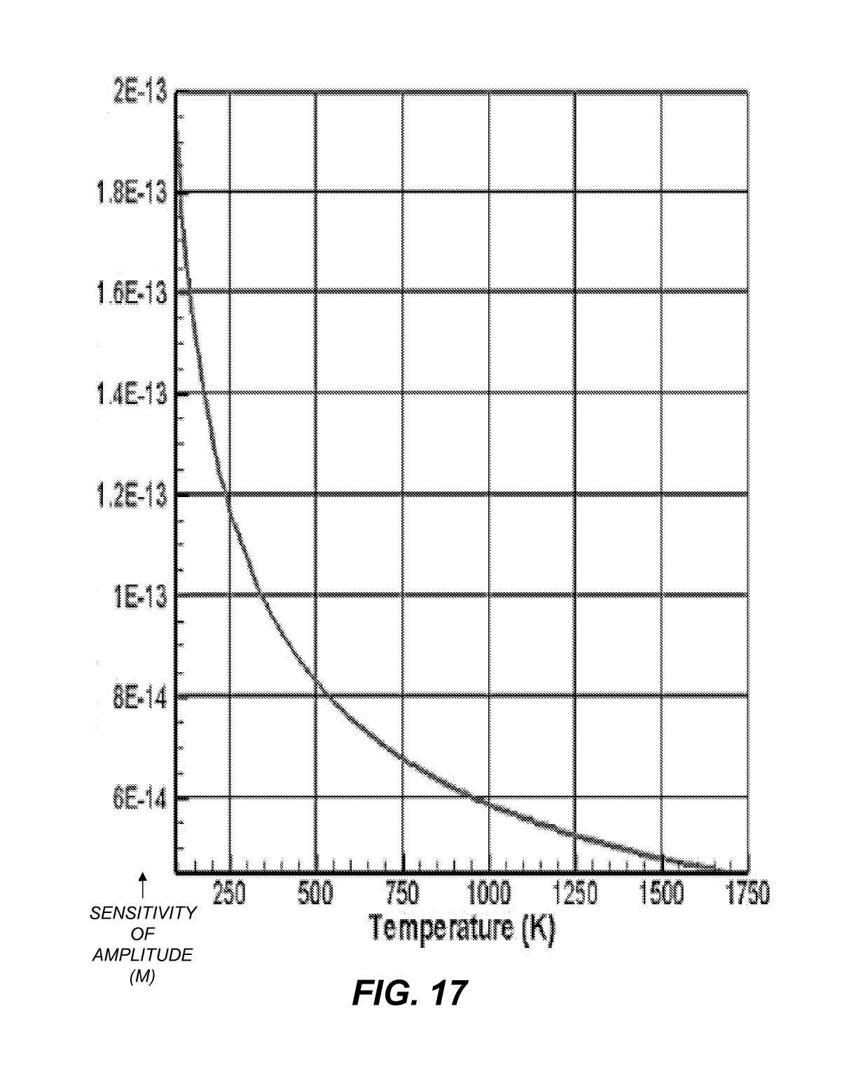

FIG. 17 shows sensitivity of amplitude with temperature. Temperature on the x-axis varies from 94 to 1687 K. Sensitivity of amplitude is determined by setting k as 2 N/m in (43). As seen in the plot, the sensitivity of amplitude to temperature decreases as temperature increases. From FIG. 17, it can be seen that the amplitude is most sensitive for lower values of temperature, and least sensitive for higher values of temperature.

Regarding displacement and stiffness, described herein is a self-calibratable measurement technology for measurement of stiffness and displacement using electrical measurands [B12-B14]. Various methods herein involve applying the steps described below to a MEMS structure.

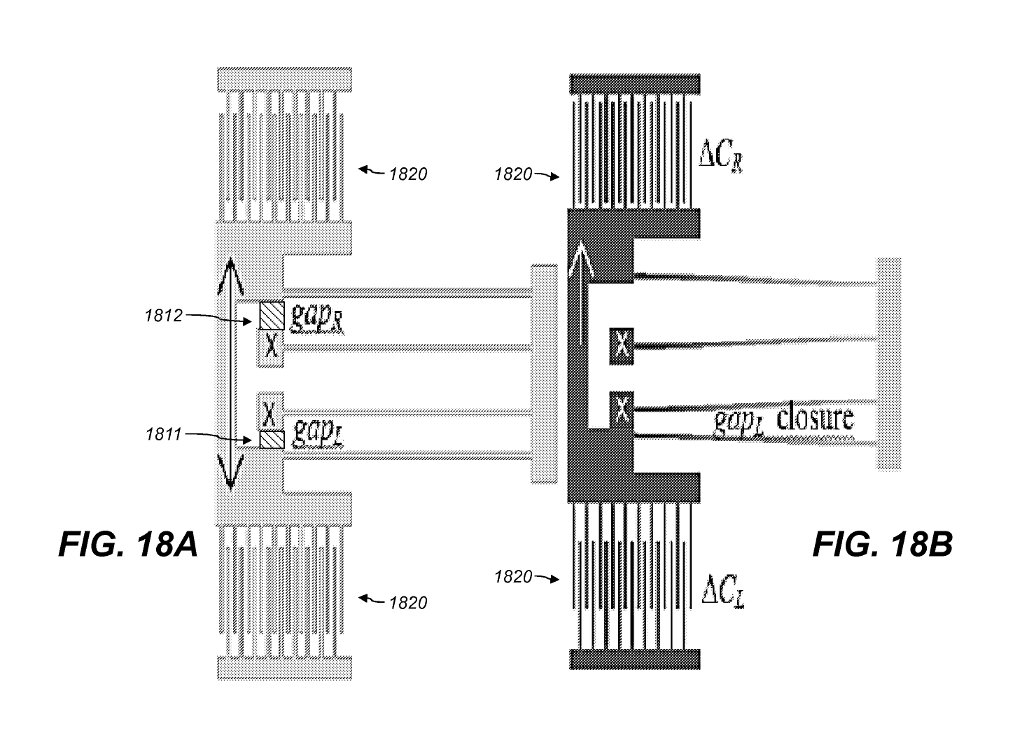

FIGS. 18A and 18B show an exemplary MEMS structure with comb drives 1820 and two asymmetric gaps 1811, 1812. Shades of gray represent displacement from a rest position. The placement of gaps shown here is not unique; other placements can be used. The gaps 1811, 1812 are shown hatched in FIG. 18A for clarity. FIG. 18A shows the rest position.

FIGS. 18A, 18B are representations of simulations relating to measurement of stiffness. FIG. 18A shows a MEMS structure having comb drives and two unequal gaps (gap_{L} and gap_{R}), which are used for self-calibration. Anchors are identified with “X” marks. FIG. 18A shows an undeflected zero state; FIG. 18B shows a state where gap (gapL) is closed (b). The zero state provides the initial C₀ capacitance measurement. Applied voltages provide ΔC_{L} and ΔC_{R} by traversing gaps gap_{L} and gap_{R}.

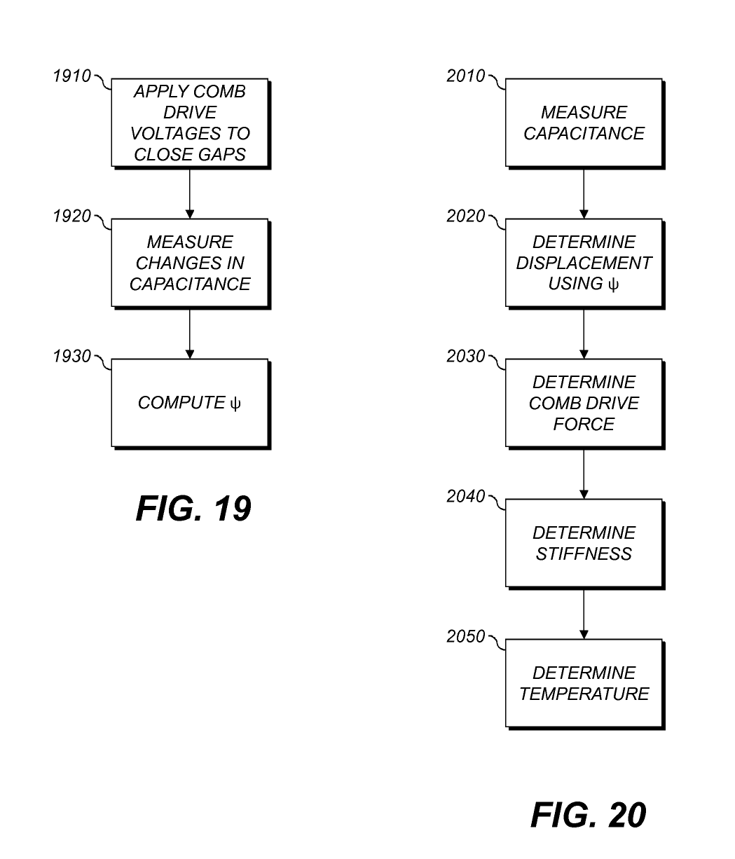

FIG. 19 is a flowchart of exemplary methods of determining a comb drive constant. Referring to FIG. 19 and also, by way of example and without limitation, to FIG. 18, step 1910 includes applying a sufficient amount of comb drive voltage to close each gap 1811, 1812 (gapR and gapL), one at a time. In step 1920, corresponding changes in capacitance (ΔC_{R} and ΔC_{L}) are measured. In step 1930, a comb drive constant ψ is computed; ψ is the ratio of change in capacitance to displacement. It can be expressed as

$$ψ = \frac{Δ {C}_{R}}{{gap}_{R}} . \qquad ( 44 )$$

FIG. 20 shows exemplary further processing. In step 2010, a capacitance measurement ΔC is taken. From (44), the comb drive constant is equal to any intermediate ratio of change in capacitance to displacement. Hence, in step 2020, an accurate measure of displacement is determined as

$$y = \frac{Δ C}{ψ} . \qquad ( 45 )$$

In step 2030, comb drive force is determined as

F=½V²∂C/∂x=½V²ψ. (46)

The system stiffness is k≡F/Δy. Using expressions of displacement (45) and force (46), in step 1940, the nonlinear stiffness is determined as

k=½ψ²V²/ΔC. (47)

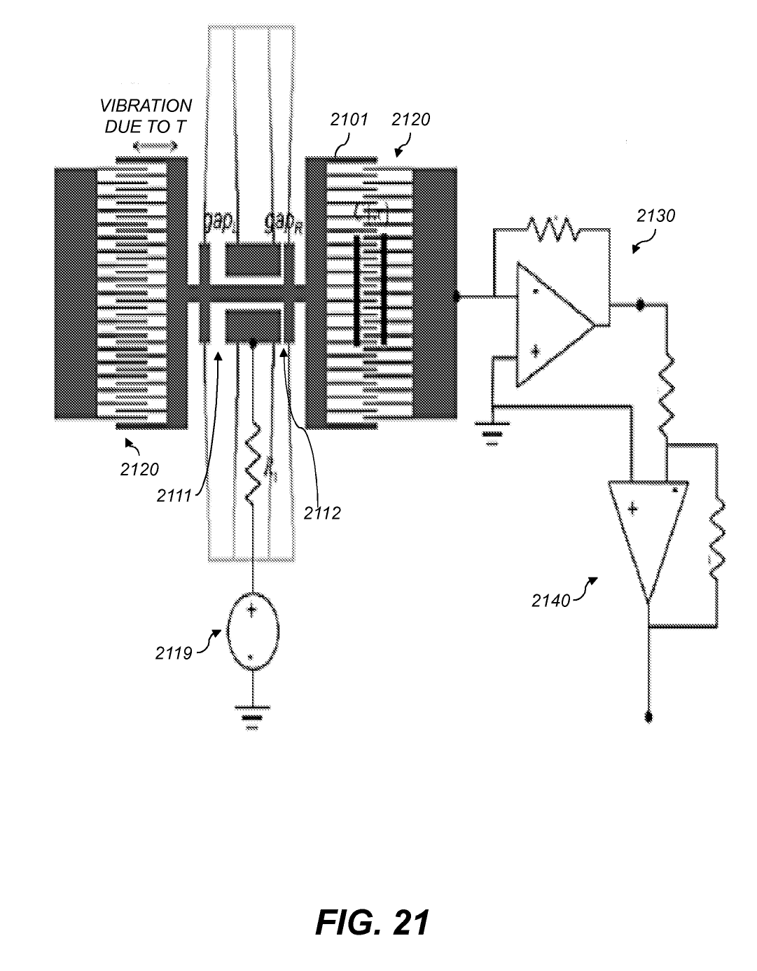

Regarding MEMS temperature sensing, an exemplary method herein for measuring temperature using MEMS involves solving the equipartition theorem (39) for absolute temperature by substituting the measured displacement using (45) and stiffness using (47). The root mean value of displacement used for (39) is

$$〈 {y}^{2} 〉 = \frac{1}{{t}_{f} - {t}_{i}} {\int }_{{t}_{i}}^{{t}_{f}} {y}^{2} d t \qquad ( 48 )$$

where displacements can be dynamically measured using a transimpedance amplifier, as illustrated in FIG. 21.

FIG. 21 shows an exemplary system for instantaneous displacement sensing. FIG. 21 illustrates a method to sense displacement using a transimpedance amplifier (TIA) 2130, which converts the capacitance of the comb drive 2120 into an amplified voltage signal. Values from the transimpedance amplifier can be used to calibrate displacement. A low-pass filter can be inserted between the TIA 2130 and a signal amplifier 2140 to condition the differentiated noise. The voltage values at gap closure states (gaps 2111, 2112 closed, respectively) are used to calibrate the output voltage, as discussed above. Intermediate displacements are obtained by interpolation (e.g., step 2020, FIG. 20). The output voltage of the amplifier 2140 can be calibrated by determining the voltage values at the displacement states of gap closure. Intermediate displacement amounts are simply interpolations based on the known gap closure displacements. The proof mass vibrates due to temperature T, as indicated by the double-headed arrow. Voltage source 2119 applies an excitation signal to convert capacitance to an impedance, e.g., Vᵢₙ=V_{dc}+V_{ac} sin(ω_{z}t). The impedance of sensing comb 2120 is Z=j/(w₀C(x)) for capacitance C(x). Gap 2111 is gam. Gap 2112 is gap_{R}. The signal from the right comb drive can be fed into the left comb drive 2140 to stop vibration.

Referring back to FIG. 20, from the stiffness and displacement measured as described above (e.g., steps 2020, 2040), in step 2050, the temperature of the MEMS is determined as:

T=k [symbol] y² [symbol] /k_{B}. (49)

Regarding mean and standard deviation, each measurement of temperature taken is based on the expected displacement, which is an averaging process. Therefore, each measurement of temperature is actually from a sampling of a distribution of average temperatures, assuming the true temperature is not changing. It is well-known that the mean of the mean measurement of temperatures quickly converges to the true temperature, regardless of the distribution type, according to the Central Limit Theorem. Once the standard of the temperature distribution is measured,

$$SD = \sqrt{\frac{1}{N - 1} {\sum }_{n = 0}^{N} {( {T}_{average} - {T}_{n} )}^{2}} , \qquad ( 50 )$$

then the sample standard deviation of the of the mean of means is

$$sd = \frac{SD}{N} . \qquad ( 51 )$$

Regarding uncertainty, uncertainty in temperature can be found by the first order terms of a multivariate Taylor expansion about the uncertainties in capacitance δC and voltage δV. These uncertainties can be practically found by determining the order of the decimal place of the largest flickering digit on a capacitance or voltage meter. The standard deviation and uncertainty in temperature, respectively, are:

$$δ T = \vert \frac{\partial T}{\partial Δ C} \vert \vert δ C \vert + \vert \frac{\partial T}{\partial Δ} \vert \vert δ V \vert . \qquad ( 52 )$$

where T from (39) is a function of capacitance and voltage due to displacement (45) and stiffness (47).
By substituting (40) and (47) into (49), temperature T can be determined as:

$$T = \frac{{ψ}^{2} {A}^{2} {V}^{2}}{4 {k}_{B} Δ C} . \qquad ( 53 )$$

Differentiating (53) with respect to change in capacitance ΔC and voltage V yields uncertainty in temperature (54) as:

$$\begin{matrix}δ T = \frac{{ψ}^{2} {A}^{2} {V}^{2}}{4 {k}_{B} Δ {C}^{2}} δ C + \frac{{ψ}^{2} {A}^{2} V}{2 {k}_{B} Δ C} δ V \\ = \frac{{kA}^{2}}{2 {k}_{B} Δ C} δ C \frac{{kA}^{2}}{{k}_{B} V} δ V .\end{matrix} \qquad ( 54 )$$

For a test case, a finite element analysis software package called COMSOL [B15] was used to model the mechanical and electrical physics. As discussed above, when closing 2 unequal gaps, the change in capacitance is measured. By substituting these values in (54) the uncertainty in measuring temperature can be predicted.

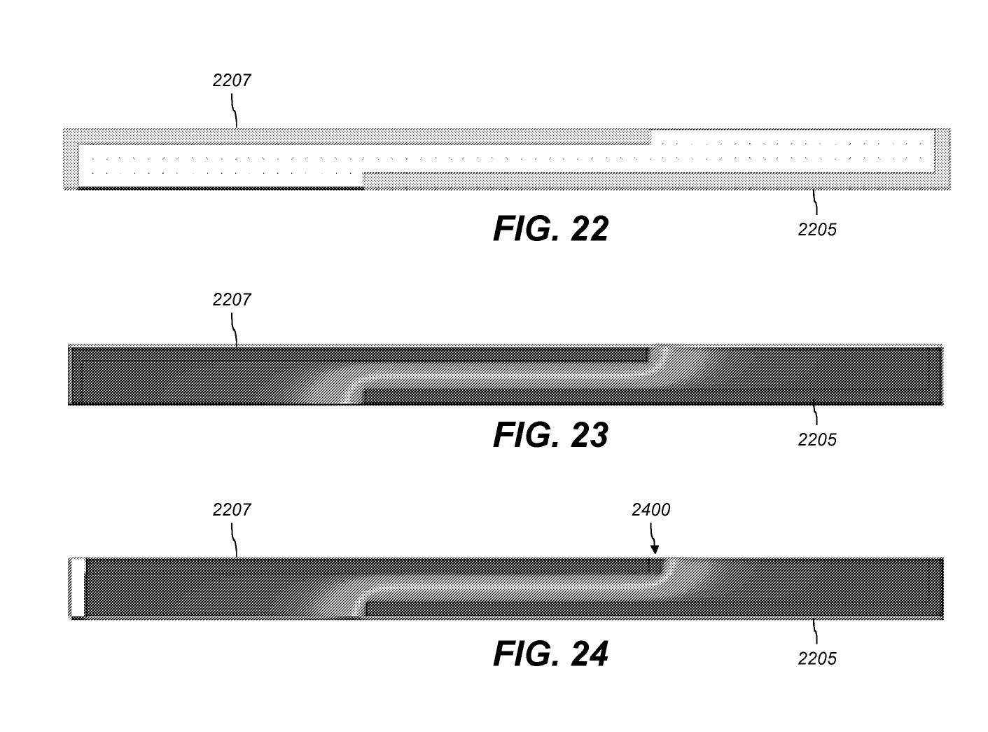

Regarding the comb drive constant, to increase precision through convergence analysis using a maximal number of elements, the comb drive constant can be modeled separately from mechanical properties of the structure. Assuming that each comb drive finger can be modeled identically, a single comb finger section can be modeled as shown in FIG. 22. Using 21000 quadratic finite elements, the comb drive constant was simulated and the simulation converged to ψ=8.917×10⁻¹¹ F/m. For twenty fingers, the comb drive constant is therefore 17.834×10⁻¹⁰ F/m.

FIGS. 22-24 show a model for simulating to determine the comb drive constant, and various simulation results. FIG. 22 shows the configuration of the portion of a comb drive. FIG. 23 shows voltage and position at an initial state. FIG. 24 shows voltage and position at an intermediate state. Rotor 2207 is the upper comb finger in this model. Stator 2205 is the lower comb finger in this model. A simulation was performed using about 21000 mesh elements; the simulation converged to a comb drive constant of ψ=8.917×10⁻¹¹ F/m. In this simulation, finger width is 2 mm, length is 40 mm, and initial overlap is 20 mm. A shift is visible, e.g., at point 2400 in FIG. 24.

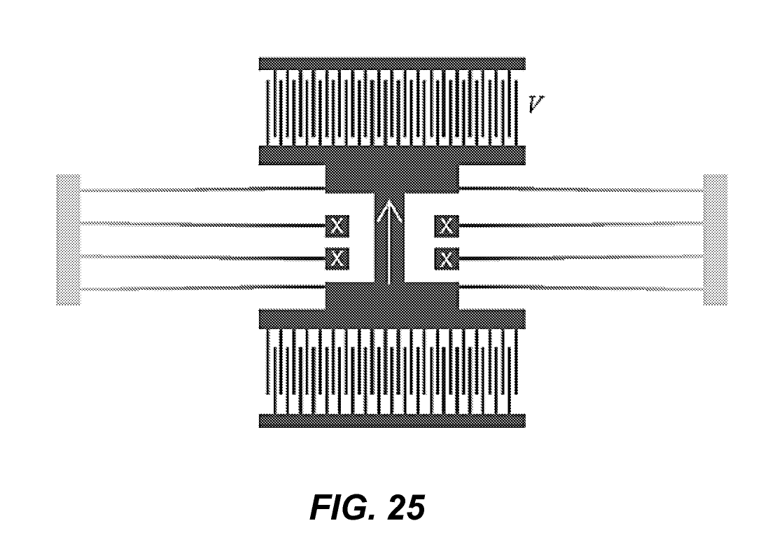

FIG. 25 shows results of a simulation of static deflection for stiffness. A static deflection of 2.944 μm is shown for an applied voltage of 50V, which generated as force of 1.1146×10⁻⁷N. The simulation was performed with 34000 finite quadratic elements. The deflection shown in the image is magnified. The smallest feature size is 2 μm. The relative error in the stiffnesses between that of the simulation and that of (47) is 0.107%.

To determine stiffness, using 34000 elements, a simulated comb drive voltage of 50V was applied and the corresponding change in capacitance was determined via simulation to be ΔC=1.04×10⁻¹⁴ F. Substituting these values into (47), the stiffness of the structure shown in FIG. 25 was determined to be k=0.38197 N/m, compared to the stiffness of 0.38156 N/m of a simulated computer model.

Regarding amplitude, corresponding to the stiffness of 0.38197 N/m, from FIG. 14 the amplitude is determined to be 1.4742×10⁻¹⁰ m at T=300K. This is a direct application of the equipartition theorem.

Regarding uncertainty, substituting k=0.38197 N/m, A=1.4742×10⁻¹⁰ m, k_{B}=1.38×10⁻²³NmK⁻¹, V=50V, ΔC=1.04×10⁻¹⁴F, δV=1×10⁻⁶ V, δC=1×10⁻¹⁸F into (54), the sensitivities are

|∂T/∂ΔC|=2.89×10¹⁶K/F

and

|∂T/∂V|=12.04K/V.

The uncertainty in the measurement of T due to the uncertainty in capacitance is |∂T/∂ΔC|δC=0.029 K, and the uncertainty in the measurement of T due to the uncertainty in voltage is |∂T/∂ΔC|δV=1.2×10⁻⁵ K. The total uncertainty is 0.029K at T=300K. The uncertainties for capacitance and voltage used here are the typical precision specifications of capacitance meters from ANALOG DEVICES INC. and voltage sources from KEITHLEY INSTRUMENTS. From the magnitude of the sensitivities in this test case, it can be seen that the uncertainty in temperature is weakly sensitive to the uncertainty in voltage, yet strongly sensitive to the uncertainty in capacitance. Fortunately, zeptofarad O(10⁻²⁴) capacitance resolution is possible, which would appear to reduce the uncertainty in temperature due to capacitance by another three orders of magnitude. In addition, as shown in (54), the sensitivities depend on design parameters such as stiffness and gap size.

Various aspects described herein include methods for measuring the MEMS temperature based on electronic probing. Various aspects use devices with comb drives. Various aspects permit temperature sensing using post-packaged MEMS that can self-calibrate. Various aspects include measuring the change in capacitance to close two asymmetric gaps. Measurements of the gaps are used to determine geometry, displacement, comb drive force, and includes stiffness. By substituting the accurate and precise measurements of stiffness and mean square displacement into the equipartition theorem, accurate and precise measurements of absolute temperature are determined. Expressions for the measurement of mean, standard deviation, and uncertainty of absolute temperature were discussed above.

Various aspects relate to an Electrostatic Force-Feedback Arrangement for Reducing Thermally-Induced Vibration of Microelectromechanical Systems. Electrostatic force-feedback is used to counter thermally-induced structural vibrations in micro electro mechanical systems (MEMS). Noise, coming from many different sources, often negatively affects the performance of N/MEMS by decreasing the precision for sensors and position controllers. As dimensions become small, mechanical stiffness decreases and the amplitude due to temperature increases, thereby making thermal vibrations become more significant. Thermal noise is most often regarded as the ultimate limit of sensor precision. This limit in precision impedes progress in discovery, the development of standards, and the development of novel NEMS devices. Hence, practical methods to reduce thermal noise are greatly needed. Prior methods to reduce thermal vibration include cooling and increasing flexure stiffness. However, the cooling increases the overall size of the system as well as operating power. And increasing the flexure stiffness can come at the cost of reduced performance. Electrostatic position feedback has been used in accelerometers and gyroscopes to protect against shock and improve performance. Various aspects described herein advantageously use such techniques to reduce vibration from noise by using velocity controlled force-feedback. Described herein are analytical models with parasitics that are verified through simulation. Using transient analysis, the vibrational effects of white thermal noise upon a MEMS can be determined. Greatly reduced vibration can be achieved due to the inclusion of a simple electrostatic feedback system.

The ultimate lower limit of most sensing performance has previously been set by noise in micro-machined devices. There are numerous sources of noise that affect performance. However, after noise from electronics has been reduced and after extraneous electromagnetic fields have been shielded, thermal noise is one of the most significant sources of noise that remain. Mechanical vibration due to this thermal noise has often been called the ultimate limit. Described herein is a method to reduce such vibrations in MEMS.

Gabrielson [C1] presented an analysis of the mechanical-thermal vibrations, or thermal noise, in MEMS. At the fundamental level, thermal noise is understood to result from the random paths and collisions of particles described by Brownian motion. From quantum statistical mechanics, the expected potential energy of a given node equals the thermal energy in a particular degree of freedom of a structure, yielding

½k [symbol] x² [symbol] =½k_{B}T (55)

where k is the stiffness in the degree of freedom, k_{B} is Boltzmann's constant, T is the temperature, and x² is the mean of the square of the displacement amplitude. Equivalently, thermal noise can be described by Nyquist's Relation as a fluctuating force

F=\sqrt{4k_{B}TD} (56)

where D is the mechanical resistance or damping [C1]. From either (55) or (56) it is clear that there will be some expected amplitude of fluctuation or vibration, x, of a mechanical structure for all temperatures. This vibration is what is referred to as thermal noise here. Leland [C2] extended the mechanical-thermal noise analysis for a MEMS gyroscope. Vig and Kim [C3] provide an analysis of thermal noise in MEMS resonators.

The problem of thermal noise is significant in atomic force microscopy (AFM), where the AFM's probe consists of a cantilever that is subject to the vibrations caused by thermal noise. Reference [C4] demonstrates the calculation, yielding results similar to equations (55) and (56), of thermal noise specifically for AFM. Using an example from [C5], given a microstructure at T=306K with a stiffness of k=0.06 N/m, then its expected amplitude of vibration would be about 0.3 nm, which is about the length of ˜1 to 3 atoms. Such vibration is often not suitable for molecular scale manipulation. With such uncertainty in displacement, and uncertainty in the measurement of AFM stiffness from 10-40%, then AFM force is uncertain by as much as <F>=k<X>˜10-100 pN. Gittes and Schmidt [C6] predict smaller vibrations of ˜0.4 pN from thermal vibrations, but acknowledge that true values will be much larger based on AFM tip and surface geometries. Regardless, these uncertainties limit the ability to resolve hydrogen bonds in DNA or measure protein unfolding dynamics [C7], as examples.

To move beyond this thermal noise limit, according to various aspects herein, electrostatic force-feedback control is used to reduce the amplitude of mechanical vibrations due to thermal noise. Boser and Howe [C8] discuss the use of position controlled electrostatic force-feedback in MEMS to improve sensor performance. Their approach uses position controlled feedback to increase device stability and extend bandwidth. The extended bandwidth is important because they propose minimizing thermal noise by design of high-Q structures with optimized resonant frequency, and therefore small useable bandwidth. Thus, Boser and Howe propose position controlled feedback as a means of extending the useful bandwidth and address thermal noise with improved mechanical design, which is still thermal noise limited. In contrast, methods herein use velocity controlled electrostatic force-feedback to directly limit thermal vibrations of MEMS structures.

There are numerous examples of the use of feedback in MEMS. Dong et al. in [C9] describe the use of force feedback with a MEMS accelerometer in order to lower the noise floor. However, the feedback is used to improve linearity, bandwidth, and dynamic range. That scheme uses digital feedback (discrete pulses) to reduce the electrical and quantization noise, taking the mechanical noise as the limiting case. In contrast, methods herein use feedback to reduce the thermal (limiting component of mechanical) noise. Similar to [C9], Jiang et al. in [C10] extended the use of digital force-feedback to a MEMS gyroscope in order to lower the noise floor down to the thermal noise limit. This scheme considers mechanical-thermal noise as the limiting factor and the feedback design only addresses electrical noise and sampling errors, while ignoring thermal noise. Handtmann et al. in [C11] describe the use of position controlled digital force-feedback with a MEMS inertial sensor to enhance the sensitivity and stability be using electrostatic capacitive sensor and actuator pairs to sense a displacement and feedback force pulses for position re-zeroing. This scheme also addresses other types of noise and leaves mechanical-thermal noise as the limit. In the prior art the feedback is used to improve performance above the thermal noise limit and is addressing other problems besides thermal noise (linearity, bandwidth, stability, etc.).

Gittes and Schmidt in [C6] discuss the use of feedback for force zeroing in AFM. They present two typical methods of feedback in a theoretical discussion about the thermal noise limits. The first type of feedback common to AFM is the position-clamp experiment where the probe tip is held stationary by using the position of the probe tip as the feedback signal to control the motion of the cantilever anchor. The result is feedback which varies the strain on the cantilever but keeps the probe tip stationary. The second type of feedback common to AFM is the force-clamp experiment where the motion of the anchor is controlled by the feedback signal in order to keep the probe strain constant. Thus, the probe tip moves with the cantilever while maintaining a constant force on the measured surface. In either case, the feedback is a part of the measurement apparatus and is not intended to address thermal vibrations. Rather, Gittes and Schmidt describe thermal noise as the source of uncertainty within the feedback system.

Huber et al. in [C12] presented the use of position based feedback control of a tunable MEMS mirror for laser bandwidth narrowing. Their approach specifically addresses thermal vibrations with a feedback system based on wavelength. Brownian motion causes the MEMS mirror to vibrate, resulting in laser wavelength blurring. Using an etalon and a difference amplifier, the resulting wavelength is compared to an expected value and the difference is used as the feedback signal. The authors were able to demonstrated reduced linewidth from 1050 to 400 MHz, a reduction of 62%. Although their system was successful, it used static position based feedback control. In contrast, methods and systems described herein use velocity controlled feedback, which does not depend on specific position, but rather uses velocity to reduce vibrations directly. At the macroscale, feedback to reduce thermal vibrations has been demonstrated. Friswell et al. in [C13] use piezoelectric sensors and actuators to feedback a damping signal for thermal vibrations in a 0.5 m aluminum beam. They use the aluminum beam as a purely experimental example to demonstrate the effects of feedback damping on thermal vibrations. They are able to demonstrate greatly reduced settling times for thermal excitations with vibrations on the order of 0.1 mm.

Regardless of the feedback applied to MEMS, an actuating mechanism is required. Two of the most common actuation methods are piezoelectric actuators and electrostatic comb drives. Wlodkowski et al. in [C14] present the design of a low noise piezoelectric accelerometer and Levinzon in [C15] derives the thermal noise expressions for piezoelectric accelerometers, looking at both the mechanical and electric thermal noise. The piezoelectric phenomenon can be applied to reducing inherent vibrations. Herein are described various aspects using electrostatic comb drive actuators, which are a common actuation mechanism in MEMS. One of the primary challenges of using MEMS to detect and provide corrective forces for vibrations induced by thermal noise is the extremely small size of the displacements. In order to provide velocity controlled feedback which reduces random thermal vibration amplitudes from nanometers to angstroms or below, the MEMS sensor and feedback electronics should rapidly sense motion and instantaneously feedback an opposing electrostatic force to counter the motion using preferably analog circuitry.

Herein are described the components of an exemplary circuit that senses vibrational proof mass motion in MEMS comb drives, and then applies electrostatic feedback forces that counter such motion using another set of comb drives; simulations of each system component that exemplify their roles; simulations of an integrated system including the feedback circuit and a MEMS structure that is subject to white noise disturbances; and simulations of the motion of the MEMS before and after activating the feedback circuit in the face of noise sources.

Various aspects herein include a force feedback damping circuit. This circuit produces an electrostatic feedback force to oppose noise-induced motion. The feedback force is proportional to velocity to emulate the well-known viscous damping force on the proof mass. Electronics are used to emulate largely-damped mechanical system dynamics that are able to reduce the noise-induced motion.

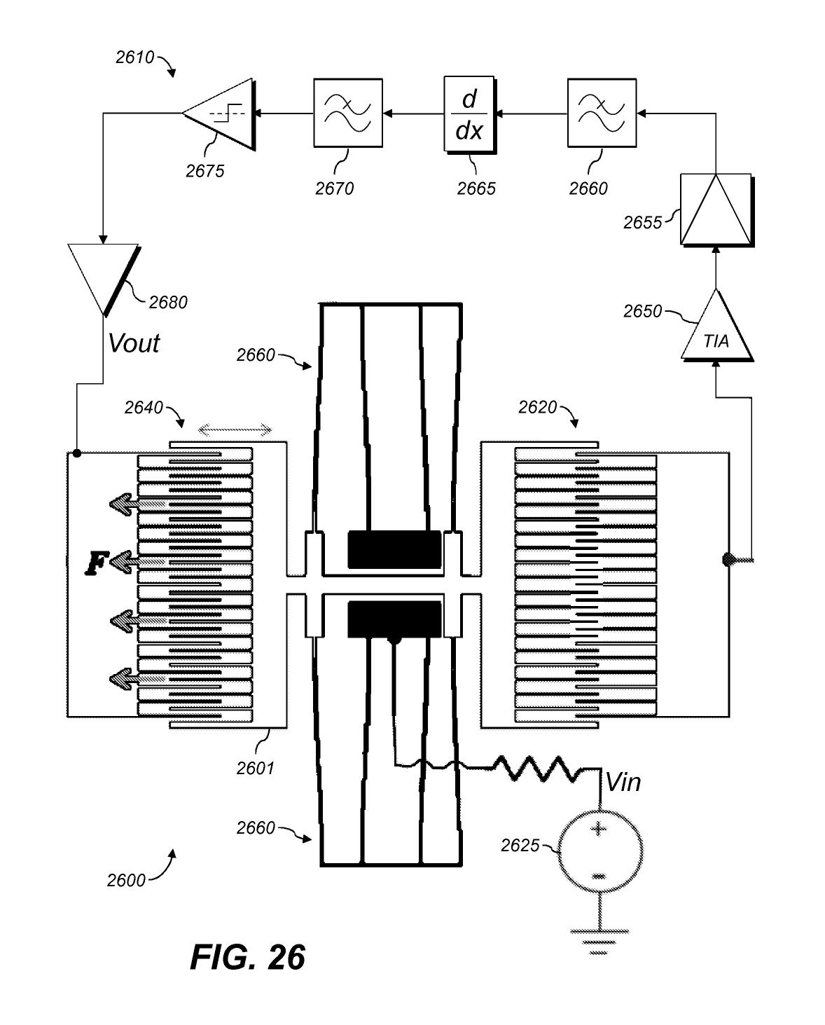

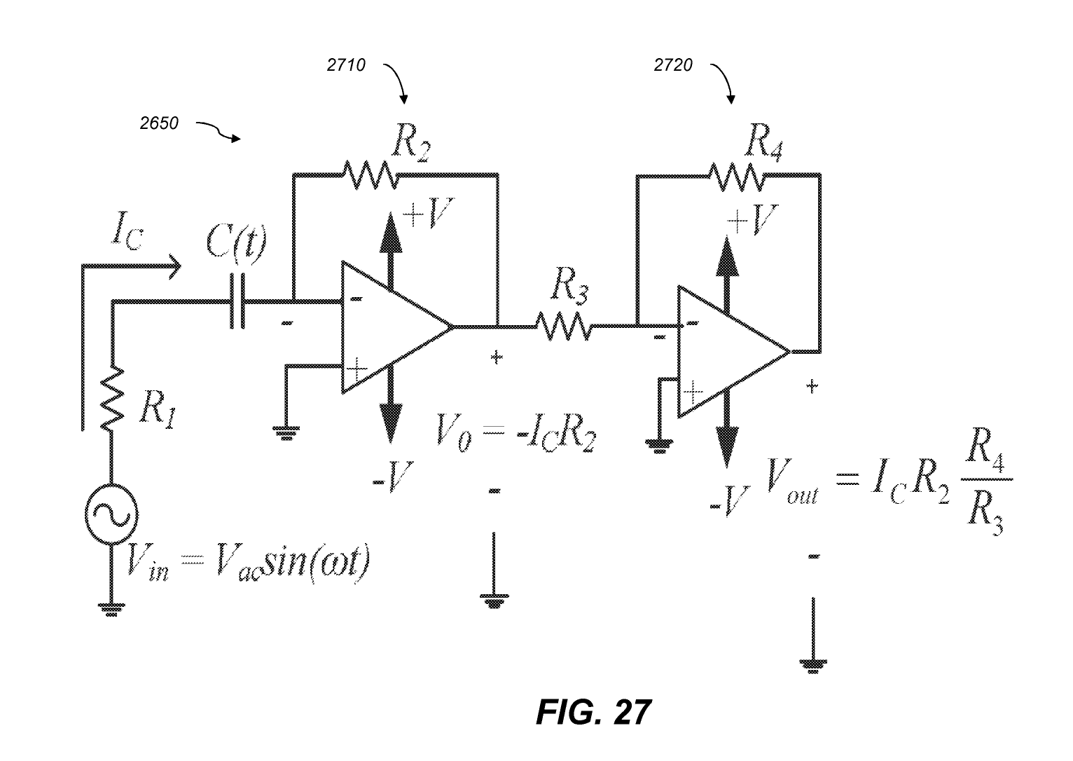

FIG. 26 shows a MEMS structure with a pair of comb drives 2620, 2640 and folded flexure supports 2660. Various aspects perform one-sided damping through electrostatic force feedback; other aspects use another pair of comb drives to provide damping in both directions.

FIG. 26 is a schematic diagram of the MEMS 2600 and its force feedback system 2610. The MEMS structure is comprised of a comb drive sensor 2620 on the right hand side (RHS) of the figure, a comb drive actuator 2640 on the left hand side (LHS), a folded flexure 2660, and electronic feedback control components. The proof-mass 2601 resonates horizontally, excited by all-frequency (white) noise. As the proof-mass moves to the right, its motion is sensed by the comb drive sensor 2620 on the RHS. This signal is converted to an electrical feedback voltage, which produces an electrostatic force on the LHS actuator 2640 that opposes motion to the right. As the proof-mass 2601 moves to the left, the voltage across the LHS actuator becomes zero, such that the force is zero.

The comb drive 2620 on the right hand side (RHS) in FIG. 26 is a motion sensor and the comb drive 2640 on the left hand side (LHS) is the feedback force actuator. Thermally-induced excitation will cause the proof mass 2601 of the device to resonate horizontally. This change in the position of proof mass 2601 will change the capacitance C(x(t)) of the RHS comb drive 2620 due to the change in the amount of comb finger overlap. The impedance Z_{C} of the RHS comb drive is, e.g.,

$${Z}_{C} = \frac{- j}{{ω}_{Z} C ( x ( t ) )} \qquad ( 57 )$$

A circuit attached to the RHS comb drive 2620 will sense this change in capacitance and produce a proportional voltage signal through a trans-impedance amplifier 2650. This signal is further processed through different parts of the circuit (see FIG. 26) to track the nature of change in right comb drive 2620 capacitance. If the comb drive 2620 capacitance is increasing, it means that the distance between the parallel plates are decreasing, i.e., the proof mass 2601 is moving rightwards. Similarly, the decrease in capacitance indicates a leftward movement of the proof mass 2601. The feedback circuit is designed such that as the proof mass moves to the right, a feedback voltage signal is applied on the left comb drive 2640. This nonzero voltage difference will create a feedback force F (represented in FIG. 26 with left-pointing arrows) that attracts the proof mass 2601 to the left to oppose its motion to the right. But as the proof mass 2601 moves to the left, the feedback signal on the left comb drive 2620 is Vᵢₙ. This zero voltage difference will not create a force as to not attract the proof mass; otherwise, it might increase the amplitude. That is, the feedback force F is proportional to velocity if proof-mass 2601 motion is to the right, and force is 0 if proof-mass motion is to the left. Circuit 2610 includes voltage source 2625, transimpedance amplifier 2650, demodulator 2655, filter 2660, differentiator 2665, filter 2670, zero-crossing detector (ZCD) 2675, and conditional circuit 2680. These together provide feedback.

The proof mass of the comb drive 2601 vibrates, due to white noise sources, at its mechanical resonance frequency of ωₘ2πfₘ. This thermal vibration causes the MEMS capacitance to vary as a function of time as

$$C ( t ) = \frac{2 N ɛ h}{g} ( {L}_{o} + {x}_{max} sin ( {ω}_{m} t ) ) \qquad ( 58 )$$

where N is the number of comb drive fingers, ε is the permittivity of the medium, h is the layer thickness, g is the gap between comb fingers, L₀ is the overlap of comb fingers and) xₘₐₓ is the maximum deflection amplitude due to noise. In relation to (55), <x²> and xₘₐₓ are related by

$$\sqrt{〈 {x}^{2} 〉} = {x}_{rms} = \frac{1}{\sqrt{2}} {x}_{max} . \qquad ( 59 )$$

To sense this noise-induced mechanical motion through the change in capacitance, a current signal (I_{C}) is passed through the position-dependent capacitor. This input signal is a sinusoid of frequency ω which is much higher than ωₘ as to not further excite the mechanical motion. The frequency ω is tunable and provided by the input voltage source 2625 (Vin) (FIG. 26):

Vᵢₙ=V_{ac} sin(ωt) (60)

The current signal I_{C} is passed through the capacitor which is then converted to a voltage signal and amplified through an inverting amplifier, as shown in FIG. 27.

FIG. 27 shows trans-impedance amplifier (TIA) 2650. A sinusoidal current signal is passed through the comb drive capacitor 2620 (FIG. 26) to sense the thermal-noise induced time varying nature of the capacitance. This current signal is converted to a voltage signal using a current to voltage converter 2710 and then amplified through an inverting amplifier 2720. The gain of the circuit is adjustable through the resistors such that the output signal Vₒᵤₜ can be larger than the input signal Vᵢₙ.

The current I_{C} through the capacitor is modulated by both amplitude and phase due to the time varying nature of the capacitance. The output signal Vout can be expressed as

$$\begin{matrix}{V}_{out} = {A}_{1} {A}_{2} {V}_{ac} sin ( ω t - θ ( t ) ) , where & ( 61 ) \\ {A}_{1} = \frac{{R}_{2} {R}_{4}}{{R}_{5}} , & ( 62 ) \\ {A}_{2} ( t ) = \frac{1}{\sqrt{{R}_{1}^{2} + {[ 1 / ω C ( t ) ]}^{2}}} , and & ( 63 ) \\ θ ( t ) = - {tan}^{- 1} [ 1 / ω {R}_{1} C ( t ) ] . & ( 64 )\end{matrix}$$

Here, A₁ is the overall gain of the circuit in FIG. 2. Also, ω=2πf, where f is the frequency of Vᵢₙ. A trend of change in the capacitance can be sensed from this signal. It can be difficult to demodulate amplitude and phase modulated signals together; however various aspects exploit the following approximations:
1. The term ωR₁C(t) is small, e.g., ωR₁C(t)<<1.
2. The input signal frequency is sufficiently larger than the natural frequency of the proof mass of the comb drive, i.e., f>>fₘ.

Using the first assumption, equation (63) can be reduced to:

$${A}_{2} ( t ) \approx ω C ( t ) - \frac{{ω}^{2} {R}_{1}}{2} {C}^{3} ( t ) . \qquad ( 65 )$$

Further, the considered device here exhibits capacitance in the picofarad range, while the change in capacitance due to thermal vibration is several magnitudes smaller. Hence the cubic term can be neglected, resulting in a linear dependency:

A₂(t)≈ωC(t). (66)

Again, the first assumption yields 1/(ωR₁C(t)) as a large value which indicates θ(t)≈−π/2. Since the change in capacitance is relatively small, there is negligible change in this angle. Moreover, the second approximation ensures that the rate change of cot is much higher than θ(t). Thus the output voltage Vout can be linearized as

Vₒᵤₜ≈ωA₁V_{ac}C(t)cos(ωt) (67)

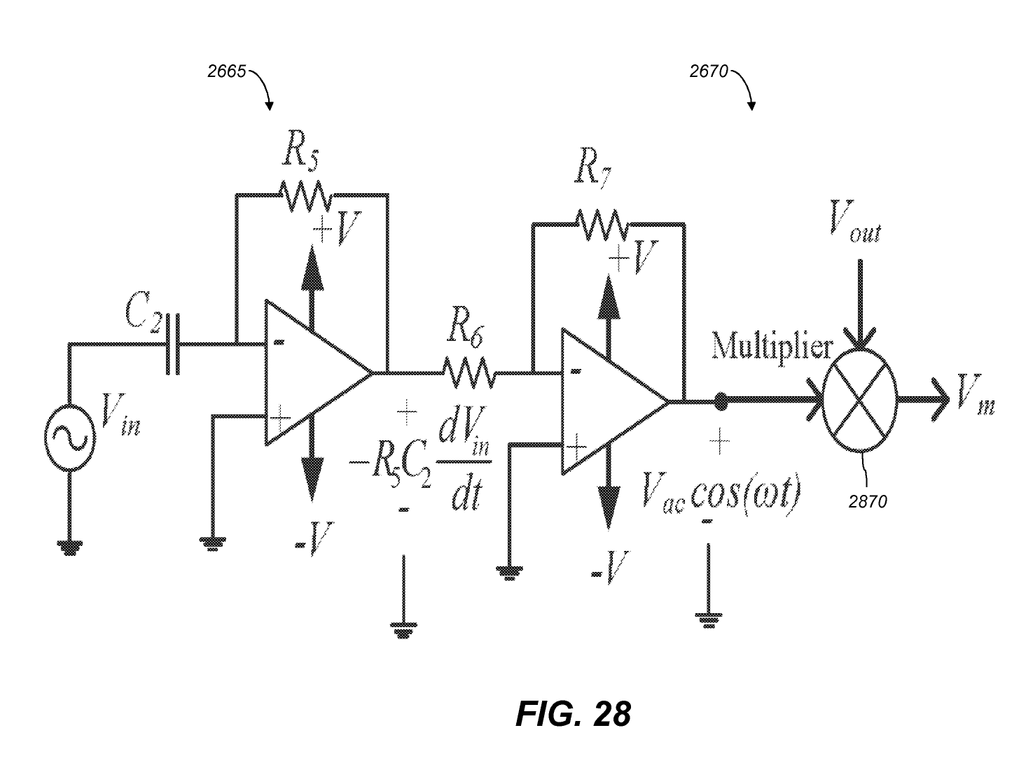

The process to retrieve the time varying nature of the capacitance is simple amplitude demodulation. The output voltage is multiplied by a demodulating signal V_{ac} cos(ωt) which is derived by passing the input signal Vᵢₙ through a differentiator 2665 (FIG. 26). The differentiator is designed such as R₅C₂ 1/ω (see FIG. 28).

FIG. 28 shows differentiator 2665 and demodulator 2670. The output signal Vₒᵤₜ is the amplitude modulated version of the input signal Vᵢₙ. The amplitude of the output signal is directly proportional to the time varying nature of comb drive capacitance. The amplitude is extracted by demodulating the signal Vₒᵤₜ with a demodulating signal V_{ac} cos(ωt), which is of same amplitude and frequency as the input signal Vᵢₙ. This demodulating signal is derived from the input signal Vᵢₙ, by passing it through a differentiator.

A multiplier 2870 is used to multiply V_{ac} cos(ωt) with Vₒᵤₜ. The multiplier circuit can be envisioned with op-amps as reported in [C16]. The output of the multiplier is given by

Vₘ=½ωAV_{ac}²C(t)+½ωAV_{ac}²C(t)cos(2ωt). (68)

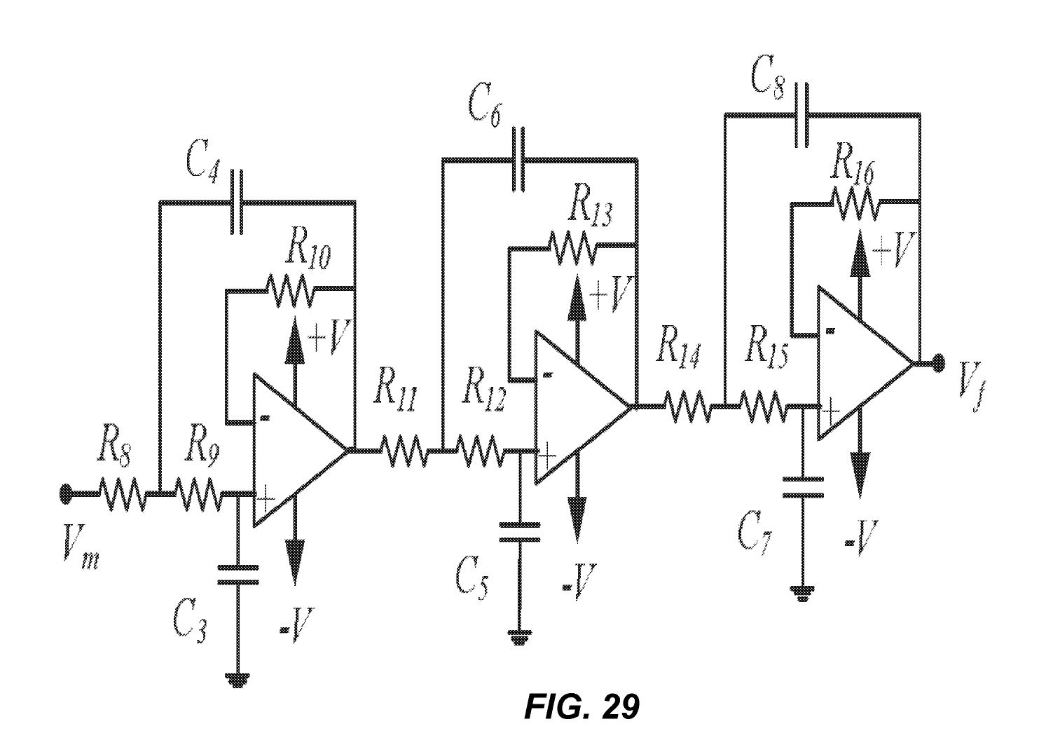

The output of the multiplier contains a term directly proportional to the capacitance which is varying at a relatively low frequency (˜30 kHz) and high frequency component, which can be eliminated by a 6th order Butterworth filter as shown in FIG. 29, with cut-off frequency ω_{c}≈0.35ω.

FIG. 29 shows a low-pass frequency filter. A 6th order Butterworth low pass filter is implemented by cascading three stages of 2nd order Butterworth low pass filters. The cutoff frequency of each stage is set to ω_{c}≈0.35ω. The roll-off is −140 dB/dec. This filter successfully attenuates the higher frequency terms in the signal Vₘ and provides a signal which is directly proportional to the comb drive capacitance.

The output of the filter is directly proportional to the capacitance of the comb drive:

V_{f}≈ωAV_{ac}²C(t). (69)

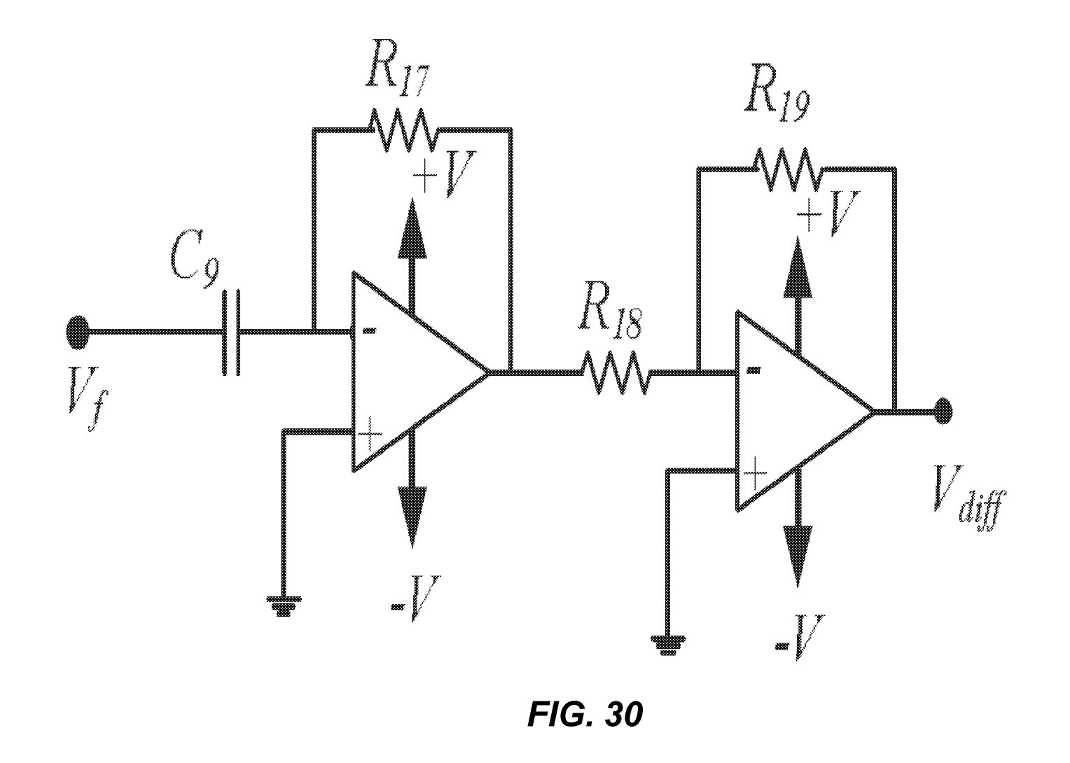

If this signal is passed through another differentiator shown in FIG. 30, the output of the differentiator will track the direction of change in capacitance,

$${V}_{diff} \approx ω {AV}_{ac}^{2} \frac{d C ( t )}{d t} . \qquad ( 70 )$$

FIG. 30 shows a differentiator. The differentiator circuit is designed such that R₁₇C₉=1/ω. This allows the gain of the differentiator to be about −1. Another inverting amplifier of gain −1 is added in series with the differentiator so that the overall gain of the circuit is 1.

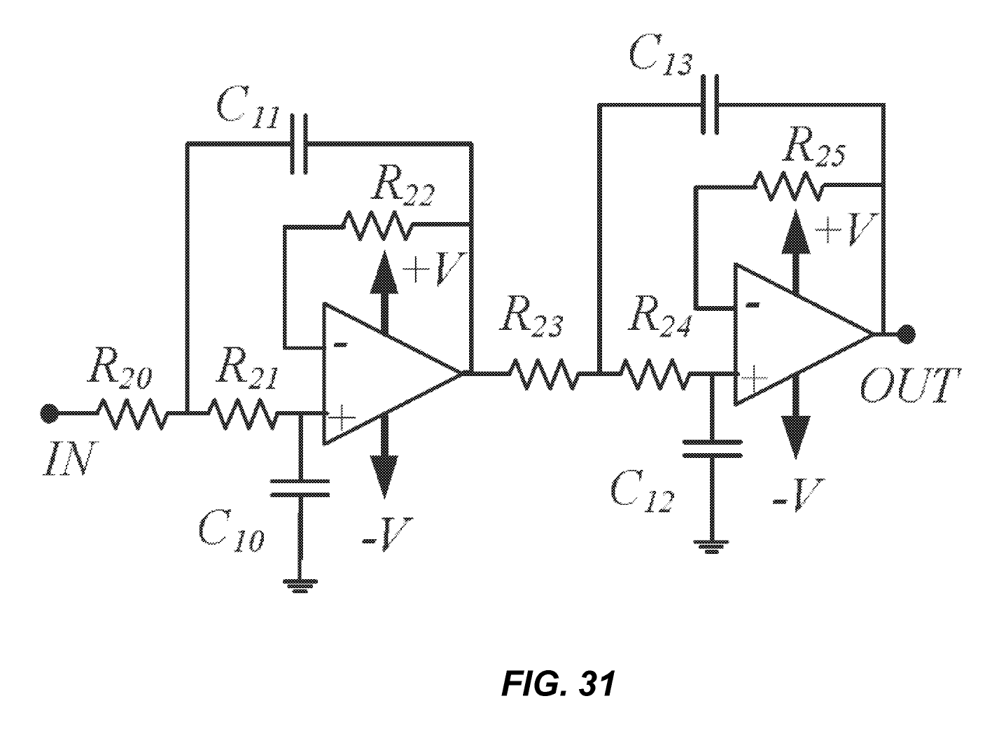

The first step of filtering does not eliminate the noise (high frequency component) altogether. Thus the differentiator may make this reminiscent noise prominent. Thus the signal can be further filtered to reduce noise using a low-order low-pass butter worth filter as shown in FIG. 31.

FIG. 31 shows a filter. The 4th order Butterworth low pass filter is implemented by cascading two 2nd order Butterworth low pass filters. The cut-off frequency of each stage is set to ω_{c}≈0.35ω. The purpose of this filter is to attenuate noise in the differentiator output signal.

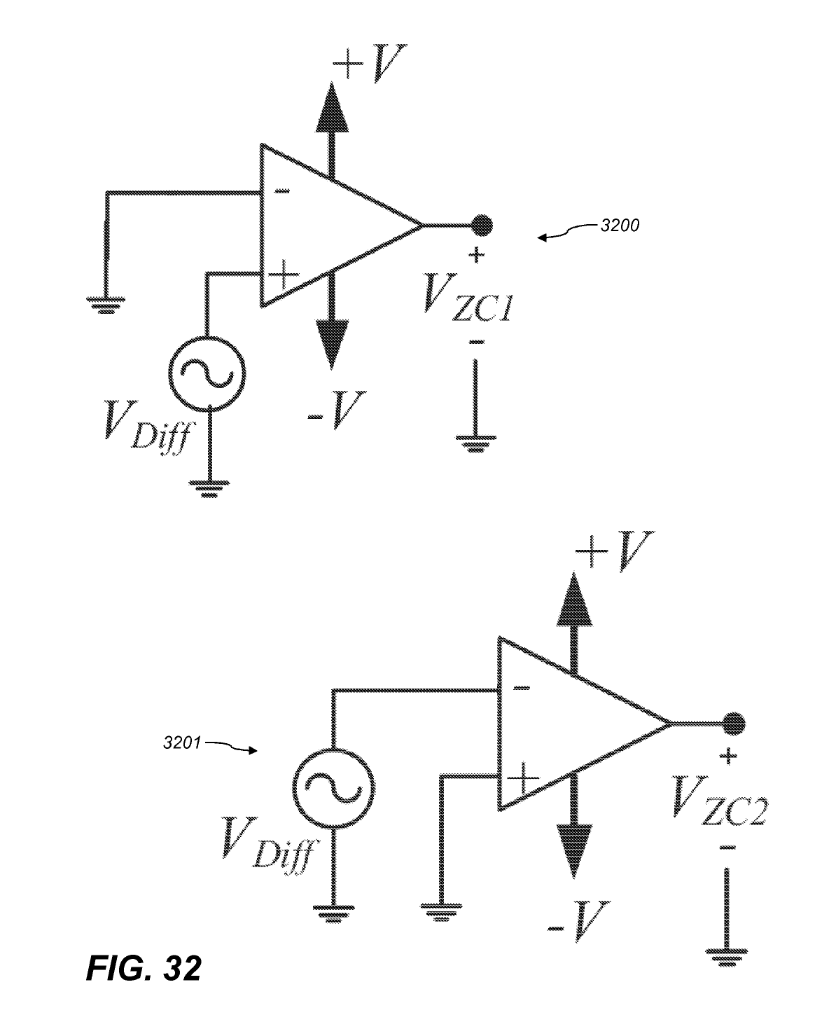

The filtered output of the differentiator is passed through both non-inverting and inverting zero-crossing detectors (see FIG. 32) to produce two pulse signals of the frequency equal to the natural frequency of the proof mass.

FIG. 32 shows zero-crossing detectors (ZCD) 3200, 3201. Detector 3200 is a non-inverting zero crossing detector. When the V_{diff} is positive, the output is +Vₛₐₜ. When the V_{diff} is positive, the output is +Vₛₐₜ. Detector 3201 is an inverting zero crossing detector. When the V_{diff} is positive, the output is +Vₛₐₜ. When the V_{diff} is positive, the output is +Vₛₐₜ. These circuits produce two controlling square wave signals of frequency substantially equal to the mechanical frequency of the MEMS.

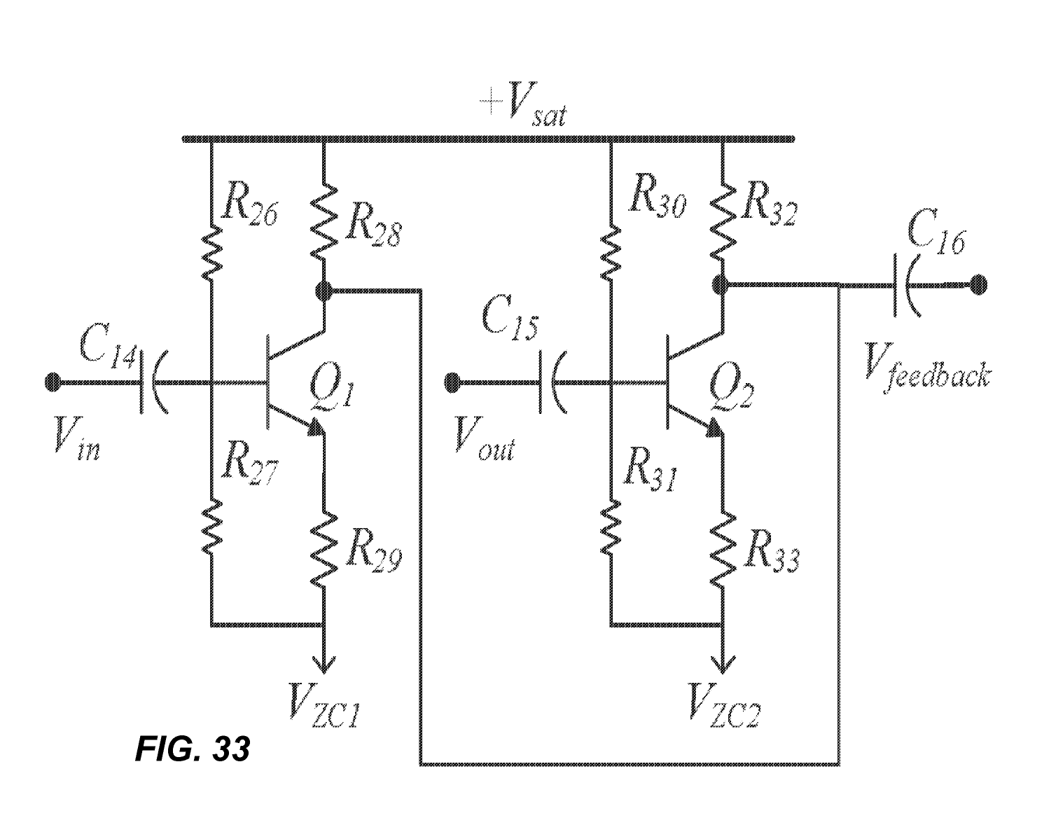

FIG. 33 shows a conditional circuit according to various aspects. The two square wave signals from zero-crossing detectors 3200, 3201 (FIG. 32) are applied to the conditional circuit. This circuit is implemented using two bipolar junction transistors. This circuit is designed so that, when the capacitance is decreasing, the output of the circuit is Vᵢₙ, and when the capacitance is increasing, the output of the circuit is Vₒᵤₜ. When the capacitance increases, the differentiator output is positive (i.e., positive slope) which causes V_{ZC1} to be equal to +Vₛₐₜ and V_{ZC2} to be equal to −Vₛₐₜ. Thus the Q1 transistor is driven to cut-off while tuning on the Q2 transistor. Thus the Vₒᵤₜ signal is provided as the feedback signal V_{feedback}. This signal is then fed back to the left comb drive 2640, which creates an electrostatic force to stop the rightward movement of the proof mass 2601 (both FIG. 26).

When the capacitance is decreasing, the differentiator output becomes negative (i.e., negative slope) which causes V_{ZC1} to be equal to −Vₛₐₜ and V_{ZC2} to be equal to +Vₛₐₜ. Thus the Q2 transistor is driven to cut-off while tuning on the Q1 transistor. Thus the Vᵢₙ signal is provided as the feedback signal V_{feedback}. Here, |Vₛₐₜ| is the saturation voltage of the op-amp.

The increase in capacitance indicates that the proof mass 2601 is moving towards the right due to an increase in comb finger overlap. Similarly, the decrease in the capacitance indicates that the proof mass 2601 is moving towards the left due to a decreasing comb finger overlap. The differentiator 2665 output senses these movements as a positive slope or a negative slope respectively, and generates square wave signals using the zero-crossing detectors 2675 to control the conditional circuit 2680 (all FIG. 26).

Still referring to FIG. 33, in various aspects, conditional circuit 2680 is implemented using two common emitter amplifiers. The positive biasing voltage is set as +Vₛₐₜ. The negative bias is given using the controlling signals V_{ZC1} and V_{ZC2}. When V_{ZC1} is equal to −Vₛₐₜ, V_{ZC2} is equal to +Vₛₐₜ. This makes the Q1 transistor ON and Q2 transistor OFF. When V_{ZC1} is equal to +Vₛₐₜ, V_{ZC2} is equal to −Vₛₐₜ. This makes the Q1 transistor OFF and Q2 transistor ON.

A simulation was performed to test the force feedback system shown in FIG. 26 by examining the outcome of each system component using typical parameter values. A comb drive device was simulated with the structural parameters: N=100, h=20 μm, g=2 μm and L0=20 μm. The maximum deflection amplitude due to noise is typically less than 1 nm in MEMS.

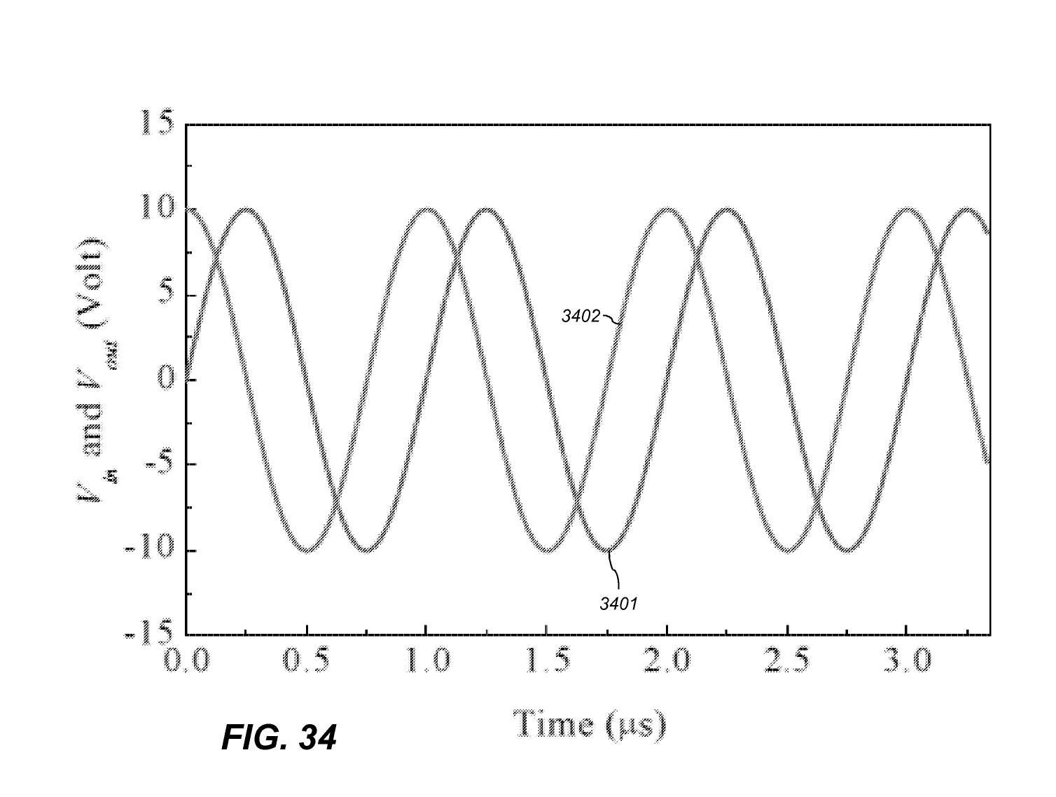

FIG. 34 shows a comparison between the output voltage Vₒᵤₜ and the input voltage Vᵢₙ to verify the approximations made. Curve 3401 is Vᵢₙ and curve 3402 is Vₒᵤₜ. There is a constant π/2 lag in the output signal from the input signal, as expected from the approximations. Here, the input signal frequency is taken as a 10V, 1 MHz sine wave, which is much higher than the natural frequency of the proof mass. Thus the phase modulation due to change in capacitance is negligible in this example. The gain of the circuit in FIG. 27 was chosen such that the input and output amplitude level is about the same. FIG. 10 shows the output of the multiplier containing high frequency component of ˜2 MHz.

FIG. 34 shows an exemplary comparison between Vᵢₙ and Vₒᵤₜ of the TIA (component from FIG. 27). The input signal is used to sense the change in comb drive capacitance through a trans-impedance amplifier (TIA). The two approximations ensure that there remains a constant π/2 phase difference between the two signals. The TIA was designed such that the amplitude of the output signal is same as the input signal.

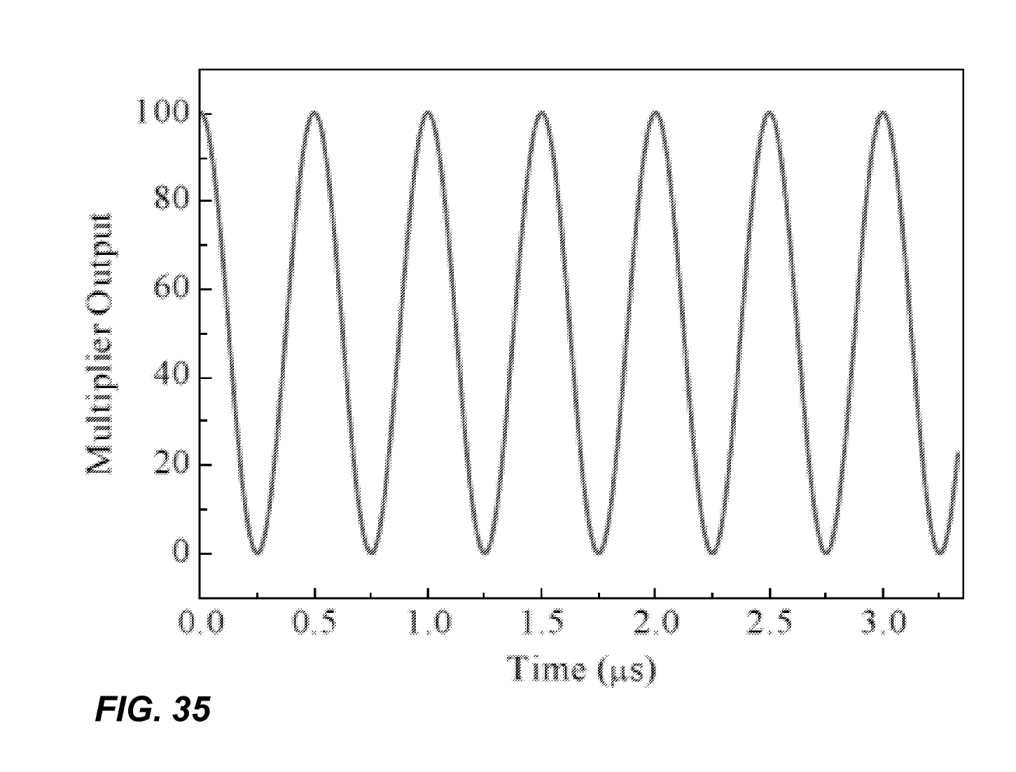

FIG. 35 shows an exemplary demodulated signal (component from FIG. 28). This demodulated signal comprises of two components. One of them is directly proportional to the comb drive capacitance and changes with a frequency equal to the mechanical frequency of the device. Another component changes very rapidly with a frequency equal to the twice the frequency of the input signal.

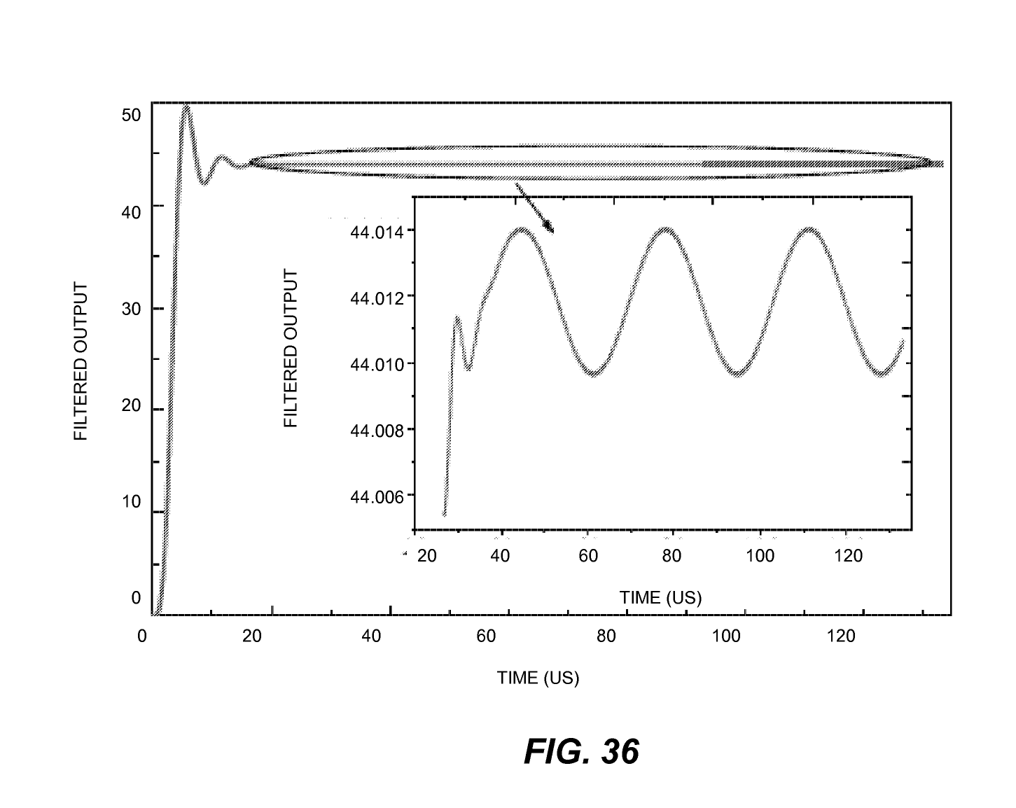

This output of the multiplier is passed through the 6th order low-pass Butterworth filter with roll-off of −140 dB/dec, as mentioned in FIG. 29, to eliminate the 2 MHz frequency component. The cut-off frequency was set to f_{C}=0.35 MHz. Thus a signal directly proportional to the change in capacitance is retrieved, as shown in FIG. 36.

FIG. 36 shows an exemplary filtered signal (component from FIG. 29). A 6th order low pass Butterworth filter is used to eliminate the higher frequency component from the demodulated signal. Thus the component directly proportional to the capacitance is left only. The output of the filter stabilized after about 30 μs and tracks the change in comb drive capacitance. As shown, e.g., in the inset, noise can be present but not render the circuit nonfunctional.

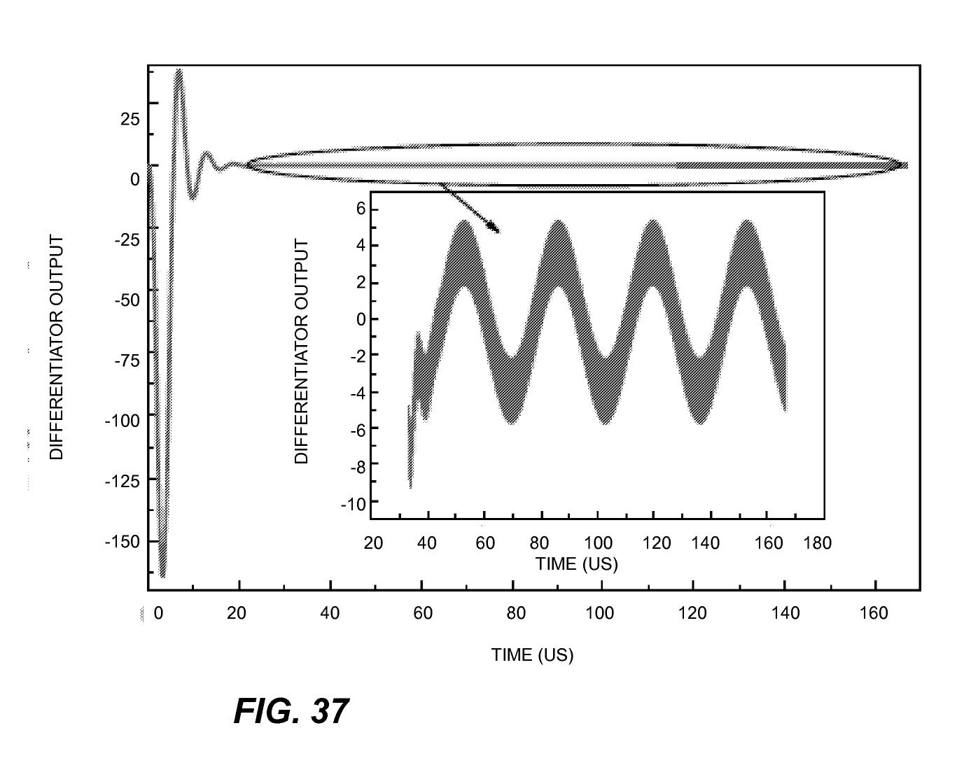

It can be observed that the output of the filter stabilizes after ˜30 μs. The direction of change in capacitance is determined with a differentiator which gives either a positive or negative voltage depending on whether the voltage is increasing or decreasing respectively. The output signal from the differentiator can be noisy due to the noises left after filtering, as shown in FIG. 37.

FIG. 37 shows an exemplary output signal from the differentiator (component from FIG. 30). A differentiator is used to track the direction of change in the comb drive capacitance (increasing or decreasing). The positive output from the differentiator indicates a positive slope, i.e., an increasing nature of the capacitance and vice versa. The differentiator increases the prominence of the leftover noise, e.g., as shown in the inset.

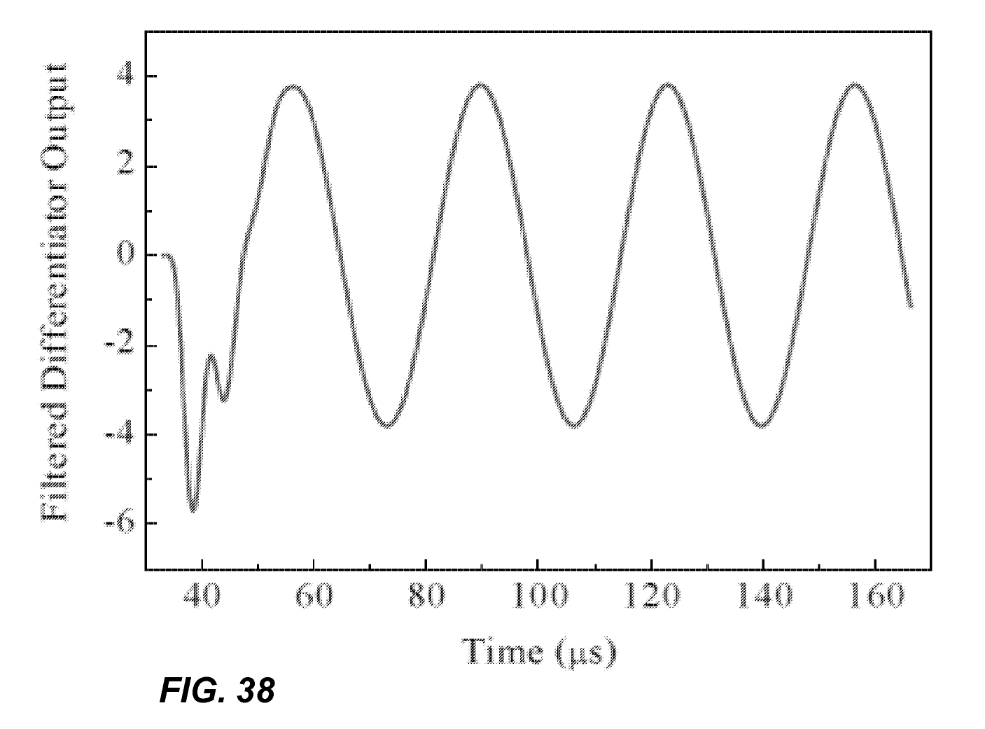

This signal can be filtered using a filter of same cut-off frequency (f_{C}=0.35 MHz). The filtered output is shown in FIG. 38. Thus the stabilizing time for the feedback circuit is increased to ˜50 μs.

FIG. 38 shows an exemplary filtered version of the differentiator signal (component from FIG. 31). The noise in the differentiator signal is reduced using a 4th order low pass Butterworth filter. This signal varies with a frequency same as the resonant frequency of the proof mass. It can be observed that further differentiating and filtering makes the stabilizing time to almost 50 μs.

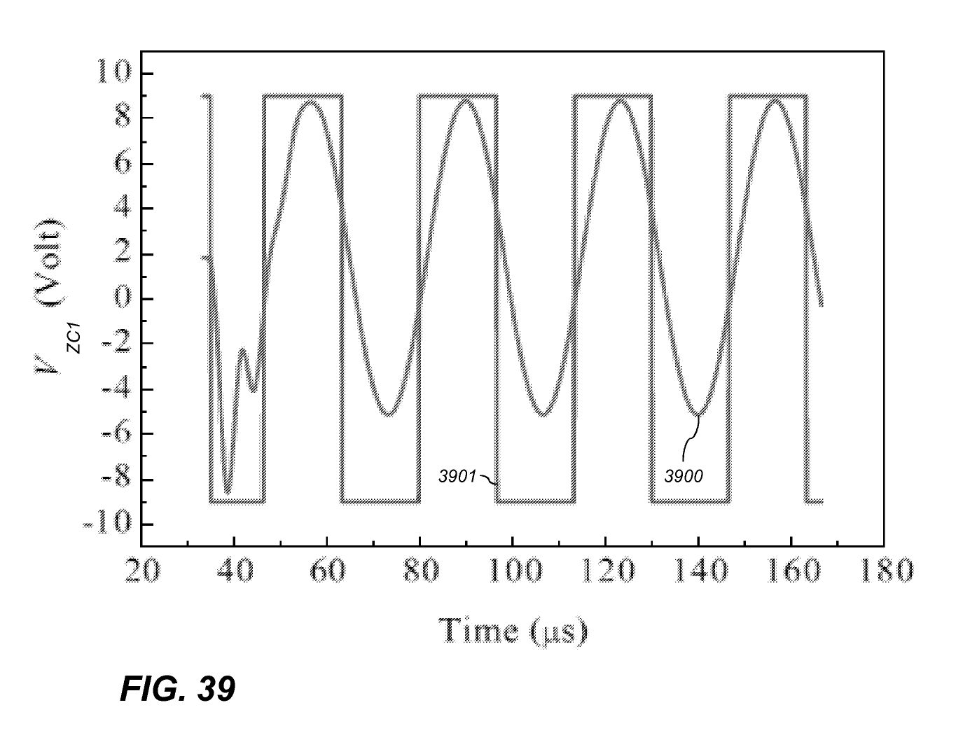

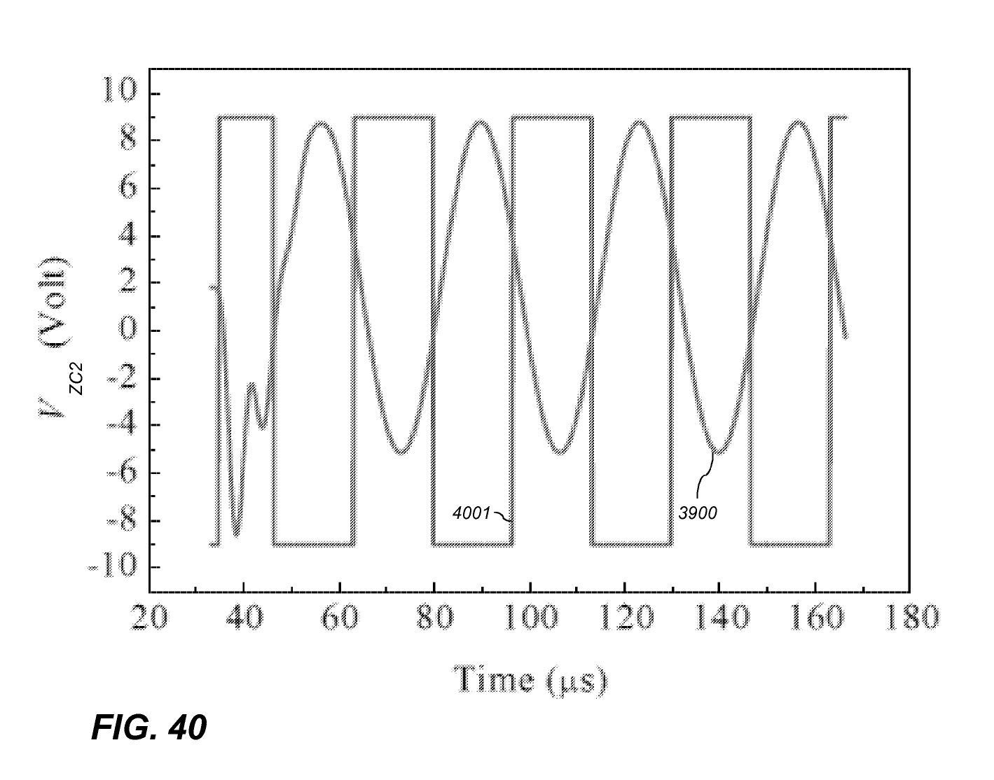

This signal is then fed to the two zero-crossing detectors described above. These two zero-crossing detectors produce square wave signals of same frequency at which the capacitance is varying. These square wave signals are shown in FIG. 39 and FIG. 40. These two signals are used to control the conditional circuit in FIG. 33, which keeps any one of the transistors ON at a time.

FIG. 39 shows an exemplary output signal from the non-inverting zero-crossing detector (component 3200 from FIG. 32). The output of the non-inverting zero-crossing detector (curve 3901) remains at +Vₛₐₜ as long as the differentiator output (ZCD input, curve 3900) remains positive and becomes −Vₛₐₜ as soon as the differentiator output becomes negative. Thus a square wave signal is generated which is of the same frequency of the comb drive capacitor.

FIG. 40 shows an exemplary output signal from the inverting zero-crossing detector (component 3201 from FIG. 32). The output of the inverting zero-crossing detector (curve 4001) remains at −Vₛₐₜ as long as the differentiator output (ZCD input, curve 3900) remains positive and becomes +Vₛₐₜ as soon as the differentiator output becomes negative. Thus a square wave signal is generated which is of the same frequency of the comb drive capacitor.

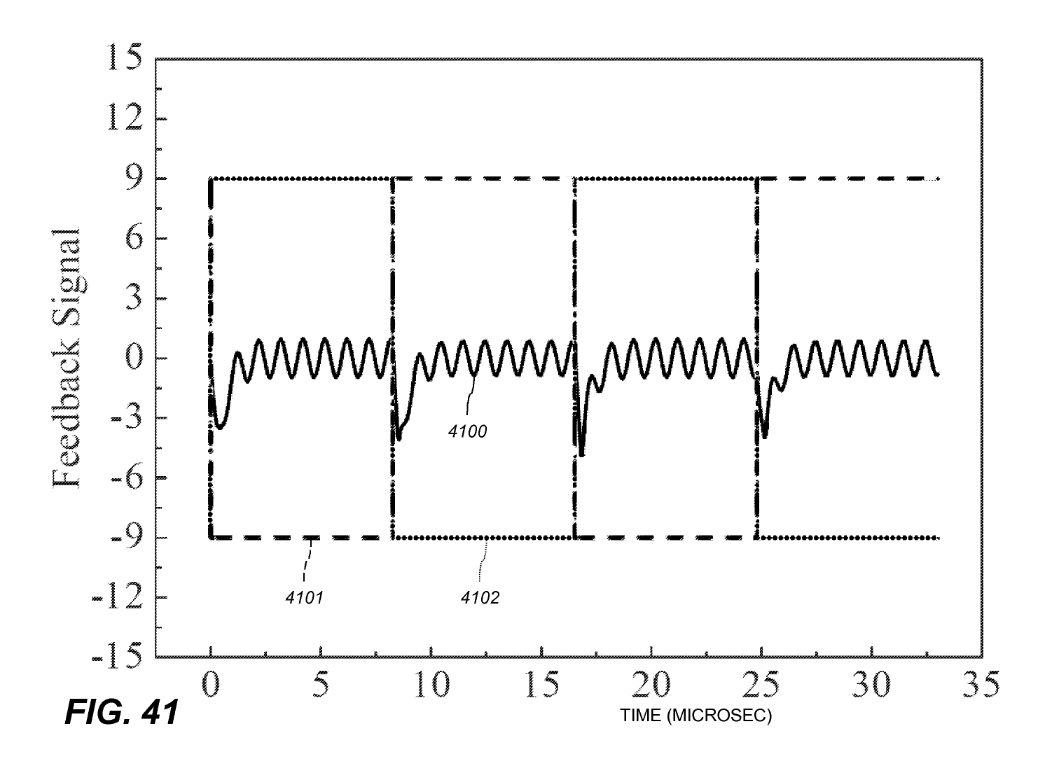

The feedback signal from the conditional circuit is shown in FIG. 41. It can be observed that there is a distortion when the ‘switching’ occurs. For a short period of time both the transistors become ON. This distortion exists for about 1.5 cycle of the original signal. Properly designing the circuit and using proper transistors can reduce this distortion.

FIG. 41 shows an exemplary feedback signal (component from FIG. 33). The complementary signals V_{ZC1} and V_{ZC2} make any one of the transistors in the conditional circuit ON and the other one OFF. Thus either Vᵢₙ or Vₒᵤₜ is passed through the circuit. The circuit is designed such that half the cycle of the mechanical movement, circuit passes Vₒᵤₜ (proof mass moves to the right) and passes Vᵢₙ in the other half of the cycle (proof mass moves to the left). Curve 4100 shows V_{feedback}, curve 4101 (dashed) shows V_{ZC1}, and curve 4102 (dotted) shows V_{ZC2}.

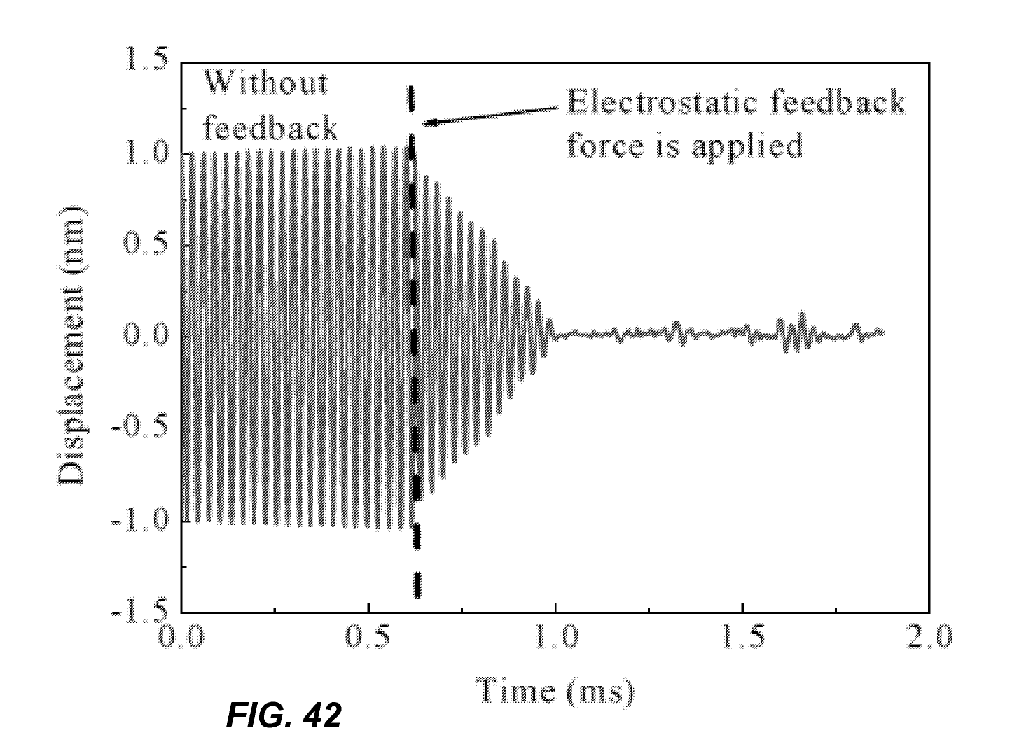

This feedback signal is applied to the left comb drive to create an electrostatic feedback force. When the proof mass of the device moves to the left, the net electrostatic force is ˜0 N, because the output of the conditional circuit is Vᵢₙ, so both plates of actuator 2640 (FIG. 26) have substantially the same voltage Vᵢₙ. But when the proof mass moves to the right, the feedback signal is equal to Vₒᵤₜ≠Vᵢₙ and the electrostatic force generated by the LHS comb drive is directly proportional to (Vₒᵤₜ−Vᵢₙ)² which opposes the movement of the proof mass. FIG. 42 shows that without the feedback system, the proof mass vibrates with amplitude of ˜1 nm. This amplitude is caused by noise disturbances. When the feedback system is turned on at t=0.6 ms, the noise starts to decay and eventually vanishes. In this simulation, white noise disturbance to induce vibration was emulated by applying very small but random mechanical forces at each time step throughout the simulation. The amount of maximum random disturbance force was chosen such that the amplitude of motion would eventually asymptote to about 1 nm, which is an upper bound amplitude for most MEMS due to various sources of parasitic noise. This convergence from 0 nm to and amplitude of ˜1 nm due to the white noise (random excitation forces) is not shown in FIG. 42. At 0.6 ms after this convergence, the force feedback system was activated. The force feedback system applied a force that is proportional to the velocity of the vibration during all rightward motion only. The effect was a significant decrease in vibrational amplitude as seen in FIG. 42.

FIG. 42 shows results of a simulation of an effect of electrostatic feedback force. The proof mass passively vibrates at its natural frequency with amplitude of ˜1 nm due to noise disturbances, without the feedback system being active. When the feedback system is turned on at t=0.6 ms, the electrostatic feedback force opposes the rightward movement of the proof mass, and has no effect to leftward movements. The opposing force to rightward motion reduces the amplitude that is caused by the presence of noise disturbances. The amplitude is greatly reduced.

Herein are described various aspects of an electrostatic force feedback circuit that can advantageously reduce the passive vibrations of MEMS that are due to parasitic disturbances such as thermal noise. Models and simulations of various integrated circuit components with a MEMS structure comprising of a pair of comb drives and folded flexure supports are described above. Various circuits herein sense motion with one comb drive and apply feedback forces with the other comb drive. The feedback force can be proportional to the velocity of the MEMS proof mass, such that the feedback force is similar to viscous damping common to simple mechanical systems. Simulation results demonstrate that the noise-induced amplitude in the MEMS device can be greatly reduced by applying electrostatic viscous force feedback. Various parameters can be adjusted to provide various strengths of under-, critical-, and overdamping.

Various aspects relate to methods and arrangements for measuring Young's modulus by electronic probing. Herein are described accurate and precise methods for measuring the Young's modulus of MEMS with comb drives by electronic probing of capacitance. The electronic measurement can be performed off-chip for quality control or on-chip after packaging for self-calibration. Young's modulus is an important material property that affects the static or dynamic performance of MEMS. Electrically-probed measurements of Young's modulus may also be useful for industrial scale automation. Conventional methods for measuring Young's modulus include analyzing stress-strain curves, which is typically destructive, or include analyzing a large array of test structures of varying dimensions, which requires a large amount of chip real estate. Methods herein measure Young's modulus by uniquely eliminating unknowns and extracting the fabricated geometry, displacement, comb drive force, and stiffness. Since Young's modulus is related to geometry and stiffness that can be determined using electronic measurands, Young's modulus can be expressed as a function of electronic measurands. Also described herein are results of a simulation using a method herein to predict the Young's modulus of a computer model. The computer model is treated as an experiment by using only on its electronic measurands. Simulation results show good agreement in predicting the exactly known Young's modulus in a computer model within 0.1%.

Young's modulus is one of the most important material properties that determine the performance of many micro electro mechanical systems (MEMS). There have been many methods developed for measuring the Young's modulus of MEMS. For example, Marshall in [D1] suggests the use of laser Doppler vibrometer for measuring the resonance frequency of an array of micromachined cantilevers to determine Young's modulus. This method requires the use of laboratory equipment, and requires the estimation of local density and geometry which can introduce significant error. The uncertainty of this method is reported to be about 3%. In [D2], Yan et al. uses a MEMS test to estimate Young's modulus using electronic probing. Yan's method requires the estimates of many unknowns, including parasitic capacitance, gap spacing, beam width, beam length, residual stress, permittivity, layer thickness, fillets, and displacement, which can introduce significant error in the measurement of Young's modulus. As a last example, in [D3], Fok et al. used an indentation method for measuring Young's modulus. That is, an indention force is applied causing surface deformation. The size of the deformed area is used to estimate Young's modulus, with unreported uncertainty. Various methods herein advantageously eliminate unknowns, and the uncertainty in measurement is quantifiable with just a single measurement. Various methods herein use electronic probing.

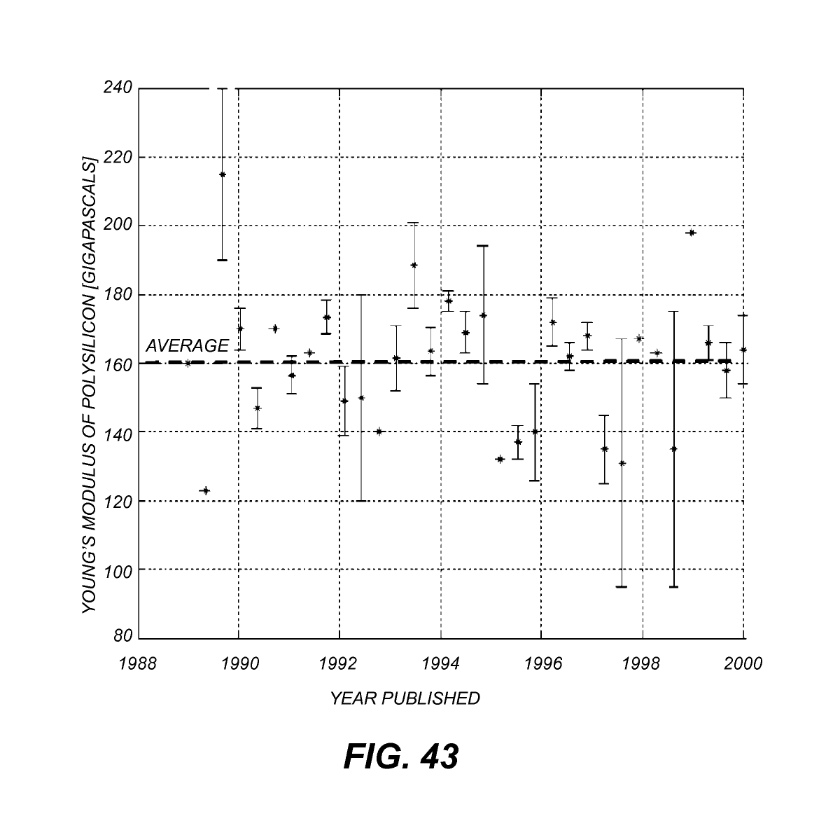

FIG. 43 shows data of the Young's modulus of polysilicon versus year published. Each data point corresponds to a different method to measure the polysilicon at various facilities. Data by Sharpe [D4]. The average measurement is 160 GPa (dashed line), with extreme values of 95 GPa and 240 GPa.

Presently, there is no ASTM standard for measuring micro-scale Young's modulus. This difficulty in developing a standard has to do with various methods not agreeing with each other and the difficulty in tracing the micro-scale measurement to an accepted macro-scale standard.

The need for an efficient and practical method for measuring the Young's modulus is critical due to process variation and the dependence of MEMS performance on Young's modulus. FIG. 43 shows the variation in the Young's modulus of polysilicon (the most common MEMS material). The data was collected from various fabrication runs, fabricated at various facilities, measured by various research groups, and using various measurement methods.

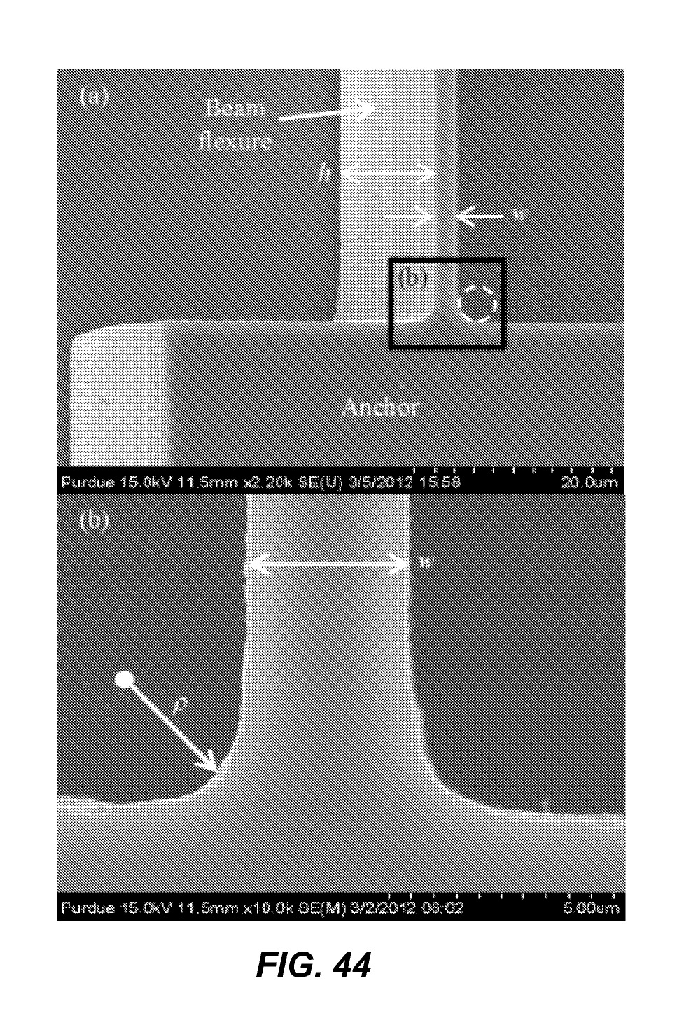

In addition to variations in material properties, upon fabrication there are also variations in geometry that can significantly affect performance. In [D5], Zhang did some work to show the high sensitivity between geometry and performance. It was found that a small change in geometry could lead to a large change from the predicted performance. FIG. 44 shows an image of a fabricated device. Typically, widths, gaps, and lengths are modified from layout geometry, and the sharp 90 degree corners became filleted. A benefit of fillets is that they reduce stress at the vertex upon beam bending. However, most models found in the literature ignore fillets, which actually have a measureable stiffening effect on beam deflection.

Various methods described herein predict the Young's modulus by including the presence of tapered beams to nearly eliminate the effect of fillets, and uses the measurement of stiffness to determine the Young's modulus. A herein-described analytical model for determining the stiffness and Young's modulus closely matches finite element analysis.

Herein are described a comparison of the effect of fillets due to fabrication upon beams with and without tapered ends; an analytical expression for the tapered beam which nearly eliminates the presence of fillets and can be used to obtain the Young's modulus; various methods of electro micro metrology (EMM) for measuring stiffness; and a simulated experiment to verify herein-described methods to extract Young's modulus.

Regarding filleted versus tapered beams, one problem with determining the Young's modulus of a flexure is the presence of fillets that appear at the locations of acute vertices. See FIG. 44. The presence of fillets tends to increase the effective stiffness of the flexure compared to having a sharp 90-degree vertex without a fillet. The effect of the fillet significantly affects static displacement and resonant frequency.

FIG. 44 shows a representation of electron micrographs of filleted vertices. Electron microscopy of a fabricated MEMS flexure attached to an anchor is shown. An angled view is shown in (a) and a zoomed-in portion of where the flexure is attached to the anchor is shown in (b). The layout width of the flexure is exactly 2 m, the corresponding fabricated width w is slightly less than 2 μm, the thickness h is about 20 μm, and the curvature of radius p of a fillet is about 1.5 μm. The layout geometry of this structure is prescribed with sharp 90 degree vertices; however, fillets form at all vertices as a consequence of the inaccurate fabrication process. Fillets appear to be unavoidable in some fabrication technologies.

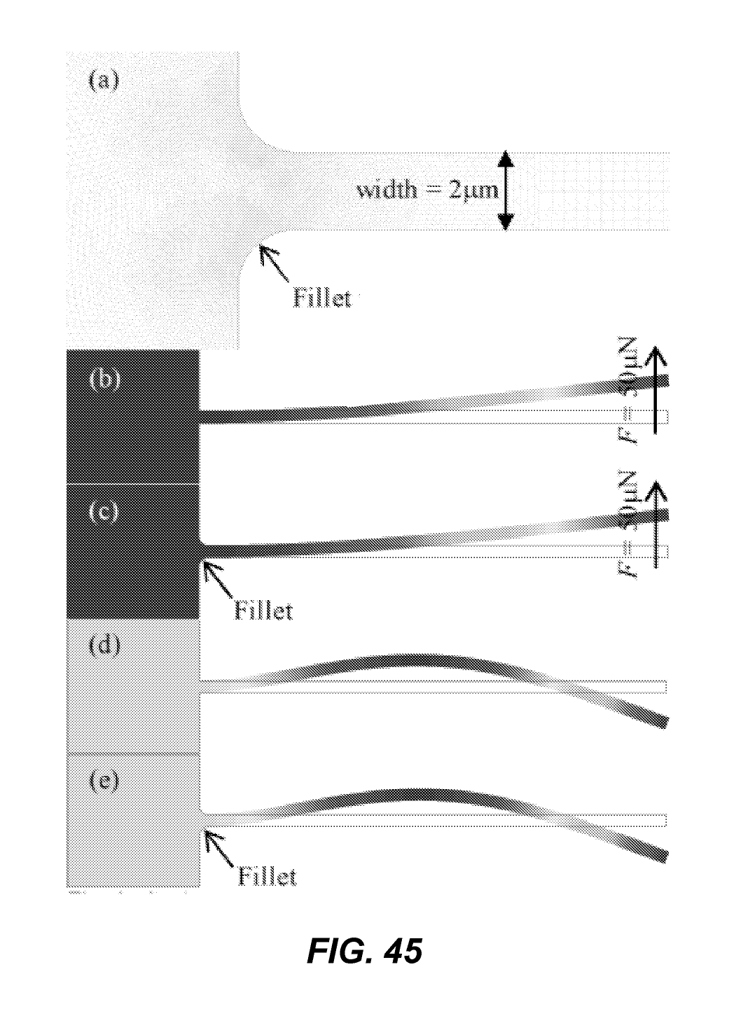

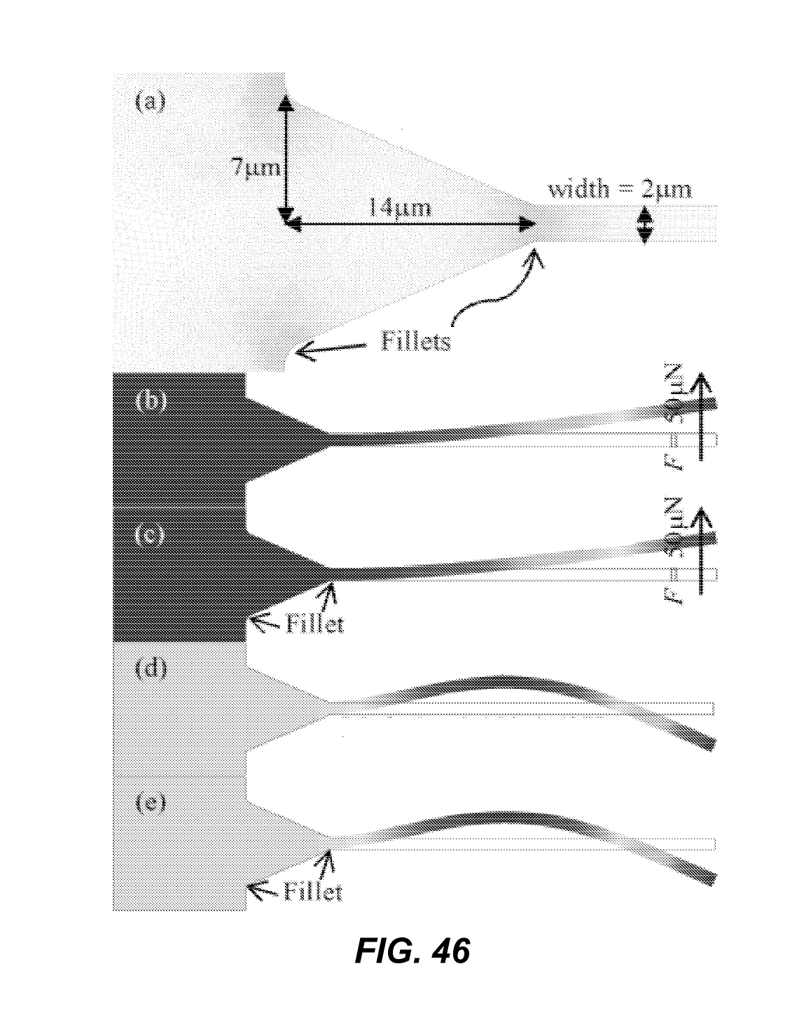

For example, FIGS. 45 and 46 compare the static displacement and resonant frequency of beams with and without fillets. The beams are otherwise identical. The beams have length of 100 μm, width of 2 μm, thickness of 20 μm, anchors of size 22 μm on a side, Young's modulus of 160 GPa, Poisson's ratio of 0.3, density of 2300 kg/m3, and vertical tip force of 50 mN. The filleted beam has a radius of curvature of 1.5 μm.

Simulations were done using finite element analysis using COMSOL [D6] with a high mesh refinement of over 32000 linear quadratic elements and over 130,000 degrees of freedom. FIG. 45, in (a), shows the mesh quality about the filleted region where the beam attaches to the anchor. FIG. 45, in (b) and (c), shows static deflection of non-filleted (3.827 m) and filleted (3.687 μm) cantilever beams, respectively. The relative error between the two types is 3.66%, where the filleted beam has a smaller vertical displacement due to increased stiffness from its fillets. FIG. 45, in (d) and (e), shows Eigen-frequency analysis between the non-filleted and filleted cantilevers, respectively. In (d), mode 1 is 433.5396 kHz and mode 2 is 2707.831 kHz. In (e), mode 1 is 444.4060 kHz and mode 2 is 2774.172 kHz. The relative error between the two types is −2.50% for mode 1 and −2.45% for mode 2, where the filleted beam resonates at higher frequencies due to increased stiffness due to the fillets.

FIG. 45 shows static and eigen-frequency simulations of cantilever beams with and without fillets. (a) shows an image of the type of mesh refinement for these FEA simulations. This close-up portion of the structure is where the beam attaches to the anchor. Number of elements is 32,256 linear quadratic and the number of degrees of freedom is 131,458. (b)-(c) show static deflections of the beams with vertical force of 100 mN applied at the right-most boundary. The left-most boundaries are fixed on all structures. The relative error between the static defections is 3.66%, which is large enough to cause a change in the second digit. The filleted beam has a smaller deflection due to the increased stiffness due to the fillets. (d)-(e) show eigen-frequency analysis for modes 1 and 2 between the nonfilleted and filleted structures. The relative errors of modes 1 and 2 are −2.50% and −2.45%, respectively. The filleted beam has higher resonance frequencies due to increased stiffness from the fillets. The mass of the fillets has a negligible effect because the location of the fillet is at a position that moves the least.

It is clear that fillets have a significant effect on the static and dynamics performance of MEMS. The analyst's problem is that it is difficult to predict what the radius of curvature will be for any one fabrication. To address this problem, various aspects described herein reduce the effect of fillets on flexures using tapered beam sections between the beam and anchor. Since a tapered beam has large obtuse angles, instead of sharp acute angles, any fillet that forms during fabrication should have a smaller effect on static and dynamic performances.

FIG. 46 shows a static and Eigenfrequency analysis for tapered beams. The analysis was the same as that performed for un-tapered beams (FIG. 45), except as shown or as discussed below. With a high mesh refinement of over 42,000 linear quadratic elements and over 170,000 degrees of freedom, FIG. 46, in (a), shows the mesh quality about the filleted region where a tapered beam has been placed between the straight beam and the anchor. (b) and (c) show static deflection of non-filleted (2.191 μm) and filleted (2.189 μm) tapered cantilever beams, respectively. The relative error between the two types is 0.091% (versus 3.66% for non-tapered cantilevers). The filleted beam has a slightly smaller vertical displacement due to increased stiffness from its fillets. (d) and (e) show eigen-frequency analysis between the non-filleted and filleted tapered cantilevers, respectively. In (d), mode 1 is 628260.4 kHz and mode 2 is 3888.614 kHz. In (e), mode 1 is 628763.5 kHz and mode 2 is 3891.521 kHz. The relative error between the two types is −0.080% for mode 1 and −0.075% for mode 2 (versus −2.50% and −2.45% for non-tapered cantilevers). The filleted tapered cantilever resonates at slightly higher frequencies due to increased stiffness due to the fillets.

FIG. 46 shows Static and Eigen-frequency simulations of tapered cantilever beams with and without fillets. (a) shows an image of the type of mesh refinement for these FEA simulations. This close-up portion of the structure is where a tapered beam is configured between the straight beam and the anchor. Number of elements is 42,240 linear quadratic and the number of degrees of freedom is 170,978. (b)-(c) show static deflections of the beams with vertical force of 50 μN applied at the right-most boundary. The left-most boundaries are fixed on all structures. The relative error between the static defections is 0.091%, which is small and causes a change in about the fourth significant digit. The filleted beam has a slightly smaller deflection due to the increased stiffness due to the fillets. (d)-(e) show eigen-frequency analysis for modes 1 and 2 between the non-filleted and filleted tapered structures. The relative errors of modes 1 and 2 are −0.080% and −0.075%, respectively. The filleted beam has slightly higher resonance frequencies due to increased stiffness from the fillets.

Tapering a flexure at the ends can thus reduce the significance of fillets. A curved tapering (i.e., tapered sections with curved sidewalls) that has a radius of curvature that is larger than what would be expected from any fabricated fillet can substantially reduce the filleting effect from fabrication. Below are described tapered sections with straight sidewalls.

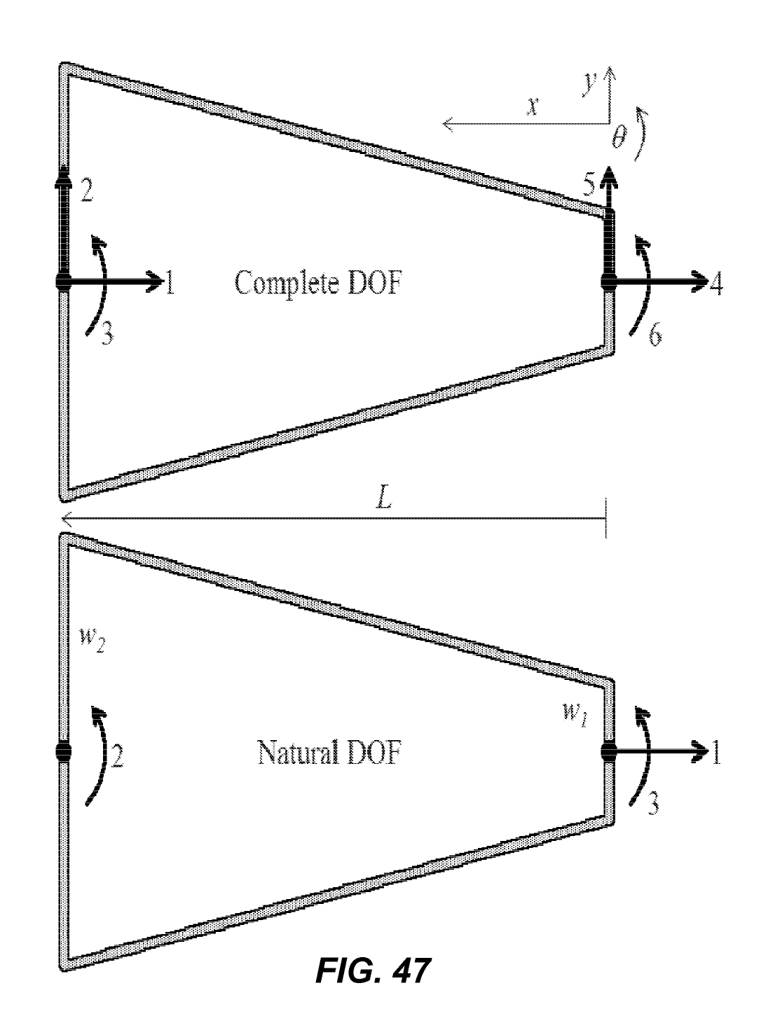

Below is described an analytical model and an exemplary method for predicting the Young's modulus. The analytical equation for finding the stiffness of a tapered element is developed as shown in FIG. 47 by using the method given in [D7-D8], and the result is compared below with the stiffness obtained from FEA.

The relation that can be used for predicting the Young's modulus is

k_{measured}=k_{model} (71)

where k_{model} is the stiffness from an analytical model and k_{measured} is the stiffness from an experiment such as herein-described methods of electro micro metrology (EMM) [D12]. An analytical model for the net stiffness is developed by using the matrix condensation [D7] technique to combine a tapered beam's stiffness matrix to a straight beam's stiffness matrix. The analytical model for the tapered beam is developed by using a method of virtual work [D8-D9]. “Virtual work” refers to applications of various techniques known in the physics art.

FIG. 47 shows a tapered beam component. The complete and natural degrees of freedom for a tapered beam are shown. It has dimensions of length L, thickness h, Young's modulus E, moment of area hw³_{tapered}/12 and it tapers from width w₂ to w₁, where w_{tapered}(x)=w₁+(w₂−w₁)x/L. The left boundary will be anchored and the right boundary will be attached to a straight beam.

As shown in FIG. 47, consider a 2D tapered beam compact element with 6 degrees of freedom (x, y, θ) at each end node. As explained in [D8-D9] a relation between complete degrees of freedom and natural degrees of freedom is obtained by constructing a transformation matrix. The flexibility matrix f for the system is created by using the method of virtual work. Each matrix element in the flexibility matrix fᵢⱼ is the displacement at degree of freedom i when a unit real force is placed at degree of freedom j where all other degrees of freedom are held at zero. The flexibility matrix for the natural system is:

$${D}_{n} = [ \begin{matrix}{f}_{11} & {f}_{12} & {f}_{13} \\ {f}_{21} & {f}_{22} & {f}_{23} \\ {f}_{31} & {f}_{32} & {f}_{33}\end{matrix} ] \qquad ( 72 )$$

By Maxwell's Theorem of Reciprocal Displacements [D10] the flexibility matrix is symmetric and since f₁₂=f₂₁=0 and f₁₃=f₃₁=0 it is necessary to find only f₁₁, f₂₂, f₃₃, and f₂₃. For the tapered component shown in FIG. 47, the cross section area along the length is:

$$A = ( {w}_{1} + \frac{{w}_{2} - {w}_{1}}{L} x ) h \qquad ( 73 )$$

To find the flexibility coefficient, f₁₁, a unit real load is placed at degree of freedom 1 in the natural system. This gives N(x)=1. A virtual load placed at degree of freedom 1 in the natural system gives n(x)=1. By using the method of virtual work for axial displacements, f₁₁ is computed as:

$${f}_{11} = {\int }_{0}^{L} \frac{N ( x ) n ( x )}{AE} d x = \frac{L {log}_{10} ( {w}_{2} / {w}_{1} )}{( {w}_{2} - {w}_{1} ) Eh} \qquad ( 74 )$$

To find f₂₂, a unit real load placed at degree of freedom 2 in the natural system gives the moment of M(x)=x/L−1. Placing a unit virtual load at degree of freedom 2 in the natural system gives the moment of m(x)=x/L−1. By using the virtual method for flexural displacements the flexibility coefficient is calculated to be

$$\begin{matrix}{f}_{22} = {\int }_{0}^{L} \frac{M ( x ) m ( x )}{IE} d x \\ = - \frac{6 L ( 3 {w}_{1}^{2} - 4 {w}_{1} {w}_{2} + {w}_{2}^{2} - 2 {w}_{1}^{2} {log}_{10} ( {w}_{1} / {w}_{2} ) )}{{( {w}_{1} - {w}_{2} )}^{3} Eh}\end{matrix} \qquad ( 75 )$$

To find f₃₃, a unit real load placed at degree of freedom 3 in the natural system gives the moment of M(x)=x/L. Placing a unit virtual load at degree of freedom 3 in the natural system gives the moment of m(x)=x/L. By using the virtual method for flexural displacements the flexibility coefficient is calculated to be

$$\begin{matrix}{f}_{33} = {\int }_{0}^{L} \frac{M ( x ) m ( x )}{IE} d x \\ = \frac{6 L ( 3 + {w}_{1}^{2} / {w}_{2}^{2} - 4 {w}_{1} / {w}_{2} + 2 {log}_{10} ( {w}_{1} / {w}_{2} ) )}{{( {w}_{1} - {w}_{2} )}^{3} Eh}\end{matrix} \qquad ( 76 )$$

To find f23, a unit real load placed at degree of freedom 3 in the natural system gives the moment of M(x)=x/L. Placing a unit virtual load at degree of freedom 2 in the natural system gives the moment of m(x)=x/L−1. By using the virtual method for flexural displacements the flexibility coefficient is calculated to be

$$\begin{matrix}{f}_{23} = {\int }_{0}^{L} \frac{M ( x ) m ( x )}{IE} d x \\ = - \frac{6 L ( {w}_{1}^{2} - {w}_{2}^{2} - 2 {w}_{1} {w}_{2} {log}_{10} ( {w}_{1} / {w}_{2} ) )}{{w}_{1} {{w}_{2} ( {w}_{1} - {w}_{2} )}^{3} Eh}\end{matrix} \qquad ( 77 )$$

The above equations can be substituted into the flexibility matrix. The transformation matrix F from the natural to the complete degrees of freedom is [D9]

$$Γ = [ \begin{matrix}- 1 & 0 & 0 & 1 & 0 & 0 \\ 0 & 1 / L & 1 & 0 & - 1 / L & 0 \\ 0 & 1 / L & 0 & 0 & - 1 / L & 1\end{matrix} ] \qquad ( 78 )$$

The stiffness matrix for the tapered beam is

$$\begin{matrix}{k}_{tapered} = {Γ}^{T} ( {D}_{n}^{- 1} ) Γ \\ = [ \begin{matrix}{k}_{11} & 0 & 0 & - {k}_{11} & 0 & 0 \\ 0 & {k}_{22} & {k}_{23} & 0 & - {k}_{22} & {k}_{26} \\ 0 & {k}_{23} & {k}_{33} & 0 & - {k}_{23} & {k}_{36} \\ - {k}_{11} & 0 & 0 & {k}_{11} & 0 & 0 \\ 0 & - {k}_{22} & - {k}_{23} & 0 & {k}_{22} & - {k}_{26} \\ 0 & {k}_{26} & {k}_{36} & 0 & - {k}_{26} & {k}_{66}\end{matrix} ]\end{matrix} \\ where \\ {k}_{11} = \frac{- {f}_{23}^{2} + {f}_{22} {f}_{33}}{- {f}_{11} {f}_{23}^{2} + {f}_{11} {f}_{22} {f}_{33}} , \\ {k}_{22} = \frac{{f}_{11} {f}_{22} - 2 {f}_{11} {f}_{23} + {f}_{11} {f}_{33}}{( - {f}_{11} {f}_{23}^{2} + {f}_{11} {f}_{22} {f}_{33} ) {L}^{2}} , \\ {k}_{23} = \frac{- {f}_{11} {f}_{23} + {f}_{11} {f}_{33}}{( - {f}_{11} {f}_{23}^{2} + {f}_{11} {f}_{22} {f}_{33} ) L} , \\ {k}_{26} = \frac{- {f}_{11} {f}_{23} + {f}_{11} {f}_{22}}{( - {f}_{11} {f}_{23}^{2} + {f}_{11} {f}_{22} {f}_{33} ) L} , \\ {k}_{33} = \frac{{f}_{11} {f}_{33}}{( - {f}_{11} {f}_{23}^{2} + {f}_{11} {f}_{22} {f}_{33} )} , \\ {k}_{36} = - \frac{{f}_{11} {f}_{23}}{( - {f}_{11} {f}_{23}^{2} + {f}_{11} {f}_{22} {f}_{33} )} , and \\ {k}_{66} = \frac{{f}_{11} {f}_{22}}{( - {f}_{11} {f}_{23}^{2} + {f}_{11} {f}_{22} {f}_{33} )} . \qquad ( 79 )$$

Similarly, using the method of virtual work for a straight beam of length l and a moment of area I=hw₁³/12, K_{beam} is:

$${K}_{beam} = [ \begin{matrix}EA / l & 0 & 0 & - EA / l & 0 & 0 \\ 0 & 12 c & 6 cl & 0 & - 12 c & 6 cl \\ 0 & 6 cl & 4 {cl}^{2} & 0 & - 6 cl & 2 {cl}^{2} \\ - EA / l & 0 & 0 & EA / l & 0 & 0 \\ 0 & - 12 c & - 6 cl & 0 & 12 c & - 6 cl \\ 0 & 6 cl & 2 {cl}^{2} & 0 & - 6 cl & 4 {cl}^{2}\end{matrix} ] \qquad ( 80 )$$

where A=w₁h is the cross-sectional area of the straight beam and c=EI/l³.

Combining the tapered (79) and straight (80) stiffnesses into a single flexure, the net flexure stiffness is:

$${k}_{net} = [ \begin{matrix}{K}_{11} & 0 & 0 & {K}_{14} & 0 & 0 \\ 0 & {K}_{22} & {K}_{23} & 0 & {K}_{25} & {K}_{26} \\ 0 & {K}_{23} & {K}_{33} & 0 & - {K}_{26} & {K}_{36} \\ {K}_{14} & 0 & 0 & - {K}_{14} & 0 & 0 \\ 0 & {K}_{25} & - {K}_{26} & 0 & - {K}_{25} & - {K}_{26} \\ 0 & {K}_{26} & {K}_{36} & 0 & - {K}_{26} & {K}_{66}\end{matrix} ] \\ where \\ {K}_{66} = 4 {cl}^{2} , {K}_{14} = - EA / l , {K}_{22} = {k}_{22} + 12 c , \\ {K}_{23} = - {k}_{26} + 6 cl , {K}_{11} = {k}_{11} + EA / l , {K}_{33} = {k}_{66} + 4 {cl}^{2} , \\ {K}_{36} = 2 {cl}^{2} , {K}_{25} = - 12 c , and {K}_{26} = 6 cl \qquad ( 81 )$$

and where the right boundary of the flexure is anchored at the location where the width is w₂, whereby eliminating the rows and columns of the anchored boundary node.

Considering a vertically applied force located at the right free end of the flexure,

$${F}_{applied} = [ \begin{matrix}0 \\ 0 \\ 0 \\ 0 \\ - F \\ 0\end{matrix} ] , \qquad ( 82 )$$

the stiffness seen by the vertical displacement at the point of application of the force is

$${k}_{model} = \frac{( \begin{matrix}2 {K}_{26}^{2} {K}_{23} {K}_{26} - {K}_{26}^{4} - {K}_{26}^{2} {K}_{23}^{2} + \\ {K}_{26}^{2} {K}_{22} {K}_{33} - 2 {K}_{22} {K}_{36} {K}_{26}^{2} + \\ {K}_{25} {K}_{33} {K}_{26}^{2} - 2 {K}_{25} {K}_{36} {K}_{26}^{2} + \\ {K}_{22} {K}_{66} {K}_{26}^{2} - {K}_{36}^{2} ( {K}_{25}^{2} + {K}_{22} {K}_{25} ) - \\ {K}_{25} {K}_{23}^{2} {K}_{66} + {K}_{66} {K}_{25}^{2} {K}_{33} + \\ 2 {K}_{23} {K}_{25} {K}_{26} {K}_{66} + {K}_{22} {K}_{25} {K}_{33} {K}_{66}\end{matrix} )}{( \begin{matrix}{K}_{66} {K}_{23}^{2} - 2 {K}_{23} {K}_{26} {K}_{36} + {K}_{33} {K}_{26}^{2} + \\ {K}_{22} {K}_{36}^{2} - {K}_{22} {K}_{33} {K}_{66}\end{matrix} )} . \qquad ( 83 )$$

Using the parameters of the filleted test case shown in FIG. 46 at (c), i.e., tapered length L=14 μm, w₁=2 μm, w₂=14 μm, thickness h=20 μm, E=160 GPa, force of F=50 N, w=2 μm, and 1=64 μm, from (83) the stiffness is computed to be k_{model}=22.8393 N/m. Comparing this value of stiffness to the simulation in FIG. 46 (at (c)) with fillets where F/y=k_{4c}=22.8415 N/m, this compact model has a relative error of −0.0096%.

(83) is then used to determine the Young's modulus of a fabricated device. That is, the fabricated stiffness is measured using EMM, then that stiffness is modeled using (83) without the Young's modulus since it is the unknown. The true Young's modulus is thus:

$${E}_{measured} = \frac{{k}_{measured}}{{k}_{model} / {E}_{model}} . \qquad ( 84 )$$

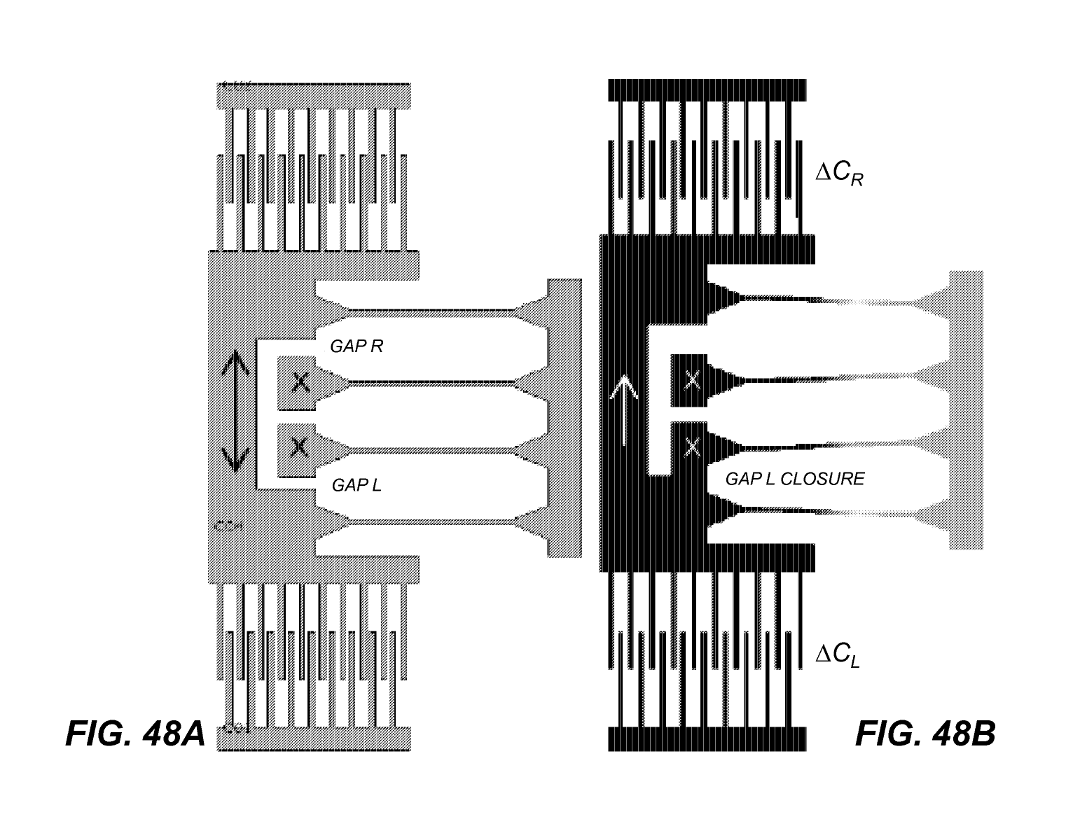

Regarding stiffness measurement using Electro Micro Metrology, below is described a theoretical basis for a measurement of system stiffness using electro micro metrology [D11-D12]. AN exemplary method involves applying the following steps to states of a structure such as the one shown in FIGS. 48A-B.

FIGS. 48A and 48B show a MEMS structure and measurement of stiffness. The structure includes comb drives and two unequal gaps (gapL and gapR), which are used for self-calibration. Anchors are identified with an “X”. The images show an undeflected zero state (FIG. 48A) and a state where one of the gaps (gapL) is closed (FIG. 48B). The zero state provides C₀ measurement. Applied voltages provide ΔC_{L} and ΔC_{R} by traversing gaps gap_{L} and gap_{R}.

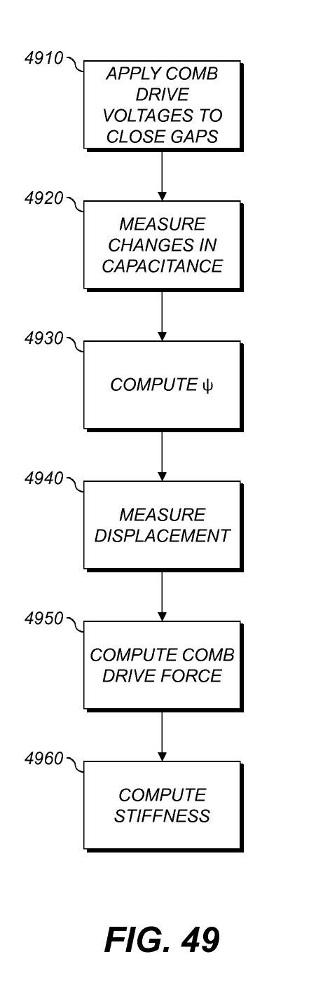

FIG. 49 shows an exemplary method of determining stiffness. Referring to FIG. 49, and for exemplary purposes only to FIGS. 48A and 48B, without limitation to the structures shown therein, in step 4910, a sufficient amount of comb drive voltage is applied to close each gap (gap_{R} and gap_{L}). In step 4920, the changes in the capacitance (ΔC_{L} and ΔC_{R}) are measured. In step 4930, the comb drive constant ψ is the ratio of change in comb drive capacitance to displacement, is computed, e.g., as

$$\begin{matrix}\text{?} & ( 85 ) \\ Ψ ≡ Δ C / {gap}_{R} = Δ C / y . \\ \text{?} \text{indicates text missing or illegible when filed} & ( 15 )\end{matrix}$$

[symbol]

In subsequent step 4940, a displacement of the comb drive is measured using the relation in (85) as

y=ΔC/Ψ. (86)

In step 4950, the comb drive force is computed as

F≡½V²∂C/∂x=½V²Ψ. (87)

In step 4960, stiffness is computed. The system stiffness is defined as k≡F/Δy. Using the expressions of displacement (86) and force (87), nonlinear stiffness can be computed as

$${k}_{measured} ≡ \frac{F}{y} = \frac{{V}^{2} {Ψ}^{2}}{2 Δ C} \qquad ( 88 )$$

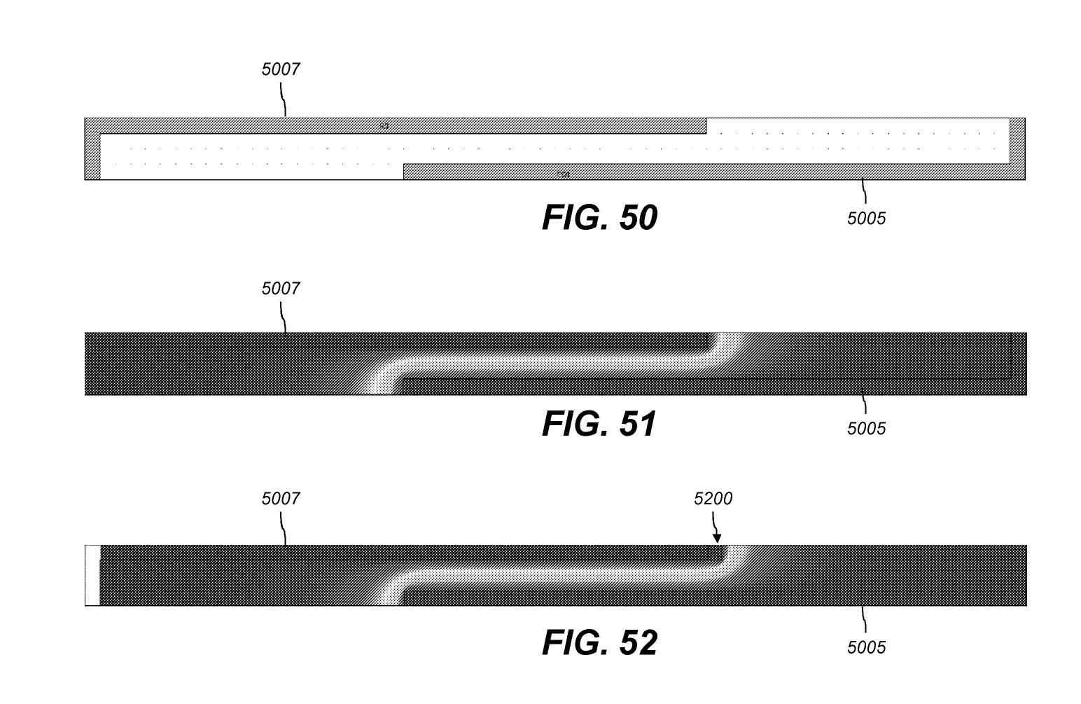

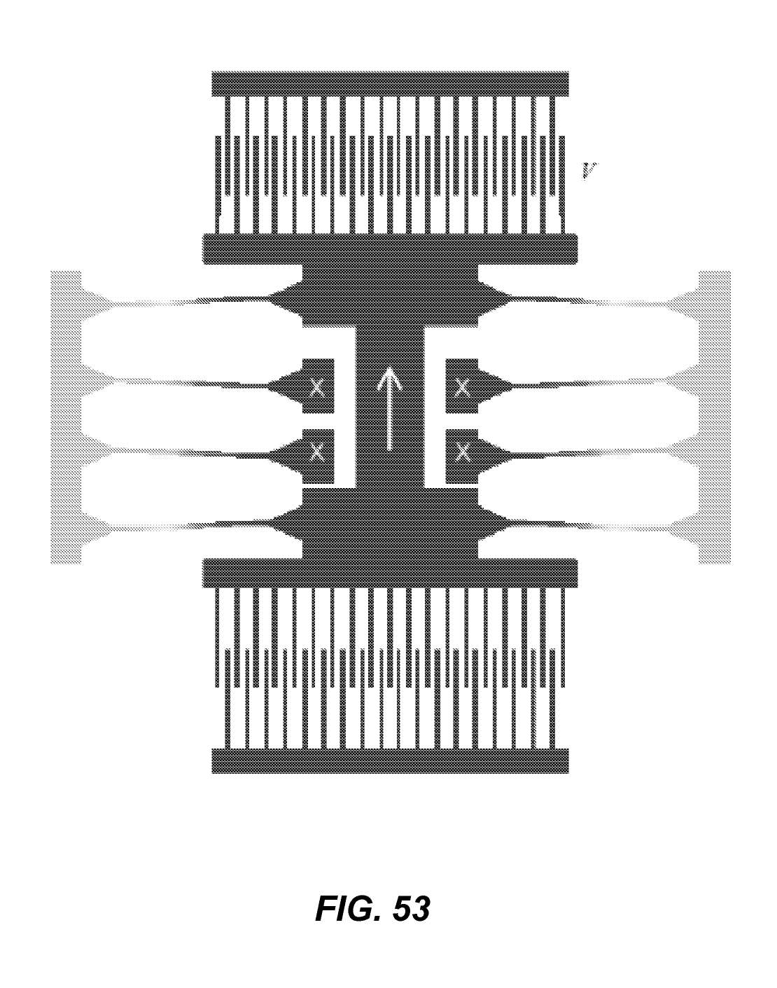

FIGS. 50-52 relate to the comb drive constant. FIG. 50 shows the configuration of the portion of a comb drive. FIG. 51 shows results of a simulation of its position at an initial state. FIG. 52 shows results of a simulation of its position at an intermediate state. A shift is visible, e.g., at point 5200 in FIG. 52. The upper comb finger represents the rotor 5007. The lower comb finger represents the stator 5005. About 21000 mesh elements can be used to converge to a comb drive constant of ψ=4.942×10⁻¹⁰ F/m. Finger gap is 2 μm, length is 40 μm, and initial overlap is 20 μm.

FIG. 53 shows static deflection for stiffness. A static deflection of 0.2698 μm results from an applied 50V, which generates a force of F=6.1719×10⁻⁷ N. The deflection shown in FIG. 53 is magnified. The smallest feature size is 2 μm. The simulation is done with 34000 finite quadratic elements. The relative error in the stiffnesses between that of the computer model and that of (88) is 0.138%.

A simulated experiment (SE) was performed. This was done because some experimental measurement methods for Young's modulus have unknown accuracy and an uncertainty larger than numerical error. In SE, measurements of capacitance are emulated, because capacitance would be one type of measurement that is available in a true experiment. As discussed above, by measuring the capacitance required to close 2 unequal gaps, system stiffness (88) of the structure under test can be obtained.

Regarding comb drive constant, to improve precision through convergence analysis through finite element mesh refinement using a maximal number of elements, the comb drive constant was modeled separately from mechanical properties of the structure. By assuming that each comb drive finger can be modeled identically in their totality, a single comb finger section can be modeled as shown in FIGS. 50-52. Using 21000 quadratic finite elements, the comb drive constant converged in simulation to ψ=4.942×10⁻¹⁰ F/m.

Regarding stiffness, using 34000 mechanical elements, a simulated comb drive force was applied using a voltage of 50V and the corresponding change in capacitance was simulated (see FIG. 53). Substituting these values into (88), the SE stiffness of the structure was determined to be

k_{measured}=22.907N/m. (89)

By substituting (89) into (84), the measured Young's modulus was determined to be E_{measured}=160.18 GPa. The true Young's modulus (i.e., the Young's modulus provided as input to the FEA model) is exactly Eₜᵣᵤₑ=160 GPa. So the SE prediction of Young's modulus has a relative error of 0.11%.

Material properties and geometries as fabricated are often significantly different than what was predicted from simulation and layout geometry. One of the geometric changes is the formation of fillets, which have a radius of curvature that is difficult to predict, and the fillets can have a significant effect on stiffness. Another property that changes is Young's modulus, which is difficult to measure due to non-accurate measurements of stiffness. Various methods and systems described herein substantially reduce the effect of fillets by using tapered beams. Various methods and systems described herein permit accurate, precise, and practical measurement of Young's modulus by measuring stiffness. An exemplary method was tested using a simulated experiment and showed agreement with true values of Young's modulus to within 0.11%.

In view of the foregoing, various aspects measure differential capacitance. A technical effect is to permit determination of mechanical properties of MEMS structures, which can in turn permit determination of, e.g., temperature, orientation, or motion of the MEMS device.

Throughout this description, some aspects are described in terms that would ordinarily be implemented as software programs. Those skilled in the art will readily recognize that the equivalent of such software can also be constructed in hardware (hard-wired or programmable), firmware, or micro-code. Accordingly, aspects of the present invention may take the form of an entirely hardware embodiment, an entirely software embodiment (including firmware, resident software, or micro-code), or an embodiment combining software and hardware aspects. Software, hardware, and combinations can all generally be referred to herein as a “service,” “circuit,” “circuitry,” “module,” or “system.” Various aspects can be embodied as systems, methods, or computer program products. Because data manipulation algorithms and systems are well known, the present description is directed in particular to algorithms and systems forming part of, or cooperating more directly with, systems and methods described herein. Other aspects of such algorithms and systems, and hardware or software for producing and otherwise processing signals or data involved therewith, not specifically shown or described herein, are selected from such systems, algorithms, components, and elements known in the art. Given the systems and methods as described herein, software not specifically shown, suggested, or described herein that is useful for implementation of any aspect is conventional and within the ordinary skill in such arts.

FIG. 54 is a high-level diagram showing the components of an exemplary data-processing system for analyzing data and performing other analyses described herein. The system includes a data processing system 5410, a peripheral system 5420, a user interface system 5430, and a data storage system 5440. The peripheral system 5420, the user interface system 5430 and the data storage system 5440 are communicatively connected to the data processing system 5410. Data processing system 5410 can be communicatively connected to network 5450, e.g., the Internet or an X.25 network, as discussed below. For example, controller 1186 (FIG. 11) can include one or more of systems 5410, 5420, 5430, 5440, and can connect to one or more network(s) 5450.

The data processing system 5410 includes one or more data processor(s) that implement processes of various aspects described herein. A “data processor” is a device for automatically operating on data and can include a central processing unit (CPU), a desktop computer, a laptop computer, a mainframe computer, a personal digital assistant, a digital camera, a cellular phone, a smartphone, or any other device for processing data, managing data, or handling data, whether implemented with electrical, magnetic, optical, biological components, or otherwise.

The phrase “communicatively connected” includes any type of connection, wired or wireless, between devices, data processors, or programs in which data can be communicated. Subsystems such as peripheral system 5420, user interface system 5430, and data storage system 5440 are shown separately from the data processing system 5410 but can be stored completely or partially within the data processing system 5410.

The data storage system 5440 includes or is communicatively connected with one or more tangible non-transitory computer-readable storage medium(s) configured to store information, including the information needed to execute processes according to various aspects. A “tangible non-transitory computer-readable storage medium” as used herein refers to any non-transitory device or article of manufacture that participates in storing instructions which may be provided to processor 1186 or another data processing system 5410 for execution. Such a non-transitory medium can be non-volatile or volatile. Examples of non-volatile media include floppy disks, flexible disks, or other portable computer diskettes, hard disks, magnetic tape or other magnetic media, Compact Discs and compact-disc read-only memory (CD-ROM), DVDs, BLU-RAY disks, HD-DVD disks, other optical storage media, Flash memories, read-only memories (ROM), and erasable programmable read-only memories (EPROM or EEPROM). Examples of volatile media include dynamic memory, such as registers and random access memories (RAM). Storage media can store data electronically, magnetically, optically, chemically, mechanically, or otherwise, and can include electronic, magnetic, optical, electromagnetic, infrared, or semiconductor components.

Aspects of the present invention can take the form of a computer program product embodied in one or more tangible non-transitory computer readable medium(s) having computer readable program code embodied thereon. Such medium(s) can be manufactured as is conventional for such articles, e.g., by pressing a CD-ROM. The program embodied in the medium(s) includes computer program instructions that can direct data processing system 5410 to perform a particular series of operational steps when loaded, thereby implementing functions or acts specified herein.

In an example, data storage system 5440 includes code memory 5441, e.g., a random-access memory, and disk 5443, e.g., a tangible computer-readable rotational storage device such as a hard drive. Computer program instructions are read into code memory 5441 from disk 5443, or a wireless, wired, optical fiber, or other connection. Data processing system 5410 then executes one or more sequences of the computer program instructions loaded into code memory 5441, as a result performing process steps described herein. In this way, data processing system 5410 carries out a computer implemented process. For example, blocks of the flowchart illustrations or block diagrams herein, and combinations of those, can be implemented by computer program instructions. Code memory 5441 can also store data, or not: data processing system 5410 can include Harvard-architecture components, modified-Harvard-architecture components, or Von-Neumann-architecture components.

Computer program code can be written in any combination of one or more programming languages, e.g., JAVA, Smalltalk, C++, C, or an appropriate assembly language. Program code to carry out methods described herein can execute entirely on a single data processing system 5410 or on multiple communicatively-connected data processing systems 5410. For example, code can execute wholly or partly on a user's computer and wholly or partly on a remote computer or server. The server can be connected to the user's computer through network 5450.

The peripheral system 5420 can include one or more devices configured to provide digital content records to the data processing system 5410. For example, the peripheral system 5420 can include digital still cameras, digital video cameras, cellular phones, or other data processors. The data processing system 5410, upon receipt of digital content records from a device in the peripheral system 5420, can store such digital content records in the data storage system 5440.

The user interface system 5430 can include a mouse, a keyboard, another computer (connected, e.g., via a network or a null-modem cable), or any device or combination of devices from which data is input to the data processing system 5410. In this regard, although the peripheral system 5420 is shown separately from the user interface system 5430, the peripheral system 5420 can be included as part of the user interface system 5430.

The user interface system 5430 also can include a display device, a processor-accessible memory, or any device or combination of devices to which data is output by the data processing system 5410. In this regard, if the user interface system 5430 includes a processor-accessible memory, such memory can be part of the data storage system 5440 even though the user interface system 5430 and the data storage system 5440 are shown separately in FIG. 54.

In various aspects, data processing system 5410 includes communication interface 5415 that is coupled via network link 5416 to network 5450. For example, communication interface 5415 can be an integrated services digital network (ISDN) card or a modem to provide a data communication connection to a corresponding type of telephone line. As another example, communication interface 5415 can be a network card to provide a data communication connection to a compatible local-area network (LAN), e.g., an Ethernet LAN, or wide-area network (WAN). Wireless links, e.g., WiFi or GSM, can also be used. Communication interface 5415 sends and receives electrical, electromagnetic or optical signals that carry digital data streams representing various types of information across network link 5416 to network 5450. Network link 5416 can be connected to network 5450 via a switch, gateway, hub, router, or other networking device.

Network link 5416 can provide data communication through one or more networks to other data devices. For example, network link 5416 can provide a connection through a local network to a host computer or to data equipment operated by an Internet Service Provider (ISP).

Data processing system 5410 can send messages and receive data, including program code, through network 5450, network link 5416 and communication interface 5415. For example, a server can store requested code for an application program (e.g., a JAVA applet) on a tangible non-volatile computer-readable storage medium to which it is connected. The server can retrieve the code from the medium and transmit it through the Internet, thence a local ISP, thence a local network, thence communication interface 5415. The received code can be executed by data processing system 5410 as it is received, or stored in data storage system 5440 for later execution.

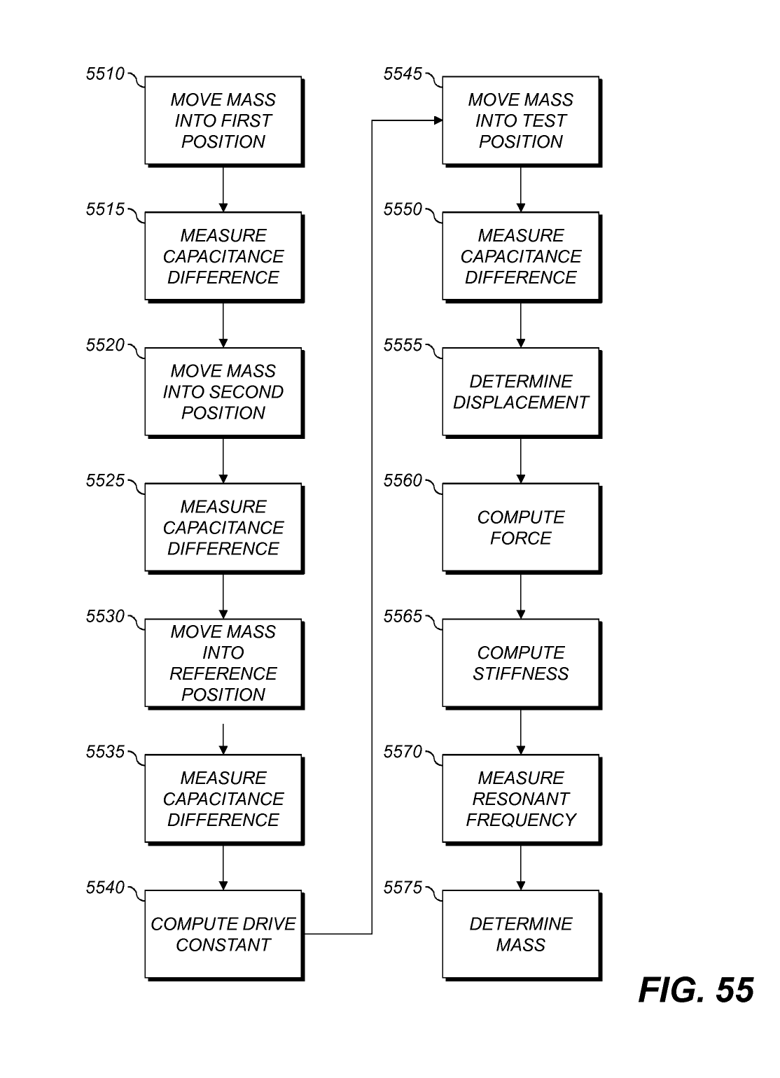

FIG. 55 shows an exemplary method of measuring displacement of a movable mass in a microelectromechanical system (MEMS). For clarity of explanation, reference is herein made to various components and quantities discussed above that can carry out, participate in, or be used in the steps of the exemplary method. It should be noted, however, that other components can be used; that is, exemplary method(s) shown in FIG. 55 are not limited to being carried out by the identified components.

In step 5510, the movable mass 101 is moved into a first position in which the movable mass is substantially in stationary contact with a first displacement-stopping surface.

In subsequent step 5515, using a controller, a first difference between the respective capacitances of two spaced-apart sensing capacitors 120 is automatically measured while the movable mass is in the first position. Each of the two sensing capacitors includes a respective first plate attached to and movable with the movable mass and a respective second plate substantially fixed in position (e.g., FIG. 1).

In step 5520, the movable mass is moved into a second position in which the movable mass is substantially in stationary contact with a second displacement-stopping surface spaced apart from the first displacement-stopping surface.

In subsequent step 5525, using the controller, a second difference between the respective capacitances is automatically measured while the movable mass is in the second position.

In step 5530, the movable mass is moved into a reference position in which the movable mass is substantially spaced apart from the first and the second displacement-stopping surfaces. A first distance between the first position and the reference position is different from a second distance between the second position and the reference position (e.g., gap₁ vs. gap₂).

In subsequent step 5535, using the controller, a third difference between the respective capacitances is automatically measured while the movable mass is in the reference position.

In step 5540, using the controller, a drive constant is automatically computed using the measured first difference (e.g., ΔC₁), the measured second difference (e.g., ΔC₂), the measured third difference (e.g., ΔC₀), and first and second selected layout distances corresponding to the first and second positions, respectively (gap_{1,layout} and gap_{1,layout}). In some aspects, the computing-drive-constant step 5540 includes, using the controller, automatically computing the following:
a) a first differential-capacitance change, computed using the measured first difference and the measured third difference;
b) a second differential-capacitance change, computed using the measured second difference and the measured third difference;
c) a geometry-difference value, computed using the first and second differential-capacitance changes and the first and second layout distances; and
d) the drive constant, computed using the first differential-capacitance change, the geometry-difference value, and the first layout distance.

In subsequent step 5545, using the controller, a drive signal is automatically applied to an actuator 140 to move the movable mass into a test position.

In subsequent step 5550, using the controller, a fourth difference between the respective capacitances is automatically measured while the movable mass is in the test position.

In subsequent step 5555, using the controller, the displacement of the movable mass in the test position is automatically determined using the computed drive constant and the measured fourth difference.

In various aspects, step 5555 is followed by step 5560. In step 5560, using the controller, a force is computed using the computed drive constant and the applied drive signal.

In step 5565, using the controller, a stiffness is determined using the computed drive constant, the applied drive signal, and the measured fourth difference.

In step 5570, a resonant frequency of the movable mass is measured.

In step 5575, using the controller, a value for the mass of the movable mass 101 is determined using the computed stiffness and the measured resonant frequency.

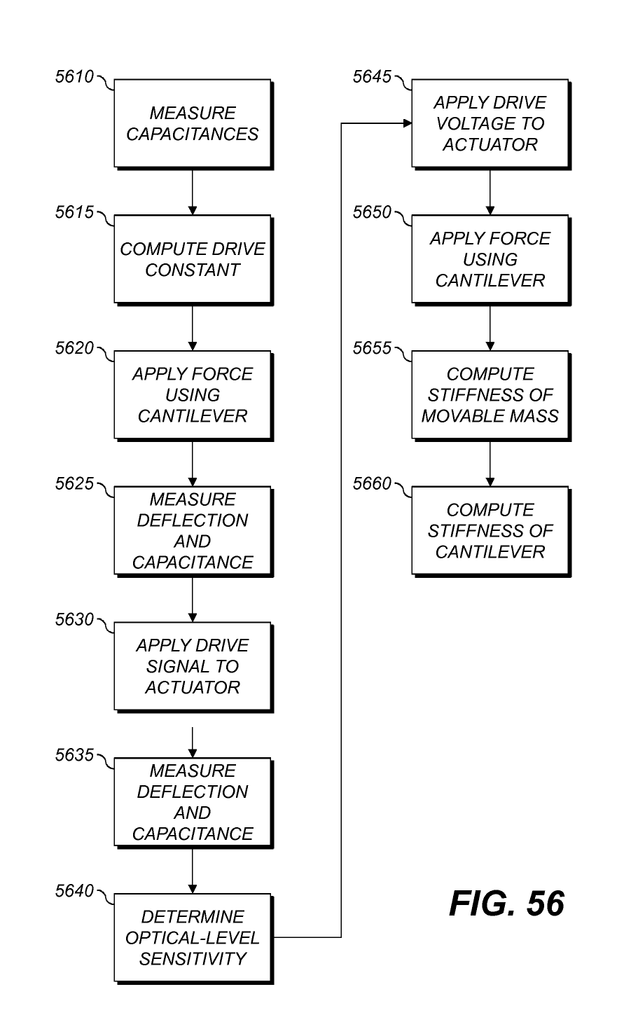

FIG. 56 shows an exemplary method of measuring properties of an atomic force microscope (AFM) having a cantilever and a deflection sensor. For clarity of explanation, reference is herein made to various components and quantities discussed above that can carry out, participate in, or be used in the steps of the exemplary method. It should be noted, however, that other components can be used; that is, exemplary method(s) shown in FIG. 55 are not limited to being carried out by the identified components.

In step 5610, using a controller, differential capacitances of two capacitors having respective first plates attached to and movable with a movable mass are measured. The capacitances are measured at a reference position of a movable mass and at first and second characterization positions of the movable mass spaced apart from the reference position along a displacement axis by respective, different first and second distances.

In step 5615, using the controller, a drive constant is automatically computed using the measured differential capacitances and first and second selected layout distances corresponding to the first and second characterization positions, respectively.

In step 5620, using an AFM cantilever, force is applied on the movable mass along the displacement axis in a first direction so that the movable mass moves to a first test position.

In subsequent step 5625, while the movable mass is in the first test position, a first test deflection of the AFM cantilever is measured using the deflection sensor. A first test differential capacitance of the two capacitors is also measured.

In step 5630, a drive signal is applied to an actuator to move the movable mass along the displacement axis opposite the first direction to a second test position.

In step 5635, while the movable mass is in the second test position, a second test deflection of the AFM cantilever is measured using the deflection sensor. A second test differential capacitance of the two capacitors is also measured.

In step 5640, an optical-level sensitivity is automatically computed using the drive constant, the first and second test deflections, and the first and second test differential capacitances.

In various aspects, step 5640 is followed by step 5645. In step 5645, a selected drive voltage is applied to the actuator.

In step 5650, while applying the drive voltage, using the AFM cantilever, force is applied on the movable mass along the displacement axis. Successive third and fourth deflections of the AFM cantilever and successive third and fourth test differential capacitances are contemporaneously measured using the deflection sensor.

In step 5655, a stiffness of the movable mass is automatically computed using the selected drive voltage and the third and fourth test differential capacitances, and the drive constant.

In step 5660, a stiffness of the AFM cantilever is automatically computed using the computed stiffness of the movable mass, the third and fourth deflections of the AFM cantilever, the third and fourth test differential capacitances, and the drive constant.

Referring back to FIG. 1, in various aspects, a microelectromechanical-systems (MEMS) device includes movable mass 101. An actuation system, e.g., including actuators 140 and voltage source 1130 (FIG. 11), is adapted to selectively translate the movable mass 101 along a displacement axis with reference to a reference position (not shown; a position in which gaps 111, 112 are both open).

Two spaced-apart sensing capacitors 120 each includes a respective first plate attached to and movable with the movable mass (one set of fingers) and a respective second plate 121 substantially fixed in position (the other set of fingers, e.g., mounted to substrate 105). Respective capacitances of the sensing capacitors vary as the movable mass 101 moves along the displacement axis 199.

Movable mass 101 can include an applicator 130 forming an end of the movable mass 101 along the displacement axis 199.

One or more displacement stopper(s) are arranged to form a first displacement-stopping surface and a second displacement-stopping surface. In this example, anchor 151 is the single displacement stopper and the displacement-stopping surfaces are the top and bottom edges of anchor 151, i.e., the faces of anchor 151 normal to displacement axis 199. The first and second displacement-stopping surfaces limit travel of the movable mass 101 in respective, opposite directions along the displacement axis 199 to respective first and second distances away from the reference position, wherein the first distance is different from the second distance (gap_{1,layout}≠gap_{2,layout}).

FIG. 5 shows another example in which two displacement stoppers 521, 522 are used. Each stopper 521, 522 has one displacement-stopping surface, i.e., the surface farthest from the anchors.

Referring to FIG. 8, the device can have a plurality of flexures 820, 821 supporting the movable mass 801 and adapted to permit the movable mass 801 to translate along the displacement axis 899 or a second axis orthogonal to the displacement axis (e.g., up/down or left/right in this figure).

FIG. 11 shows a MEMS device and system including a differential-capacitance sensor (capacitance chip 1114) and a controller 1186 adapted to automatically operate the actuation system (voltage source 1130) to position the movable mass 101 substantially at the reference position; to measure a first differential capacitance of the spaced-apart sensing capacitors 1120 using the differential-capacitance sensor 1114; to operate the actuation system to position the movable mass 101 in a first position substantially in stationary contact with the first displacement-stopping surface; to measure a second differential capacitance of the spaced-apart sensing capacitors 1120 using the differential-capacitance sensor 1114; to operate the actuation system to position the movable mass 101 in a second position substantially in stationary contact with the second displacement-stopping surface; to measure a third differential capacitance of the spaced-apart sensing capacitors using the differential-capacitance sensor; to receive first and second layout distances corresponding to the first and second positions, respectively; and to compute values of the first and second distances using the first and second layout distances and the first, second, and third measured differential capacitances.

The actuation system can include a plurality of comb drives 1140 and corresponding voltage sources 1130.

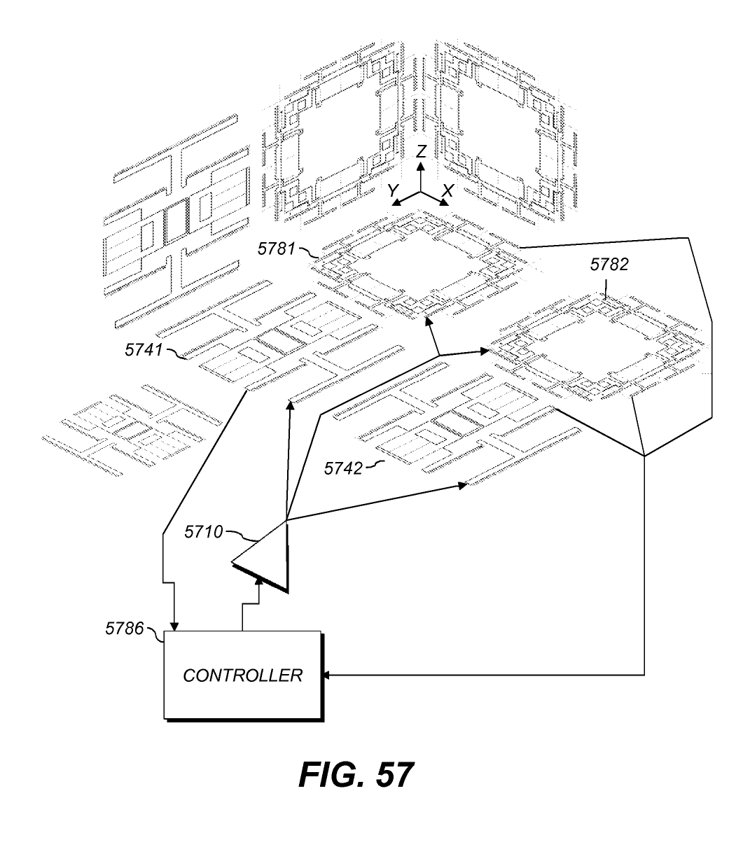

FIG. 57 shows a motion-measuring device according to various aspects.

First and second accelerometers 5741, 5742 are located within the XY plane, each accelerometer including a respective actuator and a respective sensor (FIGS. 1, 140 and 120)

First and second gyroscopes 5781, 5782 are located within the XY plane, each gyroscope including a respective actuator and a respective sensor (see FIG. 8).

Actuation source 5710 is adapted to drive the first accelerometer and the second accelerometer 90 degrees out of phase with each other, and adapted to drive the first gyroscope and the second gyroscope 90 degrees out of phase with each other. Controller 5786 is adapted to receive data from the respective sensors of the accelerometers and the gyroscopes and determine a translational, centrifugal, Coriolis, or transverse force acting on the motion-measuring device. Other accelerometers and gyroscopes are shown in the XY, XZ, and YZ planes.

In various aspects, each accelerometer and each gyroscope includes a respective movable mass. The actuation source 5710 is further adapted to selectively translate the respective movable masses along respective displacement axes with reference to respective reference positions. Each accelerometer and each gyroscope further includes a respective set of two spaced-apart sensing capacitors 120, each including a respective first plate attached to and movable with the respective movable mass and a respective second plate substantially fixed in position, wherein respective capacitances of the sensing capacitors vary as the respective movable mass moves along the respective displacement axis; and a respective set of one or more displacement stopper(s) (e.g., anchor 151) arranged to form a respective first displacement-stopping surface and a respective second displacement-stopping surface, wherein the respective first and second displacement-stopping surfaces limit travel of the respective movable mass in respective, opposite directions along the respective displacement axis to respective first and second distances away from the respective reference position, wherein each respective first distance is different from the respective second distance.

Further details of controllers such as controller 5786 are described in U.S. Publication No. 20100192266 by Clark, incorporated herein by reference. The controller may be fabricated on the same chip as the MEMS device. The MEMS device can be controlled by a computer which may be on the same chip or separate from the chip of the primary device. The computer may be any type of computer or processor, e.g., as discussed above. As discussed herein, EMM techniques can be used to extract mechanical properties of the MEMS device as functions of electronic measurands. These properties may be geometric, dynamic, material or other properties. Therefore, an electronic measurand sensor is provided to measure the desired electrical measurand on the test structure. For instance, an electronic measurand sensor may measure capacitance, voltage, frequency, or the like. The electronic measurand sensor may be on the same chip with the MEMS device. In other embodiments, electronic measurand sensor may be separate from the chip of the MEMS device.

Referring back to FIG. 21, a temperature sensor includes a movable mass 2101. An actuation system (not shown) is adapted to selectively translate the movable mass along a displacement axis with reference to a reference position. Two spaced-apart sensing capacitors 2120 are provided, each including a respective first plate attached to and movable with the movable mass and a respective second plate substantially fixed in position, wherein respective capacitances of the sensing capacitors vary as the movable mass moves along the displacement axis.

One or more displacement stopper(s) (next to gap 2111, 2112) are arranged to form a first displacement-stopping surface and a second displacement-stopping surface, wherein the first and second displacement-stopping surfaces limit travel of the movable mass in respective, opposite directions along the displacement axis to respective first and second distances away from the reference position, wherein the first distance is different from the second distance, and wherein the actuation system is further adapted to selectively permit the movable mass to vibrate along the displacement axis (“vibration due to T”) within bounds defined by the first and second displacement-stopping surfaces.

A differential-capacitance sensor (FIG. 11) is electrically connected to the respective second plates. A displacement-sensing unit (voltage source 2119; TIA 2130; amplifier 2140) is electrically connected to the movable mass 2102 and to the second plate of at least one of the sensing capacitors 2120 and adapted to provide a displacement signal correlated with a displacement of the movable mass along the displacement axis. A controller 1186 (FIG. 11) is adapted to automatically operate the actuation system to position the movable mass in a first position substantially at the reference position, in a second position substantially in stationary contact with the first displacement-stopping surface, and in a third position substantially in stationary contact with the second displacement-stopping surface; using the differential-capacitance sensor, measure first, second, and third differential capacitances of the of the sensing capacitors corresponding to the first, second, and third positions, respectively; receive first and second layout distances corresponding to the first and second positions, respectively; compute a drive constant using the measured first, second, and third differential capacitances and the first and second layout distances; apply a drive signal to the actuation system to move the movable mass into a test position; measure a test differential capacitance corresponding to the test position using the differential-capacitance sensor; compute a stiffness using the computed drive constant, the applied drive signal, and the test differential capacitance; cause the actuation system to permit the movable mass to vibrate; while the movable mass is permitted to vibrate, measure a plurality of successive displacement signals using the displacement-sensing unit and compute respective displacements of the movable mass using the computed drive constant; and determine a temperature using the measured displacements and the computed stiffness.

As shown, each first and second plate can include a respective comb. The actuation system can includes voltage source (not shown) adapted to selectively apply voltage to the second plates to exert pulling forces on the respective first plates.

In the example shown, the first plate of a selected one of the sensing capacitors 2120 (RHS) is electrically connected to the movable mass 2102. The displacement-sensing unit includes voltage source 2119 electrically connected to the movable mass 2101 and adapted to provide an excitation signal, so that a first current passes through the selected one of the sensing capacitors 2120; and a transimpedance amplifier 2130 electrically connected to the second plate of the selected one of the sensing capacitors 2120 and adapted to provide the displacement signal corresponding to the first current.

The excitation signal can include a DC component and an AC component.

A second current can pass through the non-selected one of the sensing capacitors 2120 (LHS). The differential-capacitance sensor can include a second transimpedance amplifier (not shown) electrically connected to the second plate of the non-selected one of the sensing capacitors (2120, LHS) and adapted to provide a second displacement signal corresponding to the second current; and a device for receiving the displacement signal from the transimpedance amplifier and computing the differential capacitance using the displacement signal and the second displacement signal.

The invention is inclusive of combinations of the aspects described herein. References to “a particular aspect” and the like refer to features that are present in at least one aspect of the invention. Separate references to “an aspect” or “particular aspects” or the like do not necessarily refer to the same aspect or aspects; however, such aspects are not mutually exclusive, unless so indicated or as are readily apparent to one of skill in the art. The use of singular or plural in referring to “method” or “methods” and the like is not limiting. The word “or” is used in this disclosure in a non-exclusive sense, unless otherwise explicitly noted.

The invention has been described in detail with particular reference to certain preferred aspects thereof, but it will be understood that variations, combinations, and modifications can be effected by a person of ordinary skill in the art within the spirit and scope of the invention.

1. A method of measuring displacement of a movable mass in a microelectromechanical system (MEMS), the method comprising:
moving the movable mass into a first position in which the movable mass is substantially in stationary contact with a first displacement-stopping surface;
using a controller, automatically measuring a first difference between the respective capacitances of two spaced-apart sensing capacitors while the movable mass is in the first position, wherein each of the two sensing capacitors includes a respective first plate attached to and movable with the movable mass and a respective second plate substantially fixed in position;
moving the movable mass into a second position in which the movable mass is substantially in stationary contact with a second displacement-stopping surface spaced apart from the first displacement-stopping surface;
using the controller, automatically measuring a second difference between the respective capacitances while the movable mass is in the second position;
moving the movable mass into a reference position in which the movable mass is substantially spaced apart from the first and the second displacement-stopping surfaces, wherein a first distance between the first position and the reference position is different from a second distance between the second position and the reference position;
using the controller, automatically measuring a third difference between the respective capacitances while the movable mass is in the reference position;
using the controller, automatically computing a drive constant using the measured first difference, the measured second difference, the measured third difference, and first and second selected layout distances corresponding to the first and second positions, respectively;
using the controller, automatically applying a drive signal to an actuator to move the movable mass into a test position;
using the controller, automatically measuring a fourth difference between the respective capacitances while the movable mass is in the test position; and
using the controller, automatically determining the displacement of the movable mass in the test position using the computed drive constant and the measured fourth difference.

2. The method according to claim 1, further including:
using the controller, computing a force using the computed drive constant and the applied drive signal;
using the controller, computing a stiffness using the computed drive constant, the applied drive signal, and the measured fourth difference;
measuring a resonant frequency of the movable mass; and
using the controller, determining a value for the mass of the movable mass using the computed stiffness and the measured resonant frequency.

3. The method according to claim 1, wherein the computing-drive-constant step includes, using the controller, automatically computing the following:
a) a first differential-capacitance change, computed using the measured first difference and the measured third difference;
b) a second differential-capacitance change, computed using the measured second difference and the measured third difference;
c) a geometry-difference value, computed using the first and second differential-capacitance changes and the first and second layout distances; and
d) the drive constant, computed using the first differential-capacitance change, the geometry-difference value, and the first layout distance.

4. A method of measuring properties of an atomic force microscope (AFM) having a cantilever and a deflection sensor, the method comprising:
using a controller, automatically measuring respective differential capacitances, at a reference position of a movable mass and at first and second characterization positions of the movable mass spaced apart from the reference position along a displacement axis by respective, different first and second distances, of two capacitors having respective first plates attached to and movable with the movable mass;
using the controller, automatically computing a drive constant using the measured differential capacitances and first and second selected layout distances corresponding to the first and second characterization positions, respectively;
using an AFM cantilever, applying force on the movable mass along the displacement axis in a first direction so that the movable mass moves to a first test position;
while the movable mass is in the first test position, measuring a first test deflection of the AFM cantilever using the deflection sensor and measuring a first test differential capacitance of the two capacitors;
applying a drive signal to an actuator to move the movable mass along the displacement axis opposite the first direction to a second test position;
while the movable mass is in the second test position, measuring a second test deflection of the AFM cantilever using the deflection sensor and measuring a second test differential capacitance of the two capacitors; and
automatically computing an optical-level sensitivity using the drive constant, the first and second test deflections, and the first and second test differential capacitances.

5. The method according to claim 4, further including
applying a selected drive voltage to the actuator;
while applying the drive voltage, using the AFM cantilever, applying force on the movable mass along the displacement axis and contemporaneously measuring successive third and fourth deflections of the AFM cantilever using the deflection sensor and successive third and fourth test differential capacitances;
automatically computing a stiffness of the movable mass using the selected drive voltage and the third and fourth test differential capacitances, and the drive constant; and
automatically computing a stiffness of the AFM cantilever using the computed stiffness of the movable mass, the third and fourth deflections of the AFM cantilever, the third and fourth test differential capacitances, and the drive constant.

6. A micro electromechanical-systems (MEMS) device, comprising:
a) a movable mass;
b) an actuation system adapted to selectively translate the movable mass along a displacement axis with reference to a reference position;
c) two spaced-apart sensing capacitors, each including a respective first plate attached to and movable with the movable mass and a respective second plate substantially fixed in position, wherein respective capacitances of the sensing capacitors vary as the movable mass moves along the displacement axis; and
d) one or more displacement stopper(s) arranged to form a first displacement-stopping surface and a second displacement-stopping surface, wherein the first and second displacement-stopping surfaces limit travel of the movable mass in respective, opposite directions along the displacement axis to respective first and second distances away from the reference position, wherein the first distance is different from the second distance.

7. The device according to claim 6, further including a differential-capacitance sensor and a controller adapted to automatically:
operate the actuation system to position the movable mass substantially at the reference position;
measure a first differential capacitance of the spaced-apart sensing capacitors using the differential-capacitance sensor;
operate the actuation system to position the movable mass in a first position substantially in stationary contact with the first displacement-stopping surface;
measure a second differential capacitance of the spaced-apart sensing capacitors using the differential-capacitance sensor;
operate the actuation system to position the movable mass in a second position substantially in stationary contact with the second displacement-stopping surface;
measure a third differential capacitance of the spaced-apart sensing capacitors using the differential-capacitance sensor;
receive first and second layout distances corresponding to the first and second positions, respectively; and
compute values of the first and second distances using the first and second layout distances and the first, second, and third measured differential capacitances.

8. The system according to claim 6, wherein the movable mass includes an applicator forming an end of the movable mass along the displacement axis.

9. The device according to claim 6, further including a plurality of flexures supporting the movable mass and adapted to permit the movable mass to translate along the displacement axis or a second axis orthogonal to the displacement axis.

10. The device according to claim 6, wherein the actuation system includes a plurality of comb drives and corresponding voltage sources.

11. A motion-measuring device, comprising:
a) a first and a second accelerometer located within a plane, each accelerometer including a respective actuator and a respective sensor;
b) a first and a second gyroscope located within the plane, each gyroscope including a respective actuator and a respective sensor;
c) an actuation source adapted to drive the first accelerometer and the second accelerometer 90 degrees out of phase with each other, and adapted to drive the first gyroscope and the second gyroscope 90 degrees out of phase with each other; and
d) a controller adapted to receive data from the respective sensors of the accelerometers and the gyroscopes and determine a translational, centrifugal, Coriolis, or transverse force acting on the motion-measuring device.

12. The device according to claim 11, wherein:
a) each accelerometer and each gyroscope includes a respective movable mass;
b) the actuation source is further adapted to selectively translate the respective movable masses along respective displacement axes with reference to respective reference positions; and
c) each accelerometer and each gyroscope further includes:
i) a respective set of two spaced-apart sensing capacitors,
each including a respective first plate attached to and movable with the respective movable mass and a respective second plate substantially fixed in position, wherein respective capacitances of the sensing capacitors vary as the respective movable mass moves along the respective displacement axis; and
ii) a respective set of one or more displacement stopper(s) arranged to form a respective first displacement-stopping surface and a respective second displacement-stopping surface, wherein the respective first and second displacement-stopping surfaces limit travel of the respective movable mass in respective, opposite directions along the respective displacement axis to respective first and second distances away from the respective reference position, wherein each respective first distance is different from the respective second distance.

13. A temperature sensor, comprising:
a) a movable mass;
b) an actuation system adapted to selectively translate the movable mass along a displacement axis with reference to a reference position;
c) two spaced-apart sensing capacitors, each including a respective first plate attached to and movable with the movable mass and a respective second plate substantially fixed in position, wherein respective capacitances of the sensing capacitors vary as the movable mass moves along the displacement axis;
d) one or more displacement stopper(s) arranged to form a first displacement-stopping surface and a second displacement-stopping surface, wherein the first and second displacement-stopping surfaces limit travel of the movable mass in respective, opposite directions along the displacement axis to respective first and second distances away from the reference position, wherein the first distance is different from the second distance, and wherein the actuation system is further adapted to selectively permit the movable mass to vibrate along the displacement axis within bounds defined by the first and second displacement-stopping surfaces;
e) a differential-capacitance sensor electrically connected to the respective second plates; and
f) a displacement-sensing unit electrically connected to the movable mass and to the second plate of at least one of the sensing capacitors and adapted to provide a displacement signal correlated with a displacement of the movable mass along the displacement axis;
g) a controller adapted to automatically:
operate the actuation system to position the movable mass in a first position substantially at the reference position, in a second position substantially in stationary contact with the first displacement-stopping surface, and in a third position substantially in stationary contact with the second displacement-stopping surface;
using the differential-capacitance sensor, measure first, second, and third differential capacitances of the of the sensing capacitors corresponding to the first, second, and third positions, respectively;
receive first and second layout distances corresponding to the first and second positions, respectively;
compute a drive constant using the measured first, second, and
third differential capacitances and the first and second layout distances;
apply a drive signal to the actuation system to move the movable mass into a test position;
measure a test differential capacitance corresponding to the test position using the differential-capacitance sensor;
compute a stiffness using the computed drive constant, the applied drive signal, and the test differential capacitance;
cause the actuation system to permit the movable mass to vibrate;
while the movable mass is permitted to vibrate, measure a plurality of successive displacement signals using the displacement-sensing unit and compute respective displacements of the movable mass using the computed drive constant; and
determine a temperature using the measured displacements and the computed stiffness.

14. The sensor according to claim 13, wherein each first and second plate includes a respective comb and the actuation system includes a voltage source adapted to selectively apply voltage to the second plates to exert pulling forces on the respective first plates.

15. The sensor according to claim 13, wherein the first plate of a selected one of the sensing capacitors is electrically connected to the movable mass, and the displacement-sensing unit includes:
a) a voltage source electrically connected to the movable mass and adapted to provide an excitation signal, so that a first current passes through the selected one of the sensing capacitors; and
b) a transimpedance amplifier electrically connected to the second plate of the selected one of the sensing capacitors and adapted to provide the displacement signal corresponding to the first current.

16. The sensor according to claim 15, wherein the excitation signal includes a DC component and an AC component.

17. The sensor according to claim 15, wherein a second current passes through the non-selected one of the sensing capacitors and the differential-capacitance sensor includes:
a) a second transimpedance amplifier electrically connected to the second plate of the non-selected one of the sensing capacitors and adapted to provide a second displacement signal corresponding to the second current; and
b) a device for receiving the displacement signal from the transimpedance amplifier and computing the differential capacitance using the displacement signal and the second displacement signal.
